(19) United States
(12) Patent Application Publication
(10) Pub. No.: US 2013/0037310 A1
(43) Pub. Date: Feb. 14, 2013

(54) EPOXY RESIN COMPOSITION FOR CIRCUIT BOARD, PREPREG, LAMINATE, RESIN SHEET, LAMINATED BASE MATERIAL FOR PRINTED WIRING BOARD, PRINTED WIRING BOARD, AND SEMICONDUCTOR DEVICE

(71) Applicants: Michio Kimura, Tokyo (JP); Nobuki Tanaka, Tokyo (JP); Tadasuke Endo, Tokyo (JP)

(72) Inventors: Michio Kimura, Tokyo (JP); Nobuki Tanaka, Tokyo (JP); Tadasuke Endo, Tokyo (JP)

(73) Assignee: SUMITOMO BAKELITE CO., LTD., Tokyo (JP)

(21) Appl. No.: 13/642,944

(22) PCT Filed: May 2, 2011
(86) PCT No.: PCT/JP2011/002525

§ 371 Date: Oct. 23, 2012

(30) Foreign Application Priority Data
May 7, 2010 (JP) 2010-107694
May 12, 2010 (JP) 2010-110645

(51) Int. Cl. C08L 63/00; B32B 27/38; H05K 1/03; B32B 15/092

(52) U.S. Cl. 174/251; 523/400; 428/418; 428/413

(57) ABSTRACT

Provided is an epoxy resin composition for a circuit board including an epoxy resin (A); an inorganic filler (B); and a cyclic or cage-shape siloxane compound (C) having at least two Si—H bonds or two Si—OH bonds.

### TECHNICAL FIELD

The present invention relates to an epoxy resin composition for a circuit board, a prepreg, a laminate, a resin sheet, a laminated base material for a printed wiring board, a printed wiring board, and a semiconductor device.

### BACKGROUND ART

In recent years, along with the demand for high-performance electronic equipment, the high-density integration of electronic components and furthermore the high-density packaging and the like thereof have been improved. Therefore, in printed wiring boards which are used for these and support high-density packaging, reduction in size and thickness, increase in density, and multi-layering have been further improved than the related art.

Such techniques are disclosed in Patent Documents 1 to 5 below.

For example, Patent Document 1 discloses a general prepreg used for manufacturing a printed wiring board. In addition, Patent Document 2 discloses a technique of using an electroless plating method to form an external terminal, which electrically connects a circuit and external electronic components to each other, on a printed wiring board.

In addition, Patent Document 3 discloses a printed wiring board including a substrate; and a metal foil which is provided on the substrate through an adhesive aid. In printed wiring boards, techniques of forming an adhesive layer which is provided between a substrate and a metal foil for bonding them are disclosed in Patent Documents 4 and 5.

### RELATED DOCUMENT

### Patent Document

[Patent Document 1] Japanese Unexamined patent publication NO. 2010-31263
[Patent Document 2] Japanese Unexamined patent publication NO. 2008-144188
[Patent Document 3] Japanese Unexamined patent publication NO. 2006-159900
[Patent Document 4] Japanese Unexamined patent publication NO. 2006-196863
[Patent Document 5] Japanese Unexamined patent publication NO. 2007-326962

### DISCLOSURE OF THE INVENTION

### Problems to be Solved by the Invention

In the above-described printed wiring boards, there is a room for improvement of connection reliability.

### Means for Solving the Problems

The present invention includes the following configurations.

[1]

An epoxy resin composition for a circuit board comprising:

an epoxy resin (A);

an inorganic filler (B); and

a cyclic siloxane compound (C) having at least two Si—H bonds or two Si—O bonds.

[2]

The epoxy resin composition for a circuit board according to [1],

wherein the cyclic siloxane compound (C) having at least two Si—H bonds or two Si—O bonds is represented by Formula (1) below.

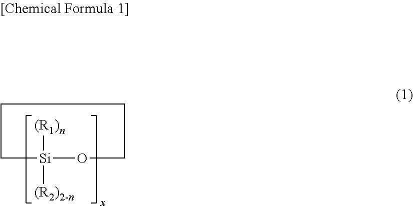

(In the formula, x represents an integer of equal to or more than 2 and equal to or less than 10; R₁'s may be the same as or different from each other and represent a group having an atom selected from an oxygen atom, a boron atom, and a nitrogen atom; and R₂ represents a hydrogen atom or a saturated or unsaturated hydrocarbon group having 1 to 20 carbon atoms, in which at least two of R₁'s and R₂'s represent a hydrogen atom or a hydroxyl group.)

[3]

The epoxy resin composition for a circuit board according to [1] or [2], further comprising:

a cyanate resin composition.

[4]

A prepreg obtained by impregnating a substrate with an epoxy resin composition for a circuit board,

wherein the epoxy resin composition for a circuit board is the epoxy resin composition for a circuit board according to any one of [1] to [3].

[5]

A metal-clad laminate comprising a metal foil at least on a single surface of the prepreg according to [4] or at least on a single surface of a laminate obtained by making two or more prepregs according to [4] overlap.

[6]

A resin sheet comprising:

a support substrate; and

an insulating layer which is formed over the support substrate and is formed of an epoxy resin composition for a circuit board,

wherein the support substrate is a film or a metal foil, and

the epoxy resin composition for a circuit board is the epoxy resin composition for a circuit board according to any one of [1] to [3].

[7]

A printed wiring board obtained by using the metal-clad laminate according to [5] as an inner layer circuit board.

[8]

A printed wiring board obtained by laminating the prepreg according to [4] over a circuit of an inner layer circuit board.

[9]

A printed wiring board obtained by laminating the prepreg according to [4] or the resin sheet according to [6] over a circuit of an inner layer circuit board.

[10]

A semiconductor device obtained by mounting a semiconductor element over a printed wiring board,

wherein the printed wiring board is the printed wiring board according to any one of [7] to [9].

[11]

A laminated base material for a printed wiring board comprising:

a support substrate;

an adhesive layer which is formed over the support substrate; and

a resin layer which is formed over the adhesive layer,

wherein the resin layer contains an epoxy resin (A), an inorganic filler (B), and a cyclic or cage-shape siloxane compound (C) having at least two bonds selected from a group consisting of an Si—H bond and an Si—OH bond.

The laminated base material for a printed wiring board according to [11],

wherein the cyclic or cage-shape siloxane compound (C) having at least two bonds selected from a group consisting of an Si—H bond and an Si—OH bond is represented by Formula (1) below.

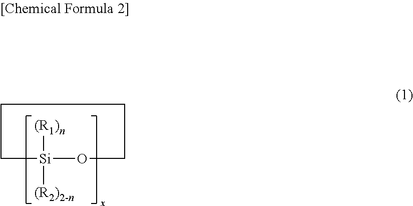

(In the formula, x represents an integer of equal to or more than 2 and equal to or less than 10; n represents an integer of equal to or more than 0 and equal to or less than 2; R₁'s may be the same as or different from each other and represent a substituent having an atom selected from an oxygen atom, a boron atom, and a nitrogen atom; and R₂'s may be the same as or different from each other and represent a hydrogen atom or a saturated or unsaturated hydrocarbon group having 1 to 20 carbon atoms, in which at least two of R₁'s and R₂'s represent a hydrogen atom or a hydroxyl group.)

[13]

The laminated base material for a printed wiring board according to [11] or [12],

wherein the resin layer contains 40 to 75% by weight of the inorganic filler (B) with respect to 100% by weight of the total weight of the resin layer.

[14]

The laminated base material for a printed wiring board according to any one of [11] to [13],

wherein the resin layer contains 1 of a cyanate resin composition (D).

[15]

The laminated base material for a printed wiring board according to [14],

wherein the adhesive layer contains an aromatic polyamide resin (X) having at least one hydroxyl group.

[16]

The laminated base material for a printed wiring board according to [15],

wherein the aromatic polyamide resin (X) having at least one hydroxyl group contains a segment where 4 or more carbon chains having a diene structure are connected.

[17]

The laminated base material for a printed wiring board according to [15] or [16],

wherein the aromatic polyamide resin (X) having at least one hydroxyl group contains a segment having a butadiene rubber component.

[18]

The laminated base material for a printed wiring board according to any one of [11] to [17],

wherein the adhesive layer contains an inorganic filler (Y) having an average particle size of 100 nm or less.

[19]

The laminated base material for a printed wiring board according to any one of [11] to [18],

wherein a total specific surface area of the inorganic filler (B) included in the resin layer is equal to or greater than 1.8 m² and equal to or less than 4.5 m².

[20]

A laminate for a printed wiring board obtained by bonding a laminated base material for a printed wiring board onto both surfaces of a substrate,

wherein the laminated base material for a printed wiring board is the laminated base material for a printed wiring board according to any one of [11] to [19].

[21]

A printed wiring board obtained by using the laminated base material for a printed wiring board according to any one of [11] to [19] as an inner layer circuit board.

[22]

The printed wiring board according to [21],

wherein the inner layer circuit board is obtained by curing the laminate for a printed wiring board according to [20] and forming a conductive circuit over the laminate for a printed wiring board.

[23]

A semiconductor device obtained by mounting a semiconductor element to the printed wiring board according to [21] or [22].

### Advantageous Effect of the Invention

According to the invention, a printed wiring board and a semiconductor device having superior connection reliability can be realized, and an epoxy resin composition for a circuit board, a prepreg, a laminate, a resin sheet, a laminated base material for a printed wiring board which are used for the same.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view schematically illustrating an example of a laminated base material for a printed wiring board;

FIG. 2 is a cross-sectional view schematically illustrating an example of a laminated base material for a printed wiring board;

FIG. 3 is a cross-sectional view schematically illustrating an impregnation coating machine which dips a fiber substrate in a resin varnish.

FIG. 4 is a cross-sectional view illustrating processes of an example of manufacturing a metal-clad laminate using a laminated base material for a printed wiring board.

FIG. 5 is a cross-sectional view illustrating processes of an example of manufacturing a printed wiring board using a laminated base material for a printed wiring board.

FIG. 6 is a cross-sectional view schematically illustrating a semiconductor device which is manufactured using a multilayer printed wiring board.

FIG. 7 is a cross-sectional view illustrating an example of manufacturing a printed wiring board using a laminated base material for a printed wiring board.

FIG. 8 is a cross-sectional view schematically illustrating a semiconductor device which is manufactured using a printed wiring board.

### DESCRIPTION OF EMBODIMENTS

Hereinafter, an epoxy resin composition for a circuit board according to the invention (hereinafter referred to as “the resin composition”) and a prepreg, a laminate (including a laminate for a printed wiring board and a metal-clad laminate), a resin sheet, a printed wiring board, a laminated base material for a printed wiring board, and a semiconductor device which uses the resin composition, will be described in detail. In an embodiment of the invention, a circuit board represents a printed wiring board in which a circuit configured by electronic members at least including, for example, a conductive pattern, a wiring layer, and electronic components is formed on a substrate. The circuit may be formed on a single surface or both surfaces of the substrate. In addition, the substrate may be configured as multiple layers (including a build-up layer) or a single layer (including a core layer). In the case of the multiple layers, the circuit may be formed on an inner layer or an outer layer. In addition, the substrate may be a flexible substrate or a rigid substrate or may include both of them. In addition, in this embodiment, a prepreg, a laminate, a resin sheet, and a laminated base material for a printed wiring board are used for the above-described printed wiring board. In this embodiment, a semiconductor device includes at least the printed wiring board, electronic elements mounted on the printed wiring board. In addition, in this embodiment, the prepreg, the laminate, the resin sheet, and the laminated base material for a printed wiring board which use the resin composition are referred to as a substrate for a printed wiring board.

The resin composition according to the invention contains an epoxy resin (A), an inorganic filler (B), and a cyclic or cage-shape siloxane compound (C) having at least two Si—H bonds or two Si—OH bonds (sometimes abbreviated as the cyclic siloxane compound (C)).

According to the invention, the cyclic siloxane compound (C) is reactive with the epoxy resin (A) and/or the inorganic filler (B) through Si—H bonds or Si—OH bonds. These components are strongly connected and cyclic siloxane compounds (C) are bonded to each other. As a result, the following first effect or second effect can be obtained.

That is, firstly, by bonding the components to each other, low thermal expansion can be imparted to the substrate for a printed wiring board using the resin composition according to the invention. In addition, the Si—H bonds or Si—OH bonds of the cyclic siloxane compound (C) can weaken the affinity between a resin surface and a plating catalyst such as palladium catalyst. As a result, plating characteristics of a resin surface which is a non-plated area can be reduced and thus plating characteristics of a metal portion formed on the resin surface (for example, a plated area configured by a pattern of metal such as copper) can be relatively improved. Accordingly, the plating characteristics in the plated area on the resin surface can be relatively improved and the occurrence of defective continuity can be suppressed after fine wiring process. Therefore, a printed wiring board and the like having superior reliability can be realized.

In addition, secondly, by bonding the components to each other, strength can be imparted to a surface of the laminated base material for a printed wiring board using the resin composition according to the invention so as to be hydrophobized. As a result, in processes of manufacturing a printed wiring board, a resin layer thereof can absorb less water. In an adhesive layer formed on a surface of such a resin layer, the infiltration of swelling solution and roughening solution in desmear process can be suppressed and thus it is difficult for the surface to be rough. Therefore, according to the invention, in a surface of an adhesive layer, excessive roughening can be suppressed. As a result, the adhesion between the adhesive layer and a conductive film can be improved and thus a printed wiring board and the like having superior reliability can be realized.

Hereinafter, a resin composition realizing the first effect (hereinafter, referred to as the first resin composition) will be described. Next, a resin composition realizing the second effect (hereinafter, referred to as the second resin composition) will be described. In addition, when a configuration of a resin composition is not particularly specified as that of the first resin composition or the second resin composition, this indicates that the configuration is shared by both of the resin compositions. In addition, the first resin composition and the second resin composition are simply referred to as the resin composition.

(First Resin Composition)

Hereinafter, the first resin composition will be described.

General printed wiring boards are formed with the following method, for example, as described in Patent Document 1. First, a resin composition including a thermosetting resin such as epoxy resin as a major component is dissolved in a solvent to prepare a resin varnish. An inorganic filler is added to this resin varnish and a substrate is impregnated with this resin varnish and applied heat and drying to prepare a prepreg. In addition, in Patent Document 2, using such a prepreg, a circuit is formed with the following plating method to obtain a printed wiring board. That is, for example, using gold plating, circuit terminal portions, wire bonding portions, and the like of a printed wiring board are electrically connected to each other. Representative examples of a gold plating method include Direct Immersion Gold (DIG), Electroless Nickel Immersion Gold (ENIG), and Electroless Nickel Electroless Palladium Immersion Gold (ENEPIG).

However, along with the reduction in the size of wiring and the reduction in the size of a printed wiring board of recent years, high-level electrical reliability is in demand. For example, in processes of manufacturing a printed wiring board, when a terminal portion is metal-plated, it is required that metal be prevented from diffusing after plating, as compared to the related art. In addition, when fine wiring is formed, it is required that electrical reliability be further improved. In addition, as compared to the related art, since a junction area of an element, a wire, and the like is reduced, it is required that lead-free solder joint reliability be further improved.

In consideration of such a technical environment, as a result of discussion, the present inventors thought that, when plating characteristics of a plated area are relatively improved and plating characteristics of a non-plated area are relatively reduced in a resin layer obtained from a resin composition, it is difficult for a plated layer to be formed on a surface of the resin layer which is in the non-plated area; and as a result, metal can be prevented from diffusing after plating. In this embodiment, the plated area represents a metal-pattern-formed area obtained by, for example, attaching a metal foil such as a copper foil to a surface of a resin layer and forming the metal foil into a predetermined pattern.

Therefore, as a result of conducting various tests, the present inventors found that it is preferable that a resin composition constituting a resin layer contain an epoxy resin (A), an inorganic filler (B), and a cyclic or cage-shape siloxane compound (C) having at least two Si—H bonds or two Si—OH bonds (sometimes abbreviated as the cyclic siloxane compound (C)), and completed the invention.

That is, according to the first resin composition, by using the epoxy resin (A) and the inorganic filler (B) in combination, when an epoxy resin composition for a circuit board is cured to obtain a laminate or a printed wiring board, low thermal expansion can be imparted thereto. For example, when plating is performed using Electroless Nickel Immersion Gold (ENEPIG) and Electroless Nickel Electroless Palladium Immersion Gold (ENEPIG), by adding the cyclic or cage-shape siloxane compound (c) having at least two Si—H bonds or two Si—OH bonds, the affinity between a surface of a resin layer and palladium catalyst can be weakened. Therefore, plating characteristics are reduced in a non-plated area, whereas plating characteristics are relatively improved in a plated area, as compared to a non-plated area. Accordingly, since satisfactory plating can be performed in a plated area, the occurrence of defective continuity and the like can be suppressed even after fine wiring processing is performed.

As a result, according to the first resin composition of the invention, there can be provided an epoxy resin composition for a circuit board which has superior low thermal expansion and high electrical reliability and supports fine wire; and a prepreg, a laminate, a printed wiring board, and a semiconductor device which use the epoxy resin composition for a circuit board and have superior electrical reliability even after plating is performed. In addition, in a case where a prepreg and a resin sheet, obtained by using the epoxy resin composition for a circuit board, are used for manufacturing a printed wiring board, even when plating such as ENEPIG is performed, a metal used for the plating is prevented from diffusing after plating and the occurrence of defective continuity can be suppressed.

Hereinafter, the respective components will be described in detail.

The epoxy resin (A) is not particularly limited, and examples thereof include bisphenol epoxy resins such as bisphenol an epoxy resin, bisphenol F epoxy resin, bisphenol S epoxy resin, bisphenol E epoxy resin, bisphenol M epoxy resin, bisphenol P epoxy resin, and bisphenol Z epoxy resin; novolac epoxy resins such as phenol novolac epoxy resin and cresol novolac epoxy resin; and epoxy resins such as biphenyl epoxy resin, biphenyl aralkyl epoxy resin, aryl alkylene epoxy resin, naphthalene epoxy resin, anthracene epoxy resin, phenoxy epoxy resin, dicyclopentadiene epoxy resin, norbornene epoxy resin, adamantane epoxy resin, and fluorene epoxy resin. Among these, one kind may be used alone or two or more kinds may be used in combination.

The content of the epoxy resin (A) is not particularly limited, and is preferably equal to or greater than 5% by weight and equal to or less than 30% by weight, with respect to the total solid content of the resin composition (the solid content represents components which actually form a resin layer and includes components such as liquid epoxy other than a solvent). When the content of the epoxy resin (A) is set to be equal to or greater than the lower limit, a deterioration in the curability of the epoxy resin or a deterioration in the moisture resistance of a prepreg or a printed wiring board obtained from the resin composition can be suppressed. In addition, when the content of the epoxy resin (A) is set to be equal to or less than the upper limit, an increase in the coefficient of linear thermal expansion of a prepreg or a printed wiring board or a reduction in heat resistance can be suppressed.

The inorganic filler (B) is not particularly limited, and examples thereof include silicates such as talc, calcined clay, non-calcined clay, mica, and glass; oxides such as titanium oxide, alumina, silica, and fused silica; carbonates such as calcium carbonate, magnesium carbonate, and hydrotalcite; hydroxides such as aluminum hydroxide, magnesium hydroxide, and calcium hydroxide; sulfates or sulfites such as barium sulfate, calcium sulfate, and calcium sulfite; borates such as zinc borate, barium metaborate, aluminum borate, calcium borate, and sodium borate; nitrides such as aluminum nitride, boron nitride, silicon nitride, and carbon nitride; and titanates such as strontium titanate and barium titanate. Among these, as the inorganic filler, one kind may be used alone or two or more kinds may be used in combination. Among these, in particular, silica is preferable and fused silica (in particular, spherical fused silica) is preferable from the viewpoint of superior low thermal expansion. The shape thereof may be granular or spherical, and usage may be adopted depending on the purposes, for example, in order to secure impregnating ability for a fiber substrate, spherical fused silica is used for lowering the melt viscosity of the resin composition.

The average particle size of the inorganic filler (B) is not particularly limited, and is preferably 0.1 to 5.0 μm and particularly preferably 0.5 to 2.0 μm (hereinafter, “to” represents an upper limit and a lower limit being included unless specified otherwise). When the particle sizes of the inorganic filler (B) are equal to or greater than the lower limit, the viscosity of a varnish is high and the effect on the workability when manufacturing a prepreg can be reduced. In addition, when the particle sizes are equal to or less than the upper limit, the occurrence of a phenomenon such as the precipitation of the inorganic filler in a varnish can be suppressed. The average particle size can be measured using, for example, an ultrasonic vibration current method (zeta potential), an ultrasonic attenuation spectroscopy (particle size distribution), or a laser diffraction and scattering method. The inorganic filler is dispersed in water with ultrasonic waves, the particle size distribution of particles is measured in terms of volume using a laser diffraction particle size distribution analyzer (manufactured by HORIBA Ltd., LB-550), and a median diameter thereof (D50) is set to the average particle size.

The content of the inorganic filler (B) is not particularly limited, and is preferably 10 to 80% by weight and more preferably 30 to 75% by weight, with respect to the total resin composition. The content is most preferably 40 to 70% by weight. When the content of the inorganic filler (B) is equal to or greater than the lower limit, flame retardancy and low thermal expansion are improved. In addition, when the content of the inorganic filler (B) is equal to or less than the upper limit, the dispersion in resin is difficult and it can be suppressed for particles to be aggregated and for defects to occur.

Furthermore, it is preferable that the inorganic filler (B) be used in combination with an inorganic filler having an average particle size of 10 to 100 nm (hereinafter, sometimes referred to as “the fine particles”). As a result, even when the amorphous inorganic filler is used as the inorganic filler (B), since the fine particles are added thereto, a deterioration in the fluidity of the resin composition can be suppressed. In addition, even when the viscosity of a resin varnish is high, by adding the fine particles to the resin varnish, a substrate can be impregnated with the resin varnish satisfactorily. Furthermore, by using the resin composition containing the fine particles for an insulating layer of a printed wiring board, fine roughness can be formed on a surface of the insulating layer and a printed wiring board having superior fine wiring processability can be obtained.

The average particle size of the fine particles is preferably 15 to 90 nm and more preferably 25 to 75 nm. When the average particle size is in the above-described range, high filling performance and high fluidity can be obtained. The average particle size of the fine particles can be measured using, for example, an ultrasonic vibration current method (zeta potential), an ultrasonic attenuation spectroscopy (particle size distribution), or a laser diffraction and scattering method. Specifically, the average particle size of the fine particles can be defined by D50.

The content of the fine particles is not particularly limited, and is preferably 0.5 to 20% by weight and more preferably 1 to 10% by weight, with respect to the total resin composition. When the content of the fine particles is in the above-described range, particularly the impregnating ability and moldability of a prepreg are superior.

The weight ratio (w2/w1) of the content (w1) of the inorganic filler (B) and the content (w2) of the fine particles is not particularly limited, and is preferably 0.02 to 0.5 and particularly preferably 0.06 to 0.4. When the weight ratio is in the above-described range, particularly moldability can be improved.

When the cyclic siloxane compound (C) has at least two Si—H bonds or two Si—OH bonds, it reacts with the epoxy resin (A) and the inorganic filler (B) so as for these components to be strongly connected to each other and be bonded to each other. Therefore, by adding the cyclic siloxane compound (C) to the resin composition, the strength of a sheet, a laminate, a printed wiring board, or the like obtained from the resin composition can be improved.

The cyclic siloxane compound (c) can use a compound represented by Formula (1) below.

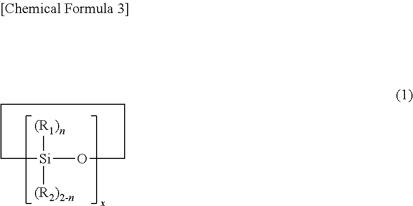

(In the formula, x represents an integer of equal to or more than 2 and equal to or less than 10; n represents an integer of equal to or more than 0 and equal to or less than 2; R₁'s may be the same as or different from each other and represent a substituent having an atom selected from an oxygen atom, a boron atom, and a nitrogen atom; and R₂'s may be the same as or different from each other and represent a hydrogen atom or a saturated or unsaturated hydrocarbon group having 1 to 20 carbon atoms, in which at least two of R₁i's and R₂'s represent a hydrogen atom or a hydroxyl group.)

The cyclic siloxane compound (C) is not particularly limited and it is preferable that the molecular weight thereof be 50 to 1000.

Examples of the saturated or unsaturated hydrocarbon group having 1 to 20 carbon atoms include alkyl groups such as methyl, ethyl, n-propyl, i-propyl, cyclopropyl, n-butyl, i-butyl, sec-butyl, tert-butyl, cyclobutyl, n-pentyl, tert-amyl, cyclopentyl, n-hexyl, cyclohexyl, and 2-ethylhexyl; aryl groups such as phenyl, diphenyl, and naphthyl; arylalkyl groups such as benzyl and methylbenzyl; alkylaryl groups such as o-toluoyl, m-toluoyl, p-toluoyl, 2,3-dimethylphenyl, 2,4-dimethylphenyl, 2,5-dimethylphenyl, 2,6-dimethylphenyl, 3,4-dimethylphenyl, 3,5-dimethylphenyl, 2,4,6-trimethylphenyl, o-ethylphenyl, m-ethylphenyl, and p-ethylphenyl; alkenyl groups such as vinyl, allyl, 1-propenyl, 1-butenyl, 1,3-butadienyl, 1-pentenyl, 1-cyclopentenyl, 2-cyclopentenyl, cyclopentadienyl, methylcyclopentadienyl, ethylcyclopentadienyl, 1-hexenyl, 1-cyclohexenyl, 2,4-cyclohexadienyl, 2,5-cyclohexadienyl, 2,4,6-cycloheptatrienyl, and 5-norbornene-2-yl; arylalkenyl groups such as 2-phenyl-1-ethenyl; alkenylaryl groups such as o-styryl, m-styryl, and p-styryl; alkynyl groups such as ethynyl, 1-propynyl, 2-propynyl, 1-butynyl, 2-butynyl, 3-butynyl, 1-pentynyl, 2-pentynyl, 3-pentynyl, 4-pentynyl, 1-hexynyl, 3-hexynyl, and 5-hexynyl; arylalkynyl groups such as 2-phenyl-1-ethynyl; and alkynylaryl groups such as 2-ethynyl-2-phenyl.

Examples of the cyclic siloxane compound (C) include 1,3,5-trimethylcyclotrisiloxane, 1,3,5,7-tetramethylcyclotetrasiloxane, 1,3,5,7,9-pentamethylcyclopentasiloxane, 1,3,5-triethylcyclotrisiloxane, 1,3,5,7-tetraethylcyclotetrasiloxane, and 1,3,5,7,9-pentaethylcyclopentasiloxane. Particularly preferable examples thereof include 1,3,5-trimethylcyclotrisiloxane, 1,3,5,7-tetramethylcyclotetrasiloxane, and 1,3,5,7,9-pentamethylcyclopentasiloxane.

The cyclic siloxane compound (C) is self-polymerized by having at least two or more reactive Si—H bonds or two or more reactive Si—OH bonds, and can be chemically or physically bonded with the inorganic filler. For example, when the inorganic filler is silica, the cyclic siloxane compound (C) can be react with a silanol group of silica and the inorganic filler can be hydrophobized. By being hydrophobized, even when the inorganic filler is highly filled, the resin composition having high resistance to chemicals such as desmear solution can be obtained. Accordingly, in a through hole or a via hole, there is little case where glass cloth protrudes due to the coming-off of a resin. Therefore, insulating reliability is improved, and when a semi-additive method is used, the peel strength of a plated copper can be improved.

The cage-shape siloxane compound is a compound having a frame structure in which one Si is bonded with at least two or more 0's (oxygen atoms) to form a three-dimensional space, and for example, is represented by Formula (2) below.

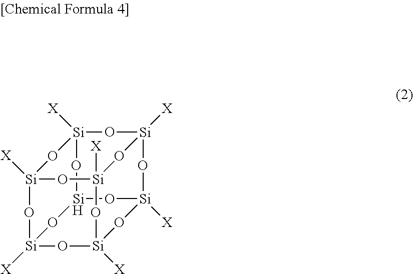

(In the formula, X represents a hydrogen atom, a hydroxyl group, a saturated or unsaturated hydrocarbon group having 1 to 20 carbon atoms, or a substituent having an atom selected from an oxygen atom, a boron atom, a nitrogen atom, and a silicon atom, in which at least two of X's represent a hydrogen atom or a hydroxyl group.)

The cage-shape siloxane compound is not particularly limited and it is preferable that the molecular weight thereof be 50 to 1000.

Examples of the cage-shape siloxane compound include polysilsesquioxane (T8), polysilsesquioxane-hydroxy substitute, polysilsesquioxane-octahydroxy substitute, polysilsesquioxane-(3-glycidyl)propoxy-heptahydroxy substitute, and polysilsesquioxane-(2,3-propanediol)propoxy-heptahydroxy substitute.

The content of the cyclic siloxane compound (C) is not particularly limited, and in the resin composition, is preferably 0.01 to 10% by weight, more preferably 0.1% by weight to 5% by weight, and most preferably 0.2% by weight to 2% by weight. When the content of the cyclic siloxane compound (C) is equal to or greater than the lower limit, the effect of an organic siloxane compound is sufficiently obtained. In addition, when the content of the cyclic siloxane compound (C) is equal to or less than the upper limit, a reduction in the characteristics of a printed wiring board can be suppressed.

The resin composition may further include cyanate resin, and heat resistance and low thermal expansion which cannot be obtained from only epoxy resin can be imparted to the resin composition. The cyanate resin described herein can be obtained by, for example, causing a halogenated cyan compound and a phenol to react with each other and optionally prepolymerizing the resultant with a method such as heating. Specific examples thereof include novolac cyanate resins such as phenol novolac cyanate resin and cresol novolac cyanate resin; bisphenol cyanate resins such as bisphenol A cyanate resin, bisphenol E cyanate resin, and tetramethyl bisphenol F cyanate resin; and dicyclopentadiene cyanate resin. A printed wiring board, obtained from the resin composition using the cyanate resin, is superior in rigidity especially during heating and thus has superior reliability when a semiconductor element is mounted.

The molecular weight of the cyanate resin is not particularly limited, and the weight average molecular weight thereof is preferably 5.0×10² to 4.5×10³ and particularly preferably 6.0×10² to 3.0×10³. When the weight average molecular weight is equal to or greater than the lower limit, stickiness is obtained when manufacturing a prepreg. Accordingly, when prepregs comes into contact with each other, the adhesion therebetween or the transfer of a resin can be suppressed. In addition, the weight average molecular weight is equal to or less than the upper limit, the occurrence of molding defects can be suppressed when a reaction is excessively high, particularly when a laminate is used. The weight average molecular weight of the cyanate resin or the like can be measured using, for example, GPC (gel permeation chromatography, standard materials: polystyrene conversion).

In addition, as the cyanate resin, a prepolymerized resin can be used. The cyanate resin may be used alone, and cyanate resins having different weight average molecular weights may be used in combination or the cyanate resin and a prepolymer thereof may be used in combination. Usually, the prepolymer described herein may be obtained by, for example, trimerizing the cyanate resin through a thermal reaction, and is preferably used for adjusting the moldability and fluidity of the resin composition for a circuit board. The prepolymer is not particularly limited and one having a trimerization ratio of 20 to 50% by weight is preferably used. The trimerization ratio can be obtained using, for example, an infrared spectrometer. In addition, the cyanate resin is not particularly limited. One kind may be used alone; two or more kinds having different weight average molecular weights can be used in combination; one kind or two or more kinds of cyanate resins and a prepolymer thereof can be used in combination.

The content of the cyanate resin is not particularly limited, and is preferably 3 to 70% by weight with respect to the total resin composition. In the above range, the content is preferably 5 to 50% by weight and more preferably 10 to 30% by weight, for example, when a prepreg is formed. When the content of the cyanate resin is equal to or less than the lower limit, the effect of improving heat resistance, obtained by adding the cyanate resin, can be sufficiently obtained. In addition, when the content of the cyanate resin is equal to or less than the upper limit, a deterioration in the strength of a molded product such as a prepreg can be suppressed.

Furthermore, the resin composition may be used in combination with a thermosetting resin (practically, which does not contain halogen). Examples of the thermosetting resin include resins having a triazine ring such as urea resin and melamine resin; unsaturated polyester resin; bismaleimide resin; polyurethane resin; diallyl phthalate resin; silicone resin; and resins having a benzoxazine ring. Among these, one kind may be used alone or two or more kinds may be used in combination.

In the resin composition, phenol resin or a curing accelerator may be optionally used. In addition, phenol resin or a curing accelerator may be used in combination.

The phenol resin is not particularly limited, and examples thereof include novolac phenol resins such as phenol novolac resin, cresol novolac resin, bisphenol A novolac resin, and aryl alkylene novolac resin; and resol phenol resins such as unmodified resol phenol resin and oil-modified resol phenol resin modified by wood oil, linseed oil, walnut oil, and the like. Among these, one kind can be used alone; two or more kinds having different weight average molecular weights can be used in combination; one kind or two or more kinds of the above-described resins and a prepolymer thereof can be used in combination. Among these, aryl alkylene phenol resin is particularly preferable. As a result, resistance to moisture absorption and solder heat can be further improved.

The curing accelerator is not particularly limited, and examples thereof include organometallic salts such as zinc naphthenate, cobalt naphthenate, tin octylate, cobalt octylate, cobalt bis-acetylacetonate (II), and cobalt tris-acetylacetonate (III); tertiary amines such as triethylamine, tributylamine, and diazabicyclo[2,2,2]octane; imidazole compounds; phenol compounds such as phenol, bisphenol A, and nonyl phenol; organic acids such as acetic acid, benzoic acid, salicylic acid, and paratoluenesulfonic acid; and mixtures thereof. Among these, including derivatatives thereof, one kind can be used alone or two or more kinds can be used in combination.

Among these curing accelerators, imidazole compounds are particularly preferable. Accordingly, when the resin composition is used for a prepreg and a semiconductor device, an insulating property and solder heat resistance can be improved.

Examples of the imidazole compound include 2-methylimidazole, 2-phenylimidazole, 1-benzyl-2-methylimidazole, 1-benzyl-2-phenylimidazole, 2-phenyl-4-methylimidazole, 2-ethyl-4-methylimidazole, 2-ethyl-4-ethylimidazole, 2,4-diamino-6-[2′-methylimidazolyl-(1′)]-ethyl-s-triazine, 2,4-diamino-6-(2′-undecylimidazolyl)-ethyl-s-triazine, 2,4-diamino-6-[2′-ethyl-4-methylimidazolyl-(1′)]-ethyl-s-triazine, 2-phenyl-4,5-dihydroxymethylimidazole, 2-phenyl-4-methyl-5-hydroxymethylimidazole, 2-undecylimidazole, 1-cyanoethyl-2-ethyl-4-methylimidazole, 1-cyanoethyl-2-undecylimidazole, 2-phenyl-4-methyl-5-hydroxyimidazole, and 2,3-dihydro-1H-pyrrolo[1,2-a]benzimidazole. Among these, 1-benzyl-2-methylimidazole, 1-benzyl-2-phenylimidazole, and 2-ethyl-4-methylimidazole are preferable. Since these imidazole compounds have especially superior miscibility with a resin component, a cured material having high uniformity can be obtained.

To the resin composition, a resin component which improves the adhesion between the resin composition and a conductor layer may be further added. Examples thereof include phenoxy resin, polyamide resin, and polyvinyl alcohol resin. Among these, it is especially preferable that phenoxy resin be added from the viewpoint of superior adhesion with a metal and less effect on curing reaction rate. Examples of the phenoxy resin include phenoxy resin having a bisphenol structure, phenoxy resin having a novolac structure, phenoxy resin having a naphthalene structure, and phenoxy resin having a biphenyl structure. In addition, phenoxy resin having plural kinds of the above-described structures can be used.

The resin composition is not particularly limited and a coupling agent is used therefor. The coupling agent improves the wettability of the interface between the epoxy resin and the inorganic filler. In addition, the thermosetting resin and the like and the inorganic filler can be uniformly fixed on a fiber substrate and thus heat resistance, in particular, solder heat resistance after moisture absorption can be improved.

The coupling agent is not particularly limited, and specifically, it is preferable that one or more kinds of coupling agents, selected from epoxy silane coupling agent, cationic silane coupling agent, amino silane coupling agent, titanate coupling agent, and silicone oil coupling agent, be used. As a result, the wettability of the interface with the inorganic filler can be improved and thus heat resistance can be further improved.

The amount of the coupling agent added is not particularly limited, and is preferably 0.05 to 3 parts by weight and particularly preferably 0.1 to 2 parts by weight, with respect to 100 parts by weight of the inorganic filler (B). When the content of the coupling agent is equal to or greater than the lower limit, the inorganic filler is sufficiently coated therewith and heat resistance can be improved. When the content of the coupling agent is equal to or less than the upper limit, there is an effect on a reaction and a deterioration in bending strength or the like can be suppressed.

To the resin composition, optionally, additives other than the above-described components such as a pigment, a dye, an antifoaming agent, a leveling agent, an ultraviolet absorber, a foaming agent, an antioxidant, a flame retardant, and an ion scavenger, may be further added.

Next, the prepreg using the first resin composition will be described.

The prepreg is obtained by impregnating a substrate with the first resin composition. As a result, a prepreg, which is preferable for manufacturing a printed wiring board having superior characteristics such as dielectric characteristics and mechanical and electrical connection reliability in a high-temperature and high-humidity environment, can be obtained.

The substrate is not particularly limited, and examples thereof include glass fiber substrates such as glass woven fabric and nonwoven glass fabric; polyamide resin fibers such as polyamide resin fiber, aromatic polyamide resin fiber, and wholly aromatic polyamide resin fiber; polyester resin fibers such as polyester resin fiber, aromatic polyester resin fiber, and wholly aromatic polyester resin fiber; woven or nonwoven synthetic fiber substrates including polyimide resin fiber or fluororesin fiber as a major component; organic fiber substrates such as a paper substrate including kraft pulp, cotton linter paper, or mixed paper of linter and kraft pulp as a major component. Among these, the glass fiber substrates are preferable. As a result, the strength of a prepreg can be improved, water absorption can be reduced, and the coefficient of thermal expansion can be reduced.

Glass constituting the glass fiber substrates is not particularly limited, and examples thereof include E glass, C glass, A glass, S glass, D glass, NE glass, T glass, and H glass. Among these, E glass, T glass, or S glass is preferable. As a result, the elasticity of the glass fiber substrates can increase and the coefficient of thermal expansion can be reduced.

A method of manufacturing the prepreg is not particularly limited, and examples thereof include a method of adjusting a resin varnish using the above-described first resin composition and dipping a substrate in the resin varnish; a coating method using various coaters; and a spraying method using a spray. Among these, the method of dipping a substrate in the resin varnish is preferable. As a result, the impregnating ability of the resin composition for a substrate can be improved. In addition, when a substrate is dipped in the resin varnish, a general impregnation coating machine can be used.

It is preferable that a solvent used for the resin varnish have favorable solubility in the resin components of the first resin composition. However, in a range not having an adverse effect, a poor solvent may be used. Examples of the solvent having the favorable solubility include acetone, methyl ethyl ketone, methyl isobutyl ketone, cyclohexanone, cyclopentanone, tetrahydrofuran, dimethylformamide, dimethylacetamide, dimethyl sulfoxide, ethylene glycol, cellosolves, and carbitols.

The solid content of the resin varnish is not particularly limited, and is preferably 50 to 90% by weight and particularly preferably 60 to 80% by weight, with respect to the solid content of the resin composition. As a result, the impregnating ability of the resin varnish for a substrate can be further improved. When a substrate is impregnated with the resin composition, a predetermined temperature is not particularly limited, and by drying a substrate at, for example, 90 to 220° C., the prepreg can be obtained.

Next, the laminate using the above-described prepreg will be described.

The laminate includes a laminate obtained by laminating at least one or plural layers of the above-described prepreg, a laminate obtained by making metal foil overlap both surfaces or a single surface of the laminate, and a laminate obtained by laminating a prepreg or a resin sheet on both surfaces or a single surface of an inner layer circuit board. The inner layer circuit board described herein is generally referred to as a core substrate used for a printed wiring board and is obtained by forming a conductive circuit on the laminate.

The inner layer circuit board is not particularly limited, and can be manufactured by forming a conductive circuit on the laminate according to the invention or can be manufactured by forming a circuit on a laminate used for a printed wiring board of the related art. When the laminate according to the invention is used, fine wiring processability is superior and electrical reliability is superior even after fine wiring is formed.

A method of manufacturing the laminate is not particularly limited and can be obtained by, for example, laminating the prepreg or the like according to a desired configuration and applying heat and pressure. A temperature for heating is not particularly limited, and is preferably 120 to 230° C. and particularly preferably 150 to 210° C. In addition, a pressure is not particularly limited, and is preferably 1 to 5 MPa and particularly preferably 2 to 4 MPa. As a result, a laminate having superior dielectric characteristics and mechanical and electrical connection reliability in a high-temperature and high-humidity environment can be obtained.

The metal foil is not particularly limited, and examples thereof include metal foils of, for example, copper and copper alloys, aluminum and aluminum alloys, silver and silver alloys, gold and gold alloys, zinc and zinc alloys, nickel and nickel alloys, tin and tin alloys, and iron and iron alloys.

The thickness of the metal foil is not particularly limited, and is preferably equal to or greater than 0.1 μm and equal to or less than 70 μm. The thickness is more preferably equal to or greater than 1 μm and equal to or less than 35 μm and still more preferably equal to or greater than 1.5 μm and equal to or less than 18 μm. When the thickness of the metal foil is equal to or greater than the lower limit, the occurrence of a pinhole can be suppressed. When this metal foil is etched to be used as a conductive circuit, the occurrence of uneven plating when forming a circuit pattern, circuit disconnection, the infiltration of chemicals such as etchant or desmear solution, and the like can be suppressed. When the thickness of the metal foil is equal to or less than the upper limit, it is suppressed for unevenness in the thickness of the metal foil to increase and for unevenness in the surface roughness of a roughened surface of the metal foil to increase.

In addition, as the metal foil, an ultra thin metal foil with carrier foil can be used. The ultra thin metal foil with carrier foil is a metal foil obtained by bonding a peelable carrier foil and an ultra thin metal foil to each other. By using the ultra thin metal foil with carrier foil, an ultra thin metal foil layer can be formed on both surfaces of the insulating layer. Therefore, for example, when a circuit is formed using a semi-additive method, by directly electroplating the ultra thin metal foil as a power supply layer without electroless plating, the ultra thin metal foil can be flash-etched after the circuit is formed. By using the ultra thin metal foil with carrier foil, even with an ultra thin metal foil having a thickness of 10 μm or less, a deterioration in the handleability of the ultra thin metal foil or the cracking or breaking of the ultra thin copper foil can be suppressed in, for example, press process.

In particular, in a case where a resin composition, obtained by adding the fine particles to the epoxy resin (A), the inorganic filler (B), the cyclic siloxane compound (C), is used as the first resin composition, even when the thickness of an ultra-thin metal foil in the ultra thin metal foil with carrier foil is equal to or less than 10 μm, workability is superior and the adhesion between an inner layer circuit and an insulating layer can be improved when the insulating layer is formed after forming the inner layer circuit.

In addition, in the laminate obtained by using the first resin composition, it is preferable that the contact angle between a resin surface and pure water be equal to or less than 85°. When the laminate has the metal foil in the outermost layer, it is preferable that the contact angle between a surface of a resin layer and pure water is equal to or less than 85° after etching the metal foil and performing metal plating. In this embodiment, when a surface of a resin layer of the laminate has high wettability for pure water, this represents that metal attached to the surface is easily removed by cleaning solution such as water. Therefore, by using such a laminate, in processes of manufacturing a printed wiring board, metal attached to a surface of a resin layer can be easily cleaned after plating such as ENEPIG. That is, cleaning characteristics in a non-plated area can be improved. As a result, in a non-plated area on a resin layer, metal included in plating solution can be prevented from diffusing. Therefore, a plated layer where a plated area and a non-plated area are clearly separated can be formed, the short circuit between plated layers can be prevented, and a printed wiring board having superior electrical reliability can be obtained.

In order for the contact angle of the laminate to be set to be equal to or less than 85° after metal plating, for example, the cyclic siloxane compound (C) may be added or the fine particles having an average particle size of 10 to 100 nm and the inorganic filler (B) having an average particle size of 0.1 to 5.0 μm may be used in combination. It is more preferable that the first resin composition contain the cyclic siloxane compound (C), the fine particles, and the inorganic filler (B). In this case, the contact angle can be set to be equal to or less than 80°. As a result, even when a fine-wiring printed wiring board is manufactured, a printed wiring board having superior electrical reliability can be obtained.

The content of the fine particles is not particularly limited, and is preferably 0.5 to 10% by weight with respect to the total first resin composition. In a case where the content of the fine particles is in the range, in particular, even when an epoxy resin, which is solid at room temperature, such as biphenyl epoxy resin or biphenyl aralkyl epoxy resin is used, the impregnating ability and moldability of a prepreg are superior and furthermore the contact angle after metal plating can be set to be equal to or less than 85°. As a result, a printed wiring board having superior electrical reliability can be obtained.

The weight ratio (w2/w1) of the content (w1) of the inorganic filler (B) and the content (w2) of the fine particles is not particularly limited, and is preferably 0.02 to 0.12 and particularly preferably 0.06 to 0.10. In a case where the weight ratio (w1/w2) is in the above-described range, in particular, even when an epoxy resin, which is solid at room temperature, such as biphenyl epoxy resin or biphenyl aralkyl epoxy resin is used, the impregnating ability and moldability of a prepreg are superior and furthermore the contact angle after metal plating can be set to be equal to or less than 85°. As a result, a printed wiring board having superior electrical reliability can be obtained.

Next, the resin sheet will be described.

The resin sheet using the first resin composition is obtained by forming an insulating layer, formed of the first resin composition, on a carrier film or a metal foil. First, the first resin composition is dissolved, mixed, and stirred in an organic solvent such as acetone, methyl ethyl ketone, methyl isobutyl ketone, toluene, ethyl acetate, cyclohexane, heptane, cyclohexanecyclohexanone, tetrahydrofuran, dimethylformamide, dimethylacetamide, dimethyl sulfoxide, ethylene glycol, cellosolves, carbitols, and anisole with various mixing machines such as an ultrasonic dispersion type, a high-pressure collision dispersion type, a high-speed rotating dispersion type, a bead mill type, a high-speed shearing dispersion type, and a planetary dispersion type. As a result, a resin varnish is prepared.

The content of the first resin composition in the resin varnish is not particularly limited, and is preferably 45 to 85% by weight and particularly preferably 55 to 75% by weight.

Next, the resin varnish is coated on a carrier film or a metal foil using various coating machines, followed by drying. Alternatively, the resin varnish is spray-coated on a carrier film or a metal foil using a spray machine, followed by drying. Using these methods, the resin sheet can be manufactured. The coating machine is not particularly limited, and, for example, a roll coater, a bar coater, a knife coater, a gravure coater, a die coater, a comma coater, and a curtain coater can be used. Among these, a method using a die coater, a knife coater, and a comma coater is preferable. As a result, a resin sheet having a uniform thickness of an insulating layer without a void can be efficiently manufactured.

It is preferable that a carrier film having easy handleability be selected because an insulating layer is formed on the carrier film. In addition, it is preferable that the carrier film be easily peeled off after laminating an insulating layer of a resin sheet on an inner layer circuit board because the carrier film is peeled off after laminating the insulating layer on an inner layer circuit board. Therefore, as the carrier film, heat-resistant thermoplastic resin films, for example, polyester resins such as polyethylene terephthalate, polybutylene terephthalate, polyethylene naphthalate, and polybutylene naphthalate, fluororesins, and polyimide resins are preferable. Among these carrier films, a film including polyester is most preferable. As a result, the carrier film can be easily peeled off from an insulating layer with appropriate strength.

The thickness of the carrier film is not particularly limited and is preferably 1 to 100 μm and particularly preferably 10 to 50 μm. When the thickness of the carrier film is in the above-described range, handleability is easy and the flatness of a surface of an insulating layer is superior.

In a similar way to that of the carrier film, a metal foil may be peeled off after laminating a resin sheet on an inner layer circuit board or a metal foil may be etched to be used as a conductive circuit. The metal foil is not particularly limited and for example, the metal foil used for the laminate can be used. In addition, in a similar way to that of the laminate, the metal foil is an ultra thin metal foil in which the carrier foil and the ultra thin metal foil may be equal to or less than 10 μm. No matter which metal foil is used, with a resin sheet obtained from the first resin composition, workability is superior and a fine circuit is formed satisfactorily, thereby suppressing the occurrence of defective continuity or the like in a circuit.

The thickness of the metal foil is not particularly limited, and is preferably equal to or greater than 0.1 μm and equal to or less than 70 μm. The thickness is more preferably equal to or greater than 1 μm and equal to or less than 35 μm and still more preferably equal to or greater than 1.5 μm and equal to or less than 18 μm. When the thickness of the metal foil is equal to or greater than the lower limit, it is difficult for a pinhole to be generated. When this metal foil is etched to be used as a conductive circuit, the occurrence of uneven plating when forming a circuit pattern, circuit disconnection, the infiltration of chemicals such as etchant or desmear solution, and the like can be suppressed. When the thickness of the metal foil is equal to or less than the upper limit, unevenness in the thickness of the metal foil is reduced and unevenness in the surface roughness of a roughened surface of the metal foil is reduced.

Next, the multilayer printed wiring board will be described.

The multilayer printed wiring board is obtained by using the above-described prepreg as an insulating layer. In addition, the multilayer printed wiring board is obtained by using the above-described laminate as an inner layer circuit board.

A case where the laminate is used as an inner layer circuit board will be described.

A circuit is formed on a single surface or both surfaces of the laminate which forms an inner layer circuit board. In some cases, a through hole may be formed through drilling and laser processing to obtain an electrical connection of both surfaces through plating. A commercially available resin sheet or the prepreg according to the invention is made to overlap the inner layer circuit board, followed by applying heat and pressure for molding. As a result, a multilayer printed wiring board can be obtained. Specifically, the multilayer printed wiring board can be obtained by joining an insulating layer side surface of the resin sheet to the inner layer circuit board; applying heat and pressure for molding in a vacuum with a vacuum pressure laminator; and then thermally curing the insulating layer with a hot air drying machine. The conditions for the applying of heat and pressure for molding described herein are not particularly limited. For example, the applying can be performed at a temperature of 60 to 160° C. and a pressure of 0.2 to 3 MPa. In addition, the conditions for thermal curing are not particularly limited. For example, thermal curing can be performed at a temperature of 140 to 240° C. for 30 to 120 minutes.

In addition, the multilayer printed wiring board can be obtained by making the prepreg overlap the inner layer circuit board and applying heat and pressure for molding with a flat press machine or the like. The conditions for the applying of heat and pressure for molding described herein are not particularly limited. For example, the applying can be performed at a temperature of 140 to 240° C. and a pressure of 1 to 4 MPa. In the applying of heat and pressure for molding with a flat press machine or the like, the applying of heat and pressure for molding and the thermal curing of an insulating layer are simultaneously performed.

A method of manufacturing a multilayer printed wiring board includes a process of overlapping and continuously laminating the resin sheet or the prepreg on a surface of the inner layer circuit board where an inner layer circuit pattern is formed; and a process of forming a conductive circuit layer with a semi-additive method.

After an insulating layer formed from the resin sheet or the prepreg is completely cured, laser light can be irradiated thereon or residual resin can be removed. However, in order to improve a desmear property, there are cases where laser light is irradiated thereon or residual resin is removed in a state where the insulating layer is semi-cured. In addition, an insulating layer as a first layer is heated at a temperature lower than a normal heating temperature to be partially cured (semi-cured); on this insulating layer, a single or multiple insulating layers are further formed; and the semi-cured insulating layers are heated to be cured again to a degree where there is practically no problem. As a result, the adhesion between the insulating layers and between the insulating layer and a circuit can be improved. In this case, the temperature of semi-curing is preferably 80° C. to 200° C. and more preferably 100° C. to 180° C. In the subsequent process, an opening is formed in the insulating layer by irradiating laser light. Before that, a substrate is peeled off. In a case where the resin sheet is used, after forming the insulating layer, the carrier film can be peeled off before or after thermal curing without a particular problem.

As the inner layer circuit board used for obtaining the multilayer printed wiring board, for example, an inner layer circuit board, obtained by forming a predetermined conductive circuit on both surfaces of a copper-clad laminate through etching or the like and blackening the conductive circuit, can be preferably used.

Here, regarding the width of a conductive circuit (L) and the interval between conductive circuits (S) (hereinafter, sometimes referred to as “L/S”), L/S of the related art is wide, for example, about 50 μm/50 μm. However, about 25 μm/25 μm is currently being considered, and along with reduction in the size of wiring of recent years, there has been a growing trend for wiring to be narrowed. When the laminate is used as a printed wiring board, fine wiring having an L/S of 15 μm/15 μm or less can be formed. In addition, even when L/S is equal to or less than 15 μm/15 μm, for example, the diffusion of metal can be suppressed after plating such as ENEPIG and the occurrence of defective continuity is suppressed.

Next, the insulating layer is irradiated with laser light to form an opening. Examples of the laser light include excimer laser light, UV laser light, and carbon dioxide laser light.

After irradiating laser light, it is preferable that residual resin and the like be removed using an oxidant such as permanganate or dichromate. In addition, a smooth surface of the insulating layer can be roughened at the same time and the adhesion of a conductive wiring circuit, which is formed through metal plating subsequent thereto, can be improved.

Next, an outer layer circuit is formed. A method of forming an outer layer circuit is to make a connection between insulating resin layers through metal plating and to form an outer layer circuit pattern through etching. In a similar way to the case of using the resin sheet or the prepreg, a multilayer printed wiring board can be obtained.

In addition, when the resin sheet or prepreg having a metal foil is used, in order for the metal foil to be used as a conductive circuit without being peeled off, a circuit may be formed through etching. In this case, when an insulating resin sheet with a substrate using a thick copper foil is used, it is difficult for a circuit pattern with a fine pitch to be formed. Therefore, a 1 to 5 μm-thick ultra thin copper foil may be used or a 12 to 18 μm-thick copper foil may be half-etched to obtain an 1 to 5 μm-thick thin copper foil.

Furthermore, an insulating layer may be laminated to form a circuit in a similar way described above. Next, a solder resist is formed on the outermost layer, a connection electrode portion is exposed such that a semiconductor element can be mounted through exposure and development, metal plating is performed through ENEPIG, and the resultant is cut to a predetermined size. As a result, a multilayer printed wiring board can be obtained.

In the above case, the example using ENEPIG has been described, but other metal plating methods may be used. In an example of using other metal plating methods, it is assumed that a laminate is used in which the contact angle with pure water is equal to or less than 85° after a resin surface (when there is a metal foil on the outermost layer, a resin surface in which the metal foil is etched is used) is metal-plated; and a printed wiring board is manufactured using the laminate. In this case, the diffusion of metal after metal-plating can be suppressed and, even when fine wiring is formed, a printed wiring board having superior electrical reliability can be obtained. Even when other metal plating methods are used, it is preferable that the contact angle of a laminate be equal to or less than 80°. In this case, even when L/S is 10 μm/10 μm, electrical reliability is superior.

Next, the semiconductor device will be described.

A semiconductor element having a solder bump is mounted on the multilayer printed wiring board obtained as above and the connection with the multilayer printed wiring board is made through the solder bump. In addition, a gap between the multilayer printed wiring board and the semiconductor element is filled with a liquid sealing resin or the like and thus a semiconductor device is formed. It is preferable that the solder bump be configured by an alloy of tin, lead, silver, copper, bismuth, and the like.

Regarding a method of connecting a semiconductor element and a multilayer printed wiring board, a connection electrode portion on a substrate and a solder bump of a semiconductor element are aligned using a flip chip bonder or the like; the solder bump is heated to a melting point or higher using an IR reflow machine, a heating plate, and other heating devices; and thus the multilayer printed wiring board and the solder bump are melted and joined to each other. In order to improve connection reliability, a layer of a metal having a relatively low melting point such as solder paste may be formed on the connection electrode portion of the multilayer printed wiring board in advance. Prior to this junction process, the solder bump or a surface layer of the connection electrode portion on the multilayer printed wiring board can be coated with flux to improve connection reliability.

(Second Resin Composition)

Hereinafter, the second resin composition will be described.

In general, a technique in which an adhesion layer is formed between a resin layer and a metal foil which constitutes a substrate to improve adhesion characteristics between the resin layer substrate and the metal foil, is being used. However, for example, in a manufacturing process such as desmear process, there are cases where a surface of the adhesion layer is excessively roughened (hereinafter, referred to as excessive roughening). Therefore, in general techniques using an adhesion layer, there is a room for improvement of adhesion characteristics between a substrate and a metal foil.

In consideration of such points to be improved, as a result of discussion, the present inventors found that, when a surface of a resin layer which is an undercoat layer is excessively roughened, a surface of an adhesion layer thereabove is also excessively roughened. Therefore, the present inventors thought that, by suppressing the excessive roughening of the surface of the resin layer which is an undercoat layer, the excessive roughening of the surface of the adhesion layer thereabove can be suppressed.

As a result of conducting various tests, the present inventors found that it is preferable that the second resin composition contain an epoxy resin (A), an inorganic filler (B), and a cyclic or cage-shape siloxane compound (C) having at least two Si—H bonds or two Si—OH bonds (sometimes abbreviated as the cyclic siloxane compound (C)), and completed the invention.

That is, the cyclic siloxane compound (C) has a reactive group having at least two Si—H bonds or two Si—OH bonds. As a result, the cyclic siloxane compound (C) reacts with the epoxy resin (A) and the inorganic filler (B) and thus these components are strongly connected. Furthermore, cyclic siloxane compounds (C) can be bonded to each other. As a result, a surface of a resin layer configured by the second resin composition has high strength so as to be hydrophobized. As a result, in processes of manufacturing a printed wiring board, a resin layer thereof can absorb less water. In an adhesive layer formed on a surface of such a resin layer, the infiltration of swelling solution and roughening solution in desmear process can be suppressed and thus it is difficult for the surface to be rough. Therefore, according to the invention, in a surface of an adhesive layer, excessive roughening can be suppressed. As a result, the adhesion between the adhesive layer and a conductive film can be improved and thus a printed wiring board and the like having superior reliability can be realized.

In addition, according to the present invention, a laminated base material for a printed wiring board in which the coefficient of thermal expansion is low, processability is superior, a surface of an insulating layer is not roughened more than necessary after desmear process, and the adhesion strength (peel strength) with a conductive circuit is superior; a laminate obtained by bonding the material for a printed wiring board to a substrate; and a printed wiring board and a semiconductor device using the laminate, can be realized.

The second resin composition can use the laminated base material for printed wiring board. Broadly, the second resin composition can be used for a case where a laminated base material for a printed wiring board 10 illustrated in FIG. 1 is used (first embodiment) and a case where a laminated base material for a printed wiring board 11 illustrated in FIG. 2 is used (second embodiment). According to the first embodiment, the laminated base material for a printed wiring board 10 is configured by a laminate obtained by laminating a peel-off sheet 12, an adhesion layer 14, and a resin layer 16. In addition, the laminated base material for a printed wiring board 11 is configured by a laminate obtained by laminating a metal foil 13, the adhesion layer 14, and the resin layer 16. In these laminates, the resin layer 16 is obtained from the second resin composition. The resin layer 16 contains, for example, the epoxy resin (A), the inorganic filler (B), and the cyclic siloxane compound (C). In this embodiment, a case of using three layers will be described, but the invention is not limited thereto.

Hereinafter, regarding the second resin composition, different points from the first resin composition will be described. That is, the epoxy resin (A), the inorganic filler (B), and the cyclic siloxane compound (C) included in the second resin composition are basically the same as those of the first resin composition, but the following points are different.

The total surface area of the inorganic filler (B) included in the resin layer 16 per unit weight is not particularly limited, but it is preferable that the inorganic filler (B) be specified. For example, the total surface area is preferably equal to or greater than 1.8 m²/g and equal to or less than 4.5 m²/g and more preferably equal to or greater than 2.0 m²/g and equal to or less than 4.3 m²/g. As a result, the water absorption of the resin layer 16 can be reduced. The total surface area of the inorganic filler (B) can be calculated according to the following expression.

total surface area (m²/g) of inorganic filler included in resin layer 16 per unit weight=(X(%)/100)×Y (m²/g) Expression

X: Ratio of inorganic filler in resin layer 16 (%)

Y: Specific surface area of inorganic filler (m²/g)

The content of the inorganic filler (B) is not particularly limited, and is preferably 10 to 85% by weight, more preferably 30 to 80% by weight, and most preferably 40 to 70% by weight, with respect to the total resin composition. When the content of the inorganic filler (B) is equal to or greater than the lower limit, flame retardancy and low thermal expansion are improved. In addition, when the content of the inorganic filler (B) is equal to or less than the upper limit, the dispersion in resin is difficult and it can be suppressed for particles to be aggregated and for defects to occur.

The cyclic siloxane compound (C) is not particularly limited and it is preferable that the molecular weight thereof be 5.0×10 to 1.0×10³.

The cage-shape siloxane compound is not particularly limited and it is preferable that the molecular weight thereof be 5.0×10 to 1.0×10³.

Regarding the water absorption of the entire resin layer 16, it is preferable that the water absorption of each resin (water absorption of components of the resin layer from which the inorganic filler (B) is excluded) be equal to or less than 2.5%.

The water absorption of each resin of the resin layer 16 is preferably 1 to 2.3% and more preferably 1 to 2.0%. It is preferable that the lower limit be equal to or greater than 1.3% in the above-described numerical range.

In this range, plating peel strength and insulating reliability are superior. In particular, the insulating reliability between vias when manufacturing a printed wiring board is superior.

When the water absorption of the resin layer is equal to or greater than the lower limit, the second resin composition having a content of the inorganic filler in the above-described range can be obtained. In a laminate obtained from the second resin composition, the coefficient of thermal expansion is low, and the adhesion between an adhesion layer and a plated layer and the like can be improved and furthermore desmearing after laser via drilling is easily performed.

In the resin layer 16, it is preferable that the water absorption of each resin be 1 to 2.5% and 55 to 75% by weight of the inorganic filler be included. As a result, plating peel strength and insulating reliability are superior to those of the related art. In particular, the insulating reliability between vias when manufacturing a printed wiring board is further improved and fine wiring processability is also improved. Specifically, even when the width of a conductive circuit (L) and the interval between conducive circuits (S) are small, that is, when L/S=15 μm/15 μm, a printed wiring board having superior reliability can be obtained.

It is preferable that a third resin composition constituting the adhesion layer 14 contain an epoxy resin. Furthermore, it is more preferable that the third resin composition further contain an aromatic polyamide resin (X) having at least one hydroxyl group (hereinafter, sometimes referred to as “the aromatic polyamide resin (X)); the inorganic filler (B) and/or fine particles; at least one kind of component selected from a group consisting of cyanate ester resin, an imidazole compound, and a coupling agent.

It is preferable that the adhesion resin 14 contain the aromatic polyamide resin (X). As a result, the adhesion strength between the adhesion layer and a conductive circuit is improved. In addition, it is more preferable that the aromatic polyamide resin (X) contains a segment where 4 or more carbon chains having a diene structure are connected. As a result, when the resin sheet or the prepreg is used for manufacturing a multilayer printed wiring board, in desmear process, the aromatic polyamide resin (X) is selectively roughened and thus a finely roughened shape can be formed. In addition, by imparting appropriate flexibility to the insulating layer, the adhesion with a conductive circuit can be improved. In this embodiment, the segment in which carbon chains are connected represents a structural unit having a predetermined structure which is formed through carbon-carbon bonds. In addition, the aromatic polyamide resin (X) having at least one hydroxyl group may include a segment having a butadiene rubber component.

Examples of the aromatic polyamide resin (X) include KAYAFLEX BPAM01 (manufactured by NIPPON KAYAKU Co., Ltd.) and KAYAFLEX BPAM155 (manufactured by NIPPON KAYAKU Co., Ltd.).

It is preferable that the weight average molecular weight (Mw) of the aromatic polyamide resin (X) be equal to or less than 2.0×10⁵. As a result, the adhesion with copper or the like can be obtained. When the weight average molecular weight (Mw) is equal to or less than 2.0×10⁵, a deterioration in the fluidity of the adhesion layer when manufacturing an adhesion layer using the third resin composition can be suppressed. In addition, a deterioration in press molding characteristics or circuit embedding characteristics can be suppressed and a deterioration in solvent solubility can be also suppressed.

It is preferable that the adhesion layer 14 contain fine particles. As the fine particles, particles which can be used for the resin layer are used. That is, as the fine particles, as in the case of the second resin layer, an inorganic filler having an average particle size of 10 to 100 nm can be used. When the adhesion layer 14 contains “the fine particles”, in desmear process, fine convex and concave portions can be easily formed on a surface thereof and the adhesion with plated metal can be improved. Furthermore, since the convex and concave portions on the surface of the adhesion layer 14 after desmear process are fine, a surface of a plated metal layer which is formed on the surface of the adhesion layer 14 is smooth and thus fine processing can be easily performed on the plated metal layer. Therefore, fine wiring can be formed on the plated metal layer.

The average particle size of the fine particles used for the adhesion layer is particularly preferably 15 to 90 nm and most preferably 25 to 75 nm. When the average particle size is in the above-described range, the adhesion layer can contain high content of the filler (filling performance is superior) and the coefficient of liner expansion of the adhesion layer can be reduced.

The content of the fine particles is not particularly limited, and is preferably 0.5 to 25% by weight and more preferably 5 to 15% by weight, with respect to the total third resin composition constituting the adhesion layer 14. When the content is in the above-described range, particularly the impregnating ability and moldability of a prepreg are superior.

The adhesion layer 14 can contain an epoxy resin. The epoxy resin is not particularly limited. The same resin as the epoxy resin (A) included in the resin layer 16 can be used.

Among these, from the viewpoint of low water absorption, it is preferable that biphenyl aralkyl epoxy resin, naphthalene aralkyl epoxy resin, and dicyclopentadiene epoxy resin be included.

When the amount of the total adhesion layer 14 other than the inorganic fillers (the inorganic filler (B) and the fine particles) is set to 100% by weight, 10 to 90% by weight and preferably 25 to 75% by weight of the epoxy resin can be included. When the content of the epoxy resin is equal to or greater than the lower limit, a deterioration in the curability of the third resin composition or a deterioration in the moisture resistance of the obtained product can be suppressed. When the content of the epoxy resin is set to be equal to or less than the upper limit, a deterioration in low thermal expansion and moisture resistance can be suppressed. That is, when the content of the epoxy resin is in the above-described range, these characteristics can be well-balanced.

The equivalent ratio of the active hydrogen equivalent of the aromatic polyamide resin to the epoxy equivalent of the epoxy resin is equal to or greater than 0.02 and equal to or less than 0.2. When the equivalent ratio is equal to or less than the upper limit, the aromatic polyamide resin (X) can be sufficiently cross-linked with the epoxy resin and heat resistance can be improved. When the equivalent ratio is equal to or greater than the lower limit, a deterioration in the fluidity or the press moldability of the adhesion layer 14 due to excessively high curing reactivity can be suppressed.

The adhesion layer 14 can contain cyanate ester resin. As the cyanate ester resin, the same resin as the cyanate ester resin included in the resin layer 16 can be used.

The content of the cyanate ester resin is preferably 10 to 90% by weight and particularly preferably 25 to 75% by weight, with respect to the total adhesion layer 14 other than the inorganic fillers (the inorganic filler (B) and the fine particles). When the content is equal to or greater than the lower limit, a deterioration in the formability of the adhesion layer 14 can be suppressed. When the content is equal to or less than the upper limit, a deterioration in the strength of the adhesion layer 14 can be suppressed.

Optionally, the adhesion layer 14 may contain a curing accelerator. Examples of the curing accelerator include imidazole compounds; organometallic salts such as zinc naphthenate, cobalt naphthenate, tin octylate, cobalt octylate, cobalt bis-acetylacetonate (II), and cobalt tris-acetylacetonate (III); tertiary amines such as triethylamine, tributylamine, and diazabicyclo[2,2,2]octane; phenol compounds such as phenol, bisphenol A, and nonyl phenol; organic acids such as acetic acid, benzoic acid, salicylic acid, and paratoluenesulfonic acid; and mixtures thereof. Among these including derivatives thereof, one kind can be used alone or two or more kinds can be used in combination.

Among these curing accelerators, imidazole compounds are particularly preferable. As a result, resistance to moisture absorption and solder heat can be further improved. The imidazole compounds have characteristics of being dissolved practically at the molecular level or being dispersed in a state close to the molecular level when being dissolved in an organic solvent with the cyanate ester resin and the epoxy resin.

By using the imidazole compound, a reaction of the cyanate ester resin and the epoxy resin can be effectively accelerated. In addition, even when the amount of the imidazole compound is small, the same characteristics can be imparted. Furthermore, the third resin composition using the imidazole compound can be cured with high uniformity from the microscopic matrix unit between the imidazole compound and resin components. As a result, the insulating property and heat resistance of the adhesion layer 14 which is formed on a multilayer printed wiring board can be improved.

In addition, in the adhesion layer 14, when a surface thereof is roughened using an oxidant such as permanganate or dichromate, plural small convex and concave shapes with high uniformity can be formed on a surface of an insulating layer after roughening.

When metal plating is performed on the surface of the insulating resin layer after roughening, the smoothness of the roughened surface is high and thus a fine conductive circuit can be accurately formed. In addition, due to the small convex and concave shapes, an anchor effect can be improved and high adhesion can be imparted between the insulating resin layer and a plated metal.

Examples of the imidazole compound include 1-benzyl-2-methylimidazole, 1-benzyl-2-phenylimidazole, 2-phenyl-4-methylimidazole, 2-ethyl-4-methylimidazole, 2,4-diamino-6-[2′-methylimidazolyl-(1′)]-ethyl-s-triazine, 2,4-diamino-6-(2′-undecylimidazolyl)-ethyl-s-triazine, 2,4-diamino-6-[2′-ethyl-4-methylimidazolyl-(1′)]-ethyl-s-triazine, 2-phenyl-4,5-dihydroxymethylimidazole, and 2-phenyl-4-methyl-5-hydroxymethylimidazol.

Among these, it is preferable that the imidazole compound be selected from 1-benzyl-2-methylimidazole, 1-benzyl-2-phenylimidazole, and 2-ethyl-4-methylimidazole. Since the imidazole compound has particularly superior miscibility and a cured material having high uniformity can be obtained, and since a fine and uniform roughened surface can be formed, a fine conductive circuit can be easily formed. In addition, a multilayer printed wiring board can exhibit high heat resistance.

The content of the imidazole compound is not particularly limited, and is preferably 0.01 to 5.00% by weight and particularly preferably 0.05 to 3.00% by weight, with respect to the total amount of the cyanate ester resin and the epoxy resin. As a result, in particular, heat resistance can be improved.

It is preferable that the adhesion layer 14 further contain a coupling agent. The coupling agent is not particularly limited, and for example, silane, titanate, and aluminum coupling agents may be used. Examples thereof include amino silane compounds such as N-phenyl-3-aminopropyltrimethoxysilane, 3-aminopropyltrimethoxysilane, 3-aminopropyltriethoxysilane, 3-(2-aminoethyl)aminopropyltrimethoxysilane, 3-(2-aminoethyl)aminopropyltriethoxysilane, 3-anilinopropyltrimethoxysilane, 3-anilinopropyltriethoxysilane, N-β-(N-vinylbenzylaminoethyl)-3-aminopropyltrimethoxysilane, and N-β-(N-vinylbenzylaminoethyl)-3-aminopropyltriethoxysilane; epoxy silane compounds such as 3-glycidoxypropyltrimethoxysilane, 3-glycidoxypropyltriethoxysilane, and 2-(3,4-epoxycyclohexyl)ethyltrimethoxysilane; and other coupling agents such as 3-mercaptopropyltrimethoxysilane, 3-mercaptopropyltriethoxysilane, 3-ureidopropyltrimethoxysilane, 3-ureidopropyltriethoxysilane, and 3-methacryloxypropyltrimethoxysilane. Among these, one kind can be used alone or two or more kinds can be used in combination. By using the coupling agent, the wettability of the interface between the cyanate ester resin, the epoxy resin, and the inorganic filler can be improved. As a result, heat resistance and, in particular, resistance to moisture absorption and solder heat can be improved.

The content of the coupling agent is not particularly limited, and is preferably 0.05 to 5.00% by weight, with respect to 100% by weight of the inorganic fillers (the inorganic filler (B) and the fine particles). In particular, it is more preferable that the content be 0.01 to 2.5% by weight. When the content of the coupling agent is equal to or greater than the lower limit, the effect of coating the inorganic fillers and improving heat resistance is sufficiently obtained. When the content of the coupling agent is equal to or less than the upper limit, a deterioration in the bending strength of the insulating layer 16 can be suppressed. That is, when the content of the coupling agent is in the above-described range, these characteristics can be well-balanced.

In addition, in order to improve various characteristics such as the miscibility of resin, stability, and workability, to the third resin composition, various additives such as a leveling agent, an antifoaming agent, an antioxidant, a pigment, a dye, an antifoaming agent, a flame retardant, an ultraviolet absorber, an ion scavenger, an unreactive diluent, a reactive diluent, a thixotropic agent, and a thickener may be appropriately added.

Hereinafter, modifications of the laminated base material for printed wiring board 10 according to this embodiment will be described.

In the laminated base material for printed wiring board 10 according to this embodiment, the adhesion layer 14 and the resin layer 16 which constitutes an insulating layer of a printed wiring board are laminated on a support substrate (peel-off sheet 12) in this order. In the resin layer 16, the water absorption of a cured material other than the inorganic fillers (the inorganic filler (B) and the fine particles) is 1 to 2.5%. In addition, when the amount of the resin layer 16 is set to 100% by weight, it is preferable that 55 to 75% by weight of the inorganic fillers be included. The water absorption of a cured material of the resin layer 16 is preferably 1 to 2.3% and more preferably 1 to 2.0%. It is preferable that the lower limit be equal to or greater than 1.3% in the above-described numerical range.

The present inventors found that the adhesion has a relation with the water absorption of a cured material constituting the insulating layer other than the inorganic fillers, not with the water absorption of the total resin layer. As a result of vigorous study based on the findings, the present inventors found that, even when an insulating layer contains the inorganic fillers in an amount that can maintain low thermal expansion, by making the water absorption of a cured material of the insulating layer fall within a predetermined range, the adhesion between an adhesion layer and a plated metal layer and the like can be improved, and completed the present invention.

When the water absorption of a cured material of the resin layer 16 is equal to or greater than the lower limit, the content of the inorganic fillers is in the above-described range. Therefore, the low thermal expansion of the insulating layer and the adhesion between an adhesion layer and a plated layer and the like can be improved. Furthermore, desmearing after laser via drilling is easily performed.

The water absorption of a cured material of the insulating layer 16 can be obtained by measuring the water absorption of the total resin layer 16, converting it in terms of the ratio of the inorganic fillers, and calculating the water absorption of a cured material other than the inorganic fillers. Specifically, the water absorption of a cured material of the insulating layer 16 can be measured as follows.

A cured resin sheet including a 90 μm-thick adhesion layer 14 is cut to 50 mm² to obtain samples; the weight of a sample after being left to stand for 2 hours in a drying machine at 120° C. and the weight of a sample after being left to stand for 2 hours in a bath at 121° C. and a humidity of 100% are respectively measured, and the water absorption of a cured material constituting the resin layer 16 can be obtained according to the following expression.

water absorption of cured material constituting resin layer 16=((B−A)/A)×100×(100/(100−X)) Expression

A: weight (mg) of sample after being left to stand for 2 hours in drying machine at 120° C.

B: weight (mg) of sample after being left to stand for 2 hours in bath at 121° C. and humidity of 100%

X: % by weight (%) of inorganic fillers of resin layer 16 (100% by weight)

Furthermore, when the amount of the resin layer 16 is set to 100% by weight, the resin layer 16 can contain preferably 60 to 75% by weight and more preferably 60 to 70% by weight of the inorganic fillers. In this embodiment, the water absorption and the content of the inorganic fillers can be appropriately set in the above-described numerical ranges.

That is, when the resin layer 16 satisfies all of the water absorption and the content of the inorganic fillers which are described above, the coefficient of thermal expansion of the resin layer 16 can be reduced and furthermore the adhesion with a plated metal layer and the like which is formed on the adhesion layer 14 is also superior. Therefore, according to the laminated base material for a printed wiring board 10 of this embodiment, there can be provided a metal-clad laminate and a printed wiring board in which mounting reliability and connection reliability are superior and the adhesion with a metal pattern and the like is also superior; and a semiconductor device obtained by mounting a semiconductor element to this printed wiring board.

In the resin layer 16, as described above, the water absorption of a cured material is 1 to 2.5% and 55 to 75% by weight of the inorganic filler (B) is included.

In addition, from the viewpoint of balancing the low thermal expansion of the resin layer 16 and the improvement of the adhesion with a metal plated layer and the like which is formed on the adhesion layer 14 well, it is preferable that the resin layer 16 contain the inorganic filler (B), the epoxy resin (A), and the cyanate ester resin (D) and it is more preferable that resin layer 16 further contain the cyclic siloxane compound (C) and the curing accelerator (E).

Hereinafter, the respective components will be described.

(Inorganic Filler (B))

As the inorganic filler (B), the above-described examples can be used. Among these, in particular, silica is preferable and fused silica is preferable from the viewpoint of superior low thermal expansion. In addition, there are granular and spherical silicas, but spherical silica is preferable from the viewpoint of lowering the melt viscosity of the resin composition.

Furthermore, in the spherical silica, it is preferable that a surface thereof be treated with a treatment agent in advance. It is preferable that the treatment agent be at least one or more kinds of compounds selected from a group consisting of functional group-containing silanes, cyclic oligosiloxanes, organohalosilanes, and alkylsilazanes.

In addition, the surface treatment of the spherical silica using organohalosilanes and alkylsilazanes among the treatment agents is preferable for hydrophobizing a surface of silica and is preferable from the viewpoint of superior dispersion of the spherical silica in the resin composition. When general functional group-containing silanes are used in combination with the organohalosilanes or the alkylsilazanes, any treatment agent may be used first for the surface treatment. However, it is preferable that the organohalosilanes or the alkylsilazanes be dispersed first because organophilic properties are imparted to the surface of the spherical silica and the subsequent surface treatment of functional group-containing silanes is made effective. It is preferable that the ratio of the amounts of the general functional group-containing silanes and the organohalosilanes or the alkylsilazanes used herein be 500/1 to 50/1 (weight ratio). When the ratio is out of the above-described range, there are cases where mechanical strength deteriorates.

Examples of the functional group-containing silanes include epoxy silane compounds such as 3-glycidoxypropyltrimethoxysilane, 3-glycidoxypropyltriethoxysilane, 3-glycidoxypropylmethyldiethoxysilane, and 2-(3,4-epoxycyclohexyl)ethyldimethoxysilane; (meth)acrylsilanes such as 3-methacryloxypropyltrimethoxysilane, 3-methacryloxypropylmethyldimethoxysilane, 3-methacryloxypropyltriethoxysilane, and 3-methacryloxypropylmethyldiethoxysilane; mercaptosilanes such as 3-mercaptopropyltrimethoxysilane, 3-mercaptopropyltriethoxysilane, and 3-mercaptopropylmethyldimethoxysilane; aminosilanes such as N-phenyl-3-aminopropyltrimethoxysilane, 3-aminopropyltrimethoxysilane, 3-aminopropyltriethoxysilane, N-2(aminoethyl)-3-aminopropyltrimethoxysilane, N-2(aminoethyl)-3-aminopropyltriethoxysilane, N-2(aminoethyl)-3-aminopropylmethyldimethoxysilane, 3-triethoxysilyl-N-(1,3-dimethyl-butylidene)propylamine, and N-(vinylbenzyl)-2-aminoethyl-3-aminopropyltrimethoxysilane; vinylsilanes such as vinyltriethoxysilane, vinyltrimethoxysilane, and vinyltrichlorosilane; isocyanatesilanes such as 3-isocyanatepropyltriethoxysilane; ureidosilanes such as 3-ureidopropyltrimethoxysilane and 3-ureidopropyltriethoxysilane; (5-norbornene-2-yl)alkylsianes such as (5-norbornene-2-yl)trimethoxysilane, (5-norbornene-2-yl)triethoxysilane, and (5-norbornene-2-yl)ethyltrimethoxysilane; and phenylsilanes such as phenyltrimethoxysilane. These functional group-containing silanes are preferably selected in order to improve the dispersibility of the inorganic filler (A) and to maintain the minimum dynamic viscosity of the resin composition to be equal to or less than 4000 Pa·s.

Examples of the cyclic oligosiloxanes include hexamethylcyclotrisiloxane and octamethylcyclotetrasiloxane.

Examples of the organohalosilanes include trimethylchlorosilane, dimethyldichlorosilane, and methyltrichlorosilane. Among these, dimethyldichlorosilane is more preferable.

Examples of the alkylsilazanes include hexamethyldisilazane, 1,3-divinyl-1,1,3,3-tetramethyldisilazane, octamethyltrisilazane, and hexamethylcyclotrisilazane. Among these, hexamethyldisilazane is more preferable.

As a method of using the spherical silica first as the surface treatment agent, a well-known method can be used. For example, spherical silica is put into a mixer and the treatment agent is sprayed under stirring in a nitrogen atmosphere, followed by being held at a predetermined temperature for a predetermined time. The treatment agent to be sprayed may be dissolved in a solvent in advance. In addition, after the spherical silica and the treatment agent are put into a mixer, a solvent may be further added thereto and stirred. In addition, in order to accelerate a reaction of silanol and a coupling agent on a surface of silica, heating may be performed, a small amount of water may be added, or acid and alkali may be used.

The temperature during the treatment depends on the kind of the treatment agent and it is necessary that the treatment be performed at a temperature equal to or lower than a decomposition temperature of the treatment agent. In addition, when the treatment temperature is excessively low, the bonding force between the treatment agent and the spherical silica is low and thus the effect of the treatment cannot be obtained. Accordingly, it is necessary that the treatment be performed at an appropriate temperature corresponding to the treatment agent. Furthermore, the holding time is appropriately adjusted according to the kind or the treatment temperature of the treatment agent.

It is preferable that the average particle size of the inorganic filler (B) be 0.01 to 5 μm. It is more preferable that the average particle size be 0.1 to 2 μm. When the average particle size of the inorganic filler (B) is equal to or greater than the lower limit, when manufacturing a resin varnish using the second resin composition, the viscosity of the resin varnish is reduced. Therefore, an effect on the workability when manufacturing a laminated base material for a printed wiring board can be reduced. On the other hand, when the average particle size of the inorganic filler (B) is equal to or less than the upper limit, the occurrence of a phenomenon such as the precipitation of the inorganic filler (B) in a resin varnish can be suppressed. When the average particle size of the inorganic filler (B) is in the above-described range, these characteristics can be well-balanced.

In addition, as the inorganic filler (B), inorganic fillers having a monodisperse average particle size or inorganic fillers having a polydisperse average particle size can be used. Furthermore, among the inorganic fillers having a monodisperse and/or polydisperse average particle size, one kind can be used alone or two or more kinds can be used in combination.

The content of the inorganic filler (B) is 55 to 75% by weight with respect to the total resin layer 16 (100% by weight) and the coefficient of thermal expansion of the resin layer 16 can be adjusted to be 10 ppm to 35 ppm.

Regarding the inorganic filler (B), the total surface area of the inorganic filler (B) included in the resin layer 16 per unit weight is 1.8 m²/g to 4.5 m²/g and preferably 2.0 m²/g to 4.3 m²/g. The total surface area of the inorganic filler (B) can be calculated according to the following expression.

total surface area (m²/g) of inorganic filler (B) included in resin layer 16 per unit weight=(X(%)/100)×Y (m²/g)

X: Ratio of inorganic filler in resin layer 16 (%)

Y: Specific surface area of inorganic filler (m²/g)

In this embodiment, the water absorption of a cured material of the insulating layer 16 is in the predetermined range and thus the adhesion between the adhesion layer 14 and a plated metal layer and the like can be improved. Furthermore, the total surface area of the inorganic filler (B) is in the above-described range, and thus the adhesion between the adhesion layer 14 and a plated metal layer and the like, the moldability of the adhesion layer 14, and furthermore insulating reliability are well-balanced.

(Epoxy Resin (A))

As the epoxy resin (A), the above-described resins can be used.

Among these, from the viewpoint of lowering the water absorption of the resin layer 16 and setting the water absorption of a cured material within the predetermined range, it is preferable that biphenyl aralkyl epoxy resin, naphthalene aralkyl epoxy resin, and dicyclopentadiene epoxy resin be included and it is more preferable that dicyclopentadiene epoxy resin be included.

When the total resin layer 16 other than the inorganic filler (B) is set to 100% by weight, 10 to 90% by weight and preferably 25 to 75% by weight of the epoxy resin (A) can be included. When the content is equal to or greater than the lower limit, a deterioration in the curability of the second resin composition or a deterioration in the moisture resistance of the obtained product can be suppressed. When the content is equal to or less than the upper limit, low thermal expansion and heat resistance can be suppressed. Therefore, from the viewpoint of balancing these characteristics well, the above-described ranges are preferable.

(Cyanate Ester Resin (D))

As the cyanate ester resin, for example, resins by causing a halogenated cyan compound and a phenol to react with each other and optionally prepolymerizing the resultant with a method such as heating. Specific examples thereof include novolac cyanate resins; bisphenol cyanate resins such as bisphenol A cyanate resin, bisphenol E cyanate resin, and tetramethyl bisphenol F cyanate resin; and dicyclopentadiene cyanate resins. Among these, novolac cyanate resins are preferable. As a result, heat resistance can be improved.

Furthermore, as the cyanate ester resin (D), resins obtained by prepolymerizing the above-described resins can be used. That is, the cyanate resin may be used alone, and cyanate resins having different weight average molecular weights may be used in combination or the cyanate resin and a prepolymer thereof may be used in combination.

Usually, the prepolymer described herein may be obtained by, for example, trimerizing the cyanate resin through a thermal reaction, and is preferably used for adjusting the moldability and fluidity of the resin composition. When the prepolymer having a trimerization ratio of, for example, 20 to 50% by weight is used, satisfactory moldability and fluidity can be exhibited.

Furthermore, in the cyanate ester resin (D), it is preferable that the viscosity at 80° C. be 15 to 550 mPa·s. This is for forming an insulating resin layer on an inner layer circuit pattern with high flatness when applying heat and pressure and laminating in a vacuum and for maintaining miscibility with other components such as the epoxy resin. When the viscosity is greater than the upper limit, there is a concern that the flatness of a surface of an insulating resin layer may deteriorate. When the viscosity is less than the lower limit, miscibility deteriorates and there is a concern that separation and bleeding may occur when laminating.

The content of the cyanate ester resin (D) is preferably 10 to 90% by weight and particularly preferably 25 to 75% by weight, with respect to the total resin layer 16 other than the inorganic filler (B). When the content is less than the lower limit, there are cases where it is difficult for an insulating resin layer to be formed, and when the content is greater than the upper limit, there are cases where the strength of an insulating resin layer deteriorates. Therefore, from the viewpoint of balancing these characteristics well, the above-described range is preferable.

(Cyclic Siloxane Compound (C))

As the cyclic siloxane compound (C), the above-described cyclic or cage-shape siloxane compound (C) having at least two Si—H bonds or two Si—OH bonds can be used.

By having at least two Si—H bonds or two Si—OH bonds, cyclic siloxane compounds are bonded to each other. Furthermore, by coating a filler or a filler and a resin interface, the strength of a laminated base material for a printed wiring board can be improved and furthermore low water absorption can be realized due to hydrophobing.

As the cyclic siloxane compound, the above-described compounds can be used.

As the cage-shape siloxane compound, the above-described compounds can be used, and examples thereof include polysilsesquioxane (T8), polysilsesquioxane-hydroxy substituent, polysilsesquioxane-octahydroxy substituent, polysilsesquioxane-(3-glycidyl)propoxy-heptahydroxy substituent, and polysilsesquioxane-(2,3-propanediol)propoxy-heptahydroxy substituent.

In this embodiment, in addition to the cyclic or cage-shape siloxane compound, a coupling agent can be used. The coupling agent is not particularly limited, and for example, silane, titanate, and aluminum coupling agents may be used. Examples thereof include amino silane compounds such as N-phenyl-3-aminopropyltrimethoxysilane, 3-aminopropyltrimethoxysilane, 3-aminopropyltriethoxysilane, 3-(2-aminoethyl)aminopropyltrimethoxysilane, 3-(2-aminoethyl)aminopropyltriethoxysilane, 3-anilinopropyltrimethoxysilane, 3-anilinopropyltriethoxysilane, N-β-(N-vinylbenzylaminoethyl)-3-aminopropyltrimethoxysilane, and N-β-(N-vinylbenzylaminoethyl)-3-aminopropyltriethoxysilane; epoxy silane compounds such as 3-glycidoxypropyltrimethoxysilane, 3-glycidoxypropyltriethoxysilane, and 2-(3,4-epoxycyclohexyl)ethyltrimethoxysilane; and other coupling agents such as 3-mercaptopropyltrimethoxysilane, 3-mercaptopropyltriethoxysilane, 3-ureidopropyltrimethoxysilane, 3-ureidopropyltriethoxysilane, and 3-methacryloxypropyltrimethoxysilane. Among these, one kind can be used alone or two or more kinds can be used in combination.

By using the coupling agent, the wettability of the interface between the epoxy resin (A), the cyanate ester resin (D), and the inorganic filler can be improved. As a result, heat resistance and, in particular, resistance to moisture absorption and solder heat can be improved.

The content of the cyclic siloxane compound (C) is not particularly limited, and is preferably 0.05 to 5.00 parts by weight, with respect to 100 parts by weight of the inorganic filler (B). In particular, it is more preferable that the content be 0.1 to 2.5 parts by weight. When the content of the cyclic siloxane compound (C) is less than the lower limit, the effect of coating the inorganic filler and improving heat resistance is not sufficiently obtained. On the other hand, when the content is greater than the upper limit, there are cases where the bending strength of an insulating layer deteriorates. That is, when the content of the coupling agent is in the above-described range, these characteristics can be well-balanced.

(Curing Accelerator (E))

Specific examples of the curing accelerator (E) include phosphorus atom-containing compounds such as organic phosphine, a tetra-substituted phosphonium compound, a phosphobetaine compound, an adduct of a phosphine compound and a quinone compound, an adduct of a phosphonium compound and a silane compound; and nitrogen atom-containing compounds such as 1,8-diazabicyclo(5,4,0)undecene-7, benzyldimethylamine, and 2-methylimidazole.

Among these, from the viewpoint of curability, phosphorus atom-containing compounds are preferable, and from the viewpoint of balancing fluidity and curability well, latent catalysts such as a tetra-substituted phosphonium compound, a phosphobetaine compound, an adduct of a phosphine compound and a quinone compound, and an adduct of a phosphonium compound and a silane compound are more preferable. In consideration of fluidity, a tetra-substituted phosphonium compound is particularly preferable; from the viewpoint of soldering resistance, a phosphobetaine compound and an adduct of a phosphine compound and a quinone compound are particularly preferable; and in consideration of latent curability, an adduct of a phosphonium compound and a silane compound is particularly preferable. In addition, from the viewpoint of moldability, a tetra-substituted phosphonium compound is preferable.

Examples of the organic phosphine include primary phosphines such as ethylphosphine and phenylphosphine; secondary phosphines such as dimethylphosphine and diphenylphosphine; and tertiary phosphines such as trimethylphosphine, triethylphosphine, tributylphosphine, and triphenylphosphine.

An example of the tetra-substituted phosphonium compound includes a compound represented by Formula (3) below is used.

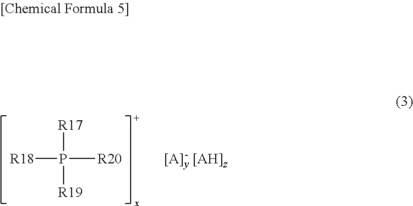

In Formula (3), P represents a phosphorus atom; R17, R18, R19, and R20 each independently represent an aromatic group or an alkyl group; A represents an anion of an aromatic organic acid having at least one functional group selected from a hydroxyl group, a carboxyl group, and a thiol group in an aromatic ring; AH represents an aromatic organic acid having at least one functional group selected from a hydroxyl group, a carboxyl group, and a thiol group in an aromatic ring; x and y represent an integer of 1 to 3; z represents an integer of 0 to 3; and x=y.

The compound represented by Formula (3) can be obtained, for example, as follows, but is not limited thereto. First, tetra-substituted phosphonium halide, an aromatic organic acid, and a base are uniformly mixed in an organic solvent to generate an aromatic organic acid anion in the solvent system thereof. Next, when water is added thereto, the compound represented by Formula (3) can be precipitated. In the compound represented by Formula (3), from the viewpoint of the balancing yield and a curing accelerating effect during synthesis well, it is preferable that R17, R18, R19, and R20 which are bonded to a phosphorus atom represent a phenyl group, AH represent a compound having a hydroxyl group in an aromatic ring, that is a phenol compound, and A represent an anion of the phenol compound. An example of the phosphobetaine compound includes a compound represented by Formula (4) below.

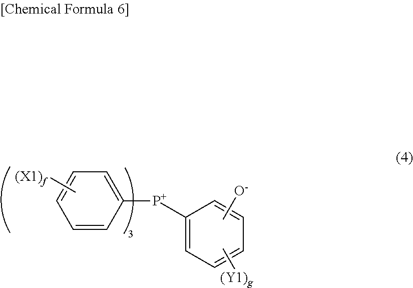

In Formula (4), X1 represents an alkyl group having 1 to 3 carbon atoms, Y1 represents a hydroxyl group, f represents an integer of 0 to 5, and g represents an integer of 0 to 4.

The compound represented by Formula (4) can be obtained, for example, as follows. The compound is obtained through a process in which triaromatic-substituted phosphine, which is a tertiary phosphine, is brought into contact with a diazonium salt to substitute the triaromatic-substituted phosphine with a diazonium group included in the diazonium salt. However, the invention is not limited thereto.

An example of the adduct of a phosphine compound and a quinone compound includes a compound represented by Formula (5) below.

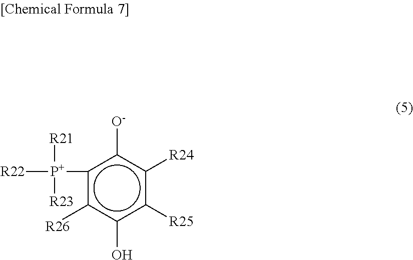

In Formula (5), P represents an phosphorus atom; R21, R22, and R23 each independently represent an alkyl group having 1 to 12 carbon atoms or an aryl group having 6 to 12 carbon atoms; R24 R25, and R26 each independently represent a hydrogen atom or a hydrocarbon group having 1 to 12 carbon atoms; and R24 and R25 may be bonded to each other to form a ring.

As the phosphine compound used for the adduct of a phosphine compound and a quinone compound, compounds in which there is no substituent or an substituent such as an alkyl group or an alkoxyl group in an aromatic ring such as triphenylphosphine, tris(alkylphenyl)phosphine, tris(alkoxyphenyl) phosphine, trinaphthylphosphine, or tris(benzyl)phosphine are preferable, in which the substituent such as an alkyl group or an alkoxyl group have, for example, 1 to 6 carbon atoms. From the viewpoint of availability, triphenylphosphine is preferable.

As the quinone compound used for the adduct of a phosphine compound and a quinone compound, for example, o-benzoquinone, p-benzoquinone, and anthraquinones are used. Among these, from the viewpoint of preservation stability, p-benzoquinone is preferable.

As a method of preparing the adduct of a phosphine compound and a quinone compound, the adduct can be obtained by brining an organic tertiary phosphine and a benzoquinone into contact with each other and mixing them in a solvent in which both of them are soluble. As the solvent, ketones such as acetone or methyl ethyl ketone having low solubility in the adduct are preferable. However, the invention is not limited thereto.

In the compound represented by Formula (5), a compound in which R21, R22, and R23 which are bonded to a phosphorus atom represent a phenyl group and R24, R25, and R26 represent a hydrogen atom, that is, a compound to which 1,4-benzoquinone and triphenylphosphine are added is preferable from the viewpoint of lowering the hot elastic modulus of a cured material of a semiconductor-sealing resin composition.

An example of the adduct of a phosphonium compound and a silane compound includes a compound represented by Formula (6) below.

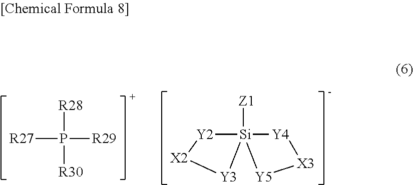

In Formula (6), P represents a phosphorus atom and Si represents a silicon atom. R27, R28, R29, and R30 each independently represent an organic group having an aromatic ring or a heterocyclic ring or an aliphatic group and X2 represents an organic group which bonds groups Y2 and Y3 to each other. X3 represents an organic group which bonds groups Y4 and Y5 to each other. Y2 and Y3 represent a group obtained by emitting a proton from a proton-donating group and the groups Y2 and Y3 in the same molecule are bonded with a silicon atom to form a chelate structure. Y4 and Y5 represent a group obtained by emitting a proton from a proton-donating group and the groups Y4 and Y5 in the same molecule are bonded with a silicon atom to form a chelate structure. X2 and X3 may be the same as or different from each other and Y2, Y3, Y4, and Y5 may be the same as or different from each other. Z1 represents an organic group having an aromatic ring or a heterocyclic ring or an aliphatic group.

In Formula (6), examples of R27, R28, R29, and R30 include a phenyl group, a methylphenyl group, a methoxyphenyl group, a hydroxyphenyl group, a naphthyl group, a hydroxynaphthyl group, a benzyl group, a methyl group, an ethyl group, a n-butyl group, a n-octyl group, and a cyclohexyl group. Among these, an aromatic group having a substituent or an unsubstituted aromatic group such as a phenyl group, a methylphenyl group, a methoxyphenyl group, a hydroxyphenyl group, or a hydroxynaphthyl group is more preferable.

In addition, in Formula (6), X2 represents an organic group which bonds groups Y2 and Y3 to each other. Likewise, X3 represents an organic group which bonds groups Y4 and Y5 to each other. Y2 and Y3 represent a group obtained by emitting a proton from a proton-donating group and the groups Y2 and Y3 in the same molecule are bonded with a silicon atom to form a chelate structure. Likewise, Y4 and Y5 represent a group obtained by emitting a proton from a proton-donating group and the groups Y4 and Y5 in the same molecule are bonded with a silicon atom to form a chelate structure. Groups X2 and X3 may be the same as or different from each other and Groups Y2, Y3, Y4, and Y5 may be the same as or different from each other. In such Formula (6), groups represented by -Y2-X2-Y3- and -Y4-X3-Y5- are groups obtained by emitting two protons from a proton donor. Examples of the proton donor include catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphthoic acid, 3-hydroxy-2-naphthoic acid, chloranilic acid, tannic acid, 2-hydroxybenzyl alcohol, 1,2-cyclohexanediol, 1,2-propanediol, and glycerine. Among these, from the viewpoint of balancing the availability of the material and a curing accelerating effect well, catechol, 1,2-dihydroxynaphthalene, and 2,3-dihydroxynaphthalene are preferable.

In addition, in Formula (6), Z1 represents an organic group having an aromatic ring or a heterocyclic ring or an aliphatic group, and specific examples thereof include aliphatic hydrocarbon groups such as a methyl group, an ethyl group, a propyl group, a butyl group, a hexyl group, and an octyl group; aromatic hydrocarbon groups such as a phenyl group, a benzyl group, a naphthyl group, and a biphenyl group; and reactive substituents such as glycidyloxypropyl group, mercaptopropyl group, aminopropyl group, and vinyl group. Among these, a methyl group, an ethyl group, a phenyl group, a naphthyl group, and a biphenyl group are preferable from the viewpoint of thermal stability.

As a method of preparing the adduct of a phosphonium compound and a silane compound, a silane compound such as phenyltrimethoxysilane and a proton donor such as 2,3-dihydroxynaphthalene are added to a flask to which methanol is added and dissolved therein; and a sodium methoxide-methanol solution is added dropwise under stirring at room temperature. Furthermore, a solution in which a tetra-substituted phosphonium halide such as tetraphenylphosphonium bromide which is prepared in advance is dissolved in methanol is added dropwise thereto under stirring at room temperature. As a result, a crystal is precipitated. The precipitated crystal is filtrated, washed with water, and dried in a vacuum. As a result, the adduct of a phosphonium compound and a silane compound is obtained. However, the invention is not limited thereto.

It is preferable that the lower limit of the content of the curing accelerator (E) be equal to or greater than 0.1% by weight, with respect to 100% by weight of the resin layer. When the lower limit of the content of the curing accelerator (E) is in the above-described range, sufficient curability can be obtained. In addition, it is preferable that the upper limit of the content of the curing accelerator (E) be equal to or less than 1% by weight, with respect to 100% by weight of the resin layer. When the upper limit of the content of the curing accelerator (E) is in the above-described range, sufficient fluidity can be obtained in the resin composition.

In this embodiment, the resin layer 16 includes 55 to 75% by weight and preferably 60 to 75% by weight of the inorganic filler (B), 5 to 35% by weight and preferably 5 to 25% by weight of the epoxy resin (A), and 5 to 30% by weight and preferably 5 to 20% by weight of the cyanate ester resin (D). As a result, the low thermal expansion of the resin layer 16 and the improvement of the adhesion with a plated metal layer and the like which is formed on the adhesion layer 14 are further well-balanced.

(Other Components)

The resin layer 16 can further include a thermosetting resin. As a result, the mechanical strength of a cured material obtained from the resin composition can be improved.

Examples of the thermosetting resin include phenoxy resin and olefin resin. One kind may be used alone; two or more kinds having different weight average molecular weights can be used in combination; one kind or two or more kinds and a prepolymer thereof can be used in combination. Among these, phenoxy resin is preferable. As a result, the heat resistance and flame retardancy of the resin layer 16 can be improved.

The phenoxy resin is not particularly limited, and examples thereof include phenoxy resins having a bisphenol structure such as phenoxy resin having a bisphenol A structure, phenoxy resin having a bisphenol F structure, phenoxy resin having a bisphenol S structure, phenoxy resin having a bisphenol M (4,4′-(1,3-phenylenediisopropylidene)bisphenol) structure, phenoxy resin having a bisphenol P (4,4′-(1,4-phenylenediisopropylidene)bisphenol) structure, and phenoxy resin having a bisphenol Z (4,4′-cyclohexylidenebisphenol) structure; phenoxy resins having a novolac structure; phenoxy resins having an anthracene structure; phenoxy resins having a fluorene structure; phenoxy resins having a dicyclopentadiene structure; phenoxy resins having a norbornene structure; phenoxy resins having a naphthalene structure; phenoxy resins having a biphenyl structure; and phenoxy resins having an adamantane structure. In addition, as the phenoxy resin, a structural unit having plural kinds of structures among the above examples can be used and phenoxy resin having structures with different ratios can be used. Furthermore, plural kinds of phenoxy resins having different structures can be used, plural kinds of phenoxy resins having different weight average molecular weights can be used, and phenoxy resin can be used in combination with a prepolymer thereof.

The resin layer 16 may further include phenol resin. The phenol resin includes all of monomers, oligomers, and polymers having a phenolic hydroxyl group which causes a curing reaction with epoxy resin to form a cross-linked structure, and examples thereof include phenol novolac resin, aralkyl phenol resin, terpene-modified phenol resin, dicyclopentadiene-modified phenol resin, bisphenol A, and triphenolmethane. These phenol resins can be used alone or as a mixture thereof.

Optionally, the resin layer 16 may contain other curing accelerators. Examples of other curing accelerators include imidazole compounds; organometallic salts such as zinc naphthenate, cobalt naphthenate, tin octylate, cobalt octylate, cobalt bis-acetylacetonate (II), and cobalt tris-acetylacetonate (III); tertiary amines such as triethylamine, tributylamine, and diazabicyclo[2,2,2]octane; phenol compounds such as phenol, bisphenol A, and nonyl phenol; organic acids such as acetic acid, benzoic acid, salicylic acid, and paratoluenesulfonic acid; and mixtures thereof. Among these including derivatives thereof, one kind can be used alone or two or more kinds can be used in combination.

Among other curing accelerators, imidazole compounds are particularly preferable. As a result, resistance to moisture absorption and solder heat can be improved. The imidazole compounds have characteristics of being dissolved practically at the molecular level or being dispersed in a state close to the molecular level when being dissolved in an organic solvent with the epoxy resin (A) and the cyanate ester resin (D).

When the resin layer 16 uses such an imidazole compound, a reaction of the epoxy resin (A) and the cyanate ester resin (D) can be effectively accelerated. In addition, even when the amount of the imidazole compound is small, the same characteristics can be imparted.

Furthermore, the resin composition using such an imidazole compound can be cured with high uniformity from the microscopic matrix unit between the imidazole compound and resin components. As a result, the insulating property and heat resistance of an insulating resin layer which is formed on a printed wiring board can be improved.

Examples of the imidazole compound include 1-benzyl-2-methylimidazole, 1-benzyl-2-phenylimidazole, 2-phenyl-4-methylimidazole, 2-ethyl-4-methylimidazole, 2,4-diamino-6-[2′-methylimidazolyl-(1′)]-ethyl-s-triazine, 2,4-diamino-6-(2′-undecylimidazolyl)-ethyl-s-triazine, 2,4-diamino-6-[2′-ethyl-4-methylimidazolyl-(1′)]-ethyl-s-triazine, 2-phenyl-4,5-dihydroxymethylimidazole, and 2-phenyl-4-methyl-5-hydroxymethylimidazol.

Among these, it is preferable that the imidazole compound be selected from 1-benzyl-2-methylimidazole, 1-benzyl-2-phenylimidazole, and 2-ethyl-4-methylimidazole. Since the imidazole compound has particularly superior miscibility and a cured material having high uniformity can be obtained, and since a fine and uniform roughened surface can be formed, a fine conductive circuit can be easily formed. In addition, a printed wiring board can exhibit high heat resistance.

The content of the imidazole compound is not particularly limited, and is preferably 0.01 to 5.00% by weight and particularly preferably 0.05 to 3.00% by weight, with respect to 100% by weight of the total amount of the epoxy resin (A) and the cyanate ester resin (D). As a result, in particular, heat resistance can be improved.

In addition, in order to improve various characteristics such as the miscibility of resin, stability, and workability, to the resin composition used for manufacturing the resin layer 16, various additives such as a leveling agent, an antifoaming agent, an antioxidant, a pigment, a dye, an antifoaming agent, a flame retardant, an ultraviolet absorber, an ion scavenger, an unreactive diluent, a reactive diluent, a thixotropic agent, and a thickener may be appropriately added.

<Method of Manufacturing Laminated Base Material for Printed Wiring Board>

The laminated base material for a printed wiring board (first embodiment) 10 and the laminated base material for a printed wiring board (second embodiment) 11 can be manufactured as follows. First, a resin composition for preparing the adhesion layer 14 or the resin layer 16 can be prepared.

The third resin composition for the adhesion layer 14 and the second resin composition for the resin layer 16 are respectively obtained as a resin varnish A (for the adhesion layer 14) and a resin varnish B (for the resin layer 16) by dissolving, mixing, and stirring the respective components included in the adhesion layer 14 and the respective components included in the resin layer 16 in an organic solvent such as acetone, methyl ethyl ketone, methyl isobutyl ketone, toluene, ethyl acetate, cyclohexane, heptane, cyclohexane, cyclohexanone, tetrahydrofuran, dimethylformamide, dimethylacetamide, dimethyl sulfoxide, ethylene glycol, cellosolves, carbitols, and anisole with various mixing machines such as an ultrasonic dispersion type, a high-pressure collision dispersion type, a high-speed rotating dispersion type, a bead mill type, a high-speed shearing dispersion type, and a planetary dispersion type.

Then, the resin varnish A is coated on the peel-off sheet 12 or the metal foil 13 using various coating machines, followed by drying. Alternatively, the resin varnish A is spray-coated on the peel-off sheet 12 using a spray machine, followed by drying. As a result, the adhesion layer 14 can be formed on the peel-off sheet 12. Furthermore, the resin varnish B is coated on the adhesion layer 14 using various coating machines, followed by drying. Alternatively, the resin varnish B is spray-coated on the adhesion layer 14 using a spray machine, followed by drying. As a result, the resin layer 16 can be formed on the adhesion layer 14.

The coating machine is not particularly limited, and, for example, a roll coater, a bar coater, a knife coater, a gravure coater, a die coater, a comma coater, and a curtain coater can be used. Among these, a method using a die coater, a knife coater, and a comma coater is preferable. As a result, a laminated base material for a printed wiring board having a uniform thickness of an insulating resin layer without a void can be efficiently manufactured.

It is preferable that the peel-off sheet 12 having easy handleability when being laminated be selected because the resin layer 16 is laminated through the adhesion layer 14. In addition, the resin layer 16-side surface of the laminated base material for a printed wiring board 10 is laminated in a state of being in contact with an inner layer circuit and then the peel-off sheet 12 is removed. Therefore, it is preferable that the peel-off sheet 12 be easily peeled off after laminating.

Examples of the peel-off sheet 12 include heat-resistant thermoplastic resin films, for example, polyester resins such as polyethylene terephthalate and polybutylene terephthalate, fluororesins, and polyimide resins. Among these films, from the viewpoint of balancing the adhesion and peel properties well in the adhesion layer 14, a film including polyester is most preferable.

The thickness of the peel-off sheet 12 is not particularly limited and is usually 10 to 200 μm and preferably 20 to 75 μm. When the thickness of the peel-off sheet 12 is in the above-described range, handleability is easy and the flatness of the resin layer 16 is superior.

In a similar way to that of the peel-off sheet 12, the metal foil 13 may be peeled off after laminating the laminated base material for a printed wiring board 10 on an inner layer circuit board or the metal foil 13 may be etched to be used as a conductive circuit. When being used as a conductive circuit, it is preferable that the metal foil 13 be formed of copper or aluminum.

The thickness of the metal foil 13 is not particularly limited, and is usually 1 to 100 μm and preferably 2 to 35 μm. When the thickness of the metal foil 13 is in the above-described range, handleability is easy and the flatness of the resin layer 16 is superior.

In addition, as the metal foil 13, an ultra thin metal foil with carrier foil can be used. The ultra thin metal foil with carrier foil is a metal foil obtained by bonding a peelable carrier foil and an ultra thin metal foil to each other. By using the ultra thin metal foil with carrier foil, an ultra thin metal foil layer can be formed on both surfaces of the insulating layer. Therefore, for example, when a circuit is formed using a semi-additive method, by directly electroplating the ultra thin metal foil as a power supply layer without electroless plating, the ultra thin copper foil can be flash-etched after the circuit is formed. By using the ultra thin metal foil with carrier foil, even with an ultra thin metal foil having a thickness of 10 μm or less, a deterioration in the handleability of the ultra thin metal foil or the cracking or breaking of the ultra thin copper foil can be suppressed in, for example, a press process.

In the laminated base material for a printed wiring board 10 or 11 thus obtained, the thickness of the adhesion layer 14 is not particularly limited, and is usually 0.5 to 10 μm and preferably 2 to 10 μm and the thickness of the resin layer 16 is usually 1 to 60 μm and preferably 5 to 40 μm.

On the other hand, the thickness of the resin layer 16 is preferably equal to or greater than the lower limit from the viewpoint of improving insulating reliability and is preferably equal to or less than the upper limit from the viewpoint of reduction in the thickness of a layer which is an object for a multilayer printed wiring board. As a result, when a multilayer printed wiring board is manufactured, convex and concave portions of an inner layer circuit can be filled for molding and a desired thickness of an insulating resin layer can be secured.

<Manufacturing of Prepreg>

The laminated base material for a printed wiring board can be obtained as a prepreg with a carrier which is obtained by impregnating a fiber substrate with a resin constituting the resin layer 16 and includes the peel-off sheet 12 or the metal foil 13. In this embodiment, both of “the prepreg with a carrier which includes at least one of the peel-off sheet 12 and the metal foil 13” and “the prepreg which is obtained by impregnating a fiber substrate with the resin varnish B and drying it” are simply referred to as “the prepreg”.

The fiber substrate is not particularly limited, and examples thereof include glass fiber substrates such as glass woven fabric and nonwoven glass fabric; polyamide resin fibers such as polyamide resin fiber, aromatic polyamide resin fiber, and wholly aromatic polyamide resin fiber; polyester resin fibers such as polyester resin fiber, aromatic polyester resin fiber, and wholly aromatic polyester resin fiber; woven or nonwoven synthetic fiber substrates including polyimide resin fiber or fluororesin fiber as a major component; organic fiber substrates such as a paper substrate including kraft pulp, cotton linter paper, or mixed paper of linter and kraft pulp as a major component. Among these, the glass fiber substrates are preferable. As a result, the strength of the prepreg can be improved, water absorption can be reduced, and the coefficient of thermal expansion can be reduced.

Glass constituting the glass fiber substrates is not particularly limited, and examples thereof include E glass, C glass, A glass, S glass, D glass, NE glass, T glass, and H glass. Among these, E glass, T glass, or S glass is preferable. As a result, the elasticity of the glass fiber substrates can increase and the coefficient of thermal expansion can be reduced.

Examples of a method of manufacturing the prepreg with a carrier include a method of obtaining a prepreg with a carrier in which a prepreg, obtained by impregnating a fiber substrate with the resin varnish B constituting the resin layer 16 in advance and volatilizing a solvent through heating and drying, is prepared, the resin varnish A constituting the adhesion layer 14 is further coated on the prepreg, a solvent is volatilized through heating and drying, and the peel-off sheet 12 or the metal foil 13 is bonded to the adhesion layer 14; and a method of obtaining a prepreg with a carrier in which a fiber substrate is impregnated with the resin varnish B constituting the resin layer 16, the resin varnish A constituting the adhesion layer 14 is coated thereon immediately, a solvent is volatilized through heating and drying, and the peel-off sheet 12 or the metal foil 13 is bonded to the adhesion layer 14.

In addition, as described above, the laminated base material for a printed wiring board 10 is prepared. Furthermore, a resin sheet in which the resin layer 16 is laminated over the peel-off sheet 12 is prepared. Then, on both surfaces of a sheet-like fiber substrate 40, the insulating resin layers 16 of insulating resin sheets with a film are disposed to face each other (FIG. 5(a)). Then, in a vacuum, for example, at a temperature of 60 to 130° C. and a pressure of 0.1 to 5 MPa, by laminating from both sides of the insulating resin sheets with a film, the fiber substrate 40 is impregnated with resins which constitute the resin layers 16. As a result, a prepreg 42 having a film on both surfaces can be obtained (FIG. 5(b)).

Here, the laminated base material for a printed wiring board 11 may be used instead of the laminated base material for a printed wiring board 10. In addition, instead of the resin sheet in which the resin layer 16 is laminated on the peel-off sheet 12, a resin sheet which is used in the related art (for example, Japanese Unexamined patent publication NO. 2010-31263) can be used.

Examples of a method of impregnating a fiber substrate with the resin varnish B includes a method of dipping a fiber substrate in the resin varnish B, a coating method using various coaters, and a spraying method using a spray. Among these, the method of dipping a fiber substrate in the resin varnish B is preferable. As a result, the impregnating ability of the resin varnish B (epoxy resin composition) for a fiber substrate can be improved. In addition, when a fiber substrate is dipped in the resin varnish B, a general impregnation coating machine can be used.

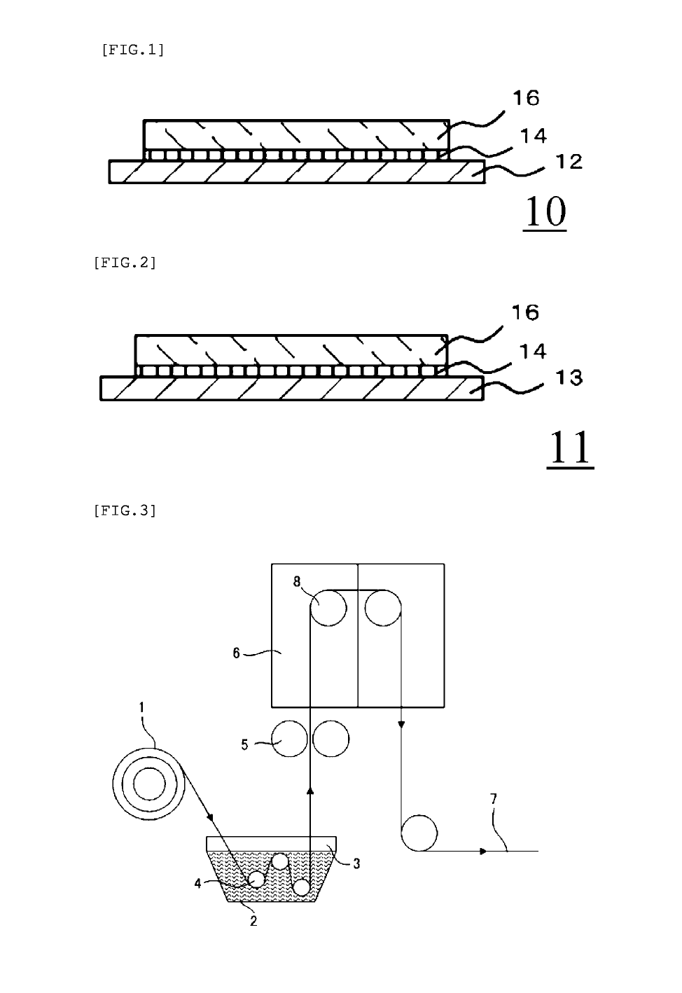

For example, as illustrated in FIG. 3, once a roll-like fiber substrate 1 is wound off, it is dipped in a resin varnish 3 of an impregnation bath 2. The impregnation bath 2 is provided with dip rolls 4 (in FIG. 1, three dip rolls). The fiber substrate 1 is caused to continuously pass through the resin varnish 3 through the dip rolls 4 and the fiber substrate 1 is impregnated with the epoxy resin varnish 3. Next, the fiber substrate 1 impregnated with the epoxy resin varnish 3 is vertically pulled up and is caused to pass through a pair of squeeze rolls 5 and 5 which are horizontally provided to face each other. As a result, the amount of the epoxy resin varnish 3 impregnating the fiber substrate 1 is adjusted. Instead of the squeeze rolls, comma rolls can be used. Next, the fiber substrate 1 impregnated with the epoxy resin varnish 3 is heated in a drying machine 6 at a predetermined temperature to volatilize a solvent in the coated varnish and semi-cure the resin varnish B. As a result, a prepreg 7 is manufactured. Rolls 8 illustrated in the upper section of FIG. 3 rotates in the same direction of a traveling direction of the prepreg 7 in order to move the prepreg 7 in the traveling direction. In addition, by drying the solvent of the epoxy resin varnish, for example, at a temperature of 90 to 180° C. for 1 to 10 minutes, the semi-cured prepreg 7 can be obtained.

In addition, a prepreg with a carrier can be manufactured with a manufacturing method including the following steps.

First, the resin layer 16-side surface of the laminated base material for a printed wiring board 10 or 11 is made to overlap a single surface or both surfaces of a fiber substrate and they are joined to each other under reduced pressure conditions (Step (a)). Next, after junction, insulating resin components constituting the resin layer 16 are heated at a temperature of a glass transition temperature thereof or higher to prepare a prepreg with a carrier (Step (b)).

First, Step (a) will be described.

In Step (a), under reduced pressure conditions, the laminated base material for a printed wiring board 10 or 11 and a fiber substrate are joined to each other.

A method of joining the laminated base material for a printed wiring board 10 and a fiber substrate to each other is not particularly limited, and an example thereof includes a method of continuously supplying a fiber substrate and the laminated base material for a printed wiring board 10 to make them overlap and be joined.

In Step (a), when the resin layer 16-side surface of the laminated base material for a printed wiring board 10 or 11 and a fiber substrate are joined, it is preferable that heating is performed at a temperature improving the fluidity of the resin components of the insulating resin layer 16. As a result, the fiber substrate and the insulating resin layer 16 can be easily joined. In addition, by melting at least a portion of the insulating resin layer 16 to impregnate the inside of a fiber substrate, a prepreg with a carrier having satisfactory impregnating ability can be easily obtained.

Here, a heating method is not particularly limited, and for example, a method using a laminate roll which is heated at a predetermined temperature during junction can be preferably used.

Here, a heating temperature varies depending on the kind and the combination of resins which form the insulating resin layer, and heating is performed at a temperature of, for example, 60 to 100° C.

Next, Step (b) will be described.

After the junction in Step (a), in Step (b), insulating resin components constituting the resin layer 16 are heated at a temperature of a glass transition temperature thereof or higher to prepare a prepreg.

As a result, in Step (a), voids under reduced pressure or voids in a practical vacuum, which remains when a carrier with the insulating resin layer and the fiber substrate are joined, can be eliminated. Therefore, a prepreg provided with a carrier on both surfaces thereof in which there are very few unfilled portions or practically no unfilled portions, can be manufactured.

A heating method is not particularly limited, and for example, heating is performed using a hot air drying machine, an infrared heating machine, a heating roll machine, a plate-like heating platen press machine, or the like.

<Manufacturing of Laminate>

An example of a method of manufacturing a metal-clad laminate using the laminated base material for a printed wiring board 10 or 11 will be described below.

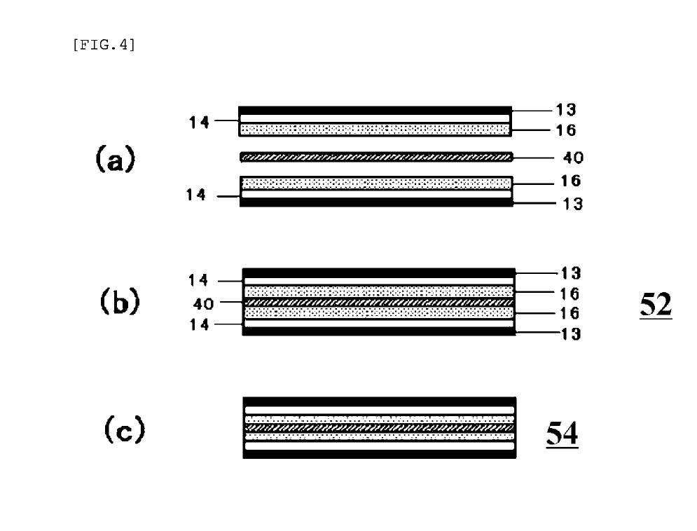

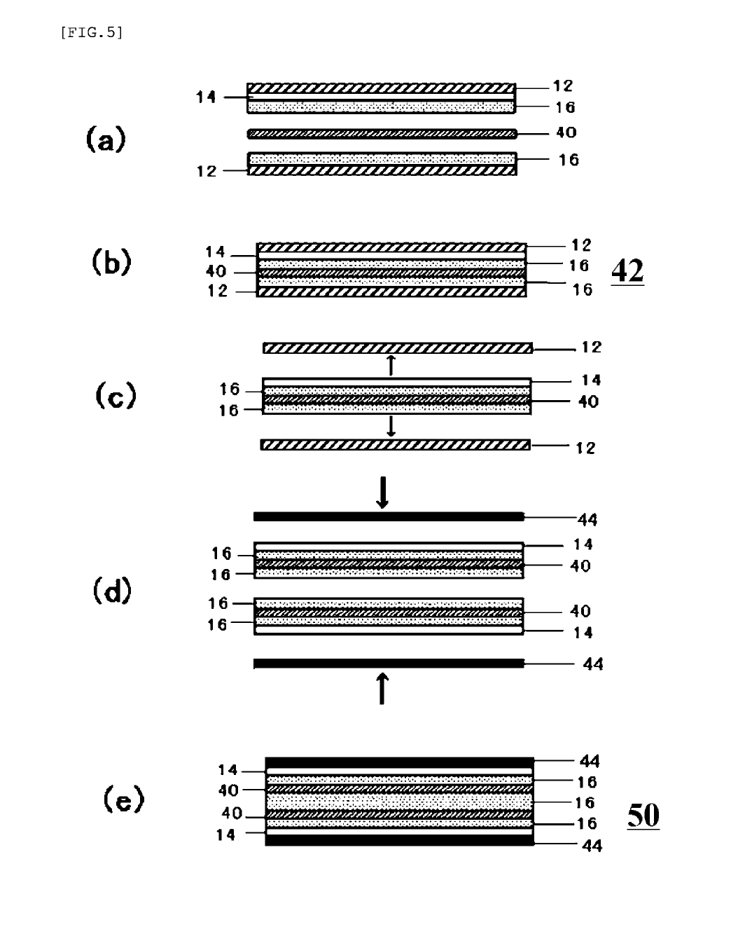

First, as described above, the laminated base material for a printed wiring board 11 illustrated in FIG. 2 is prepared. Next, on both surfaces of the sheet-like fiber substrate 40, the insulating resin layers 16 are disposed to face each other (FIG. 4(a))

Then, in a vacuum, for example, at a temperature of 60 to 130° C. and a pressure of 0.1 to 5 MPa, the fiber substrate 40 is impregnated with resins constituting the resin layers 16 of the laminated base material for a printed wiring board 11 (FIG. 4(b)). Next, by directly applying heat and pressure to a prepreg 52 having a metal foil on both surfaces thereof for molding, a laminate 54 having a metal foil on both surfaces thereof can be obtained (FIG. 4(c)).

In addition, by using the laminated base materials for a printed wiring board 10 and 12, a laminate having a metal foil on a single surface thereof; and by using only the laminated base materials for a printed wiring board 10, a laminate without a metal foil can be obtained with the same method.

Furthermore, by using a resin sheet used for a printed wiring board of the related art (for example, Japanese Unexamined patent publication NO. 2010-31263), a laminate may be manufactured from a fiber substrate and the laminated base material for a printed wiring board 10 or 11. For example, the peel-off sheets 12 of the prepreg with a carrier 42 are peeled off and a prepreg is obtained (FIG. 5(c)). Then, two resin layers 16 of the prepreg are disposed to face each other. In addition, the adhesion layers 14 and metal foils 44 are disposed to face each other (FIG. 5(d)). Therefore, a laminate 50 which has two fiber substrates by applying heat and pressure for molding from both sides and has a metal foil on both surfaces can be obtained (FIG. 5 (e)).

As the fiber substrate 40, a fiber substrate using the above-described prepreg can be used.

<Method of Manufacturing Printed Wiring Board>

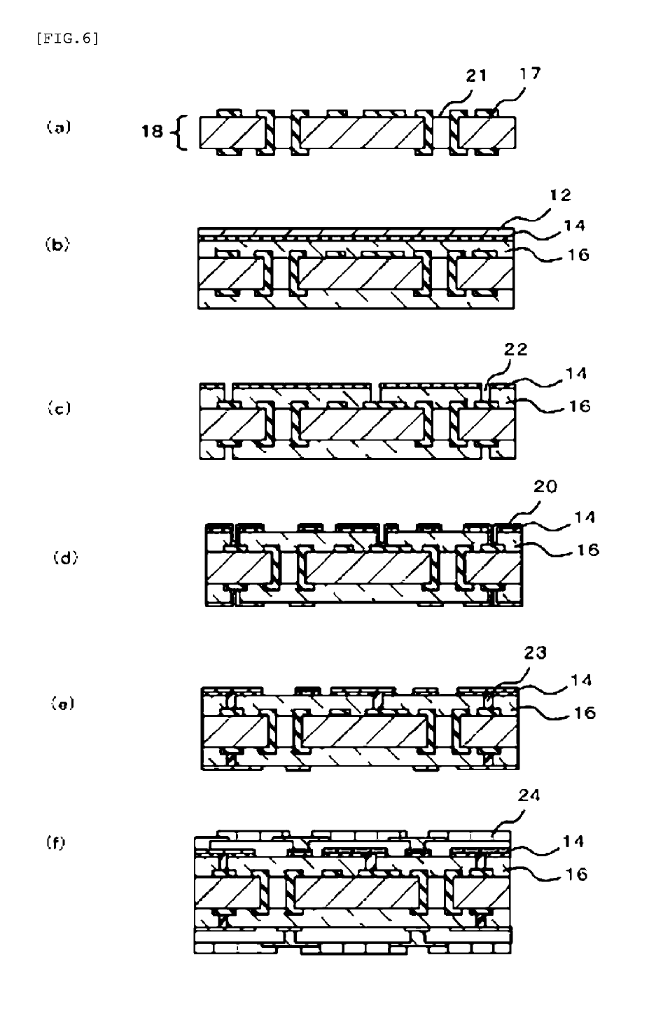

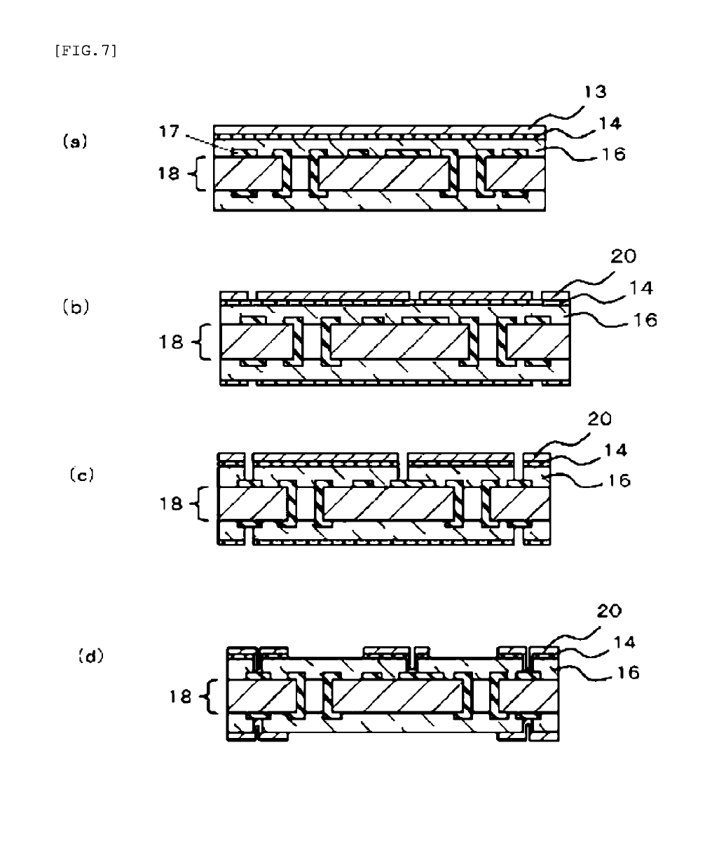

FIG. 6 illustrates a method of manufacturing a multilayer printed wiring board using the laminated base material for a printed wiring board 10.

FIG. 6(a) illustrates an inner layer circuit board 18 in which a circuit pattern is formed on a core substrate (for example, a double-sided copper foil FR-4).

First, a core substrate is drilled using a drilling machine to form an opening 21. Residual resin and the like, which remains after drilling, is removed by an oxidant such as permanganate or dichromate and the like in desmear process. By using the metal-clad laminate as a core substrate of this embodiment, the adhesion between the adhesion layer 14 and the metal layer 16 can be maintained even after the desmear process.

Then, the opening 21 is plated through electroless plating to make a connection between both surfaces of the inner layer circuit board 18. Then, by etching the copper foil of the core substrate, an inner layer circuit 17 is formed.

As the inner layer circuit board used for obtaining the multilayer printed wiring board, for example, an inner layer circuit board, obtained by roughening an inner layer circuit portion, for example, by blackening it, can be preferably used. In addition, the opening 21 can be appropriately filled with a conductive paste or a resin paste.

As the material of the inner layer circuit 17, a material, which can be easily removed with a method such as etching or peeling during the formation of an inner layer circuit, is preferable. In the case of etching, a material having chemical resistance to chemicals or the like used for etching is preferable. Examples of such a material of the inner layer circuit 17 include a copper foil, a copper plate, a copper alloy plate, an alloy 42, and nickel. In particular, a copper foil, a copper plate, and a copper alloy plate are most preferably used as the inner layer circuit 17 because electro-plated products and rolling products can be selected and they are available in various thicknesses.

Next, the laminated base material for a printed wiring board 10 is laminated to cover the inner layer 17 such that the resin layer 16 faces the inner layer circuit board 18 side (FIG. 6(b)). A method of laminating the laminated base material for a printed wiring board is not particularly limited. For example, a laminating method using a vacuum press, a normal-pressure laminator, or a laminator which applies heat and pressure in a vacuum is preferable and a method using a laminator which applies heat and pressure in a vacuum is more preferable.

Next, the formed resin layer 16 is heated to be cured. The curing temperature is not particularly limited, and is preferably in a range of 100° C. to 250° C. In particular, the temperature is preferably in a range of 150° C. to 200° C. In addition, in order to promote laser irradiation and residual resin removal, there are cases where the resin layer 16 is semi-cured. In addition, the resin layer 16 as a first layer is heated at a temperature lower than a normal heating temperature to be partially cured (semi-cured); on the adhesion layer 14, a single or multiple layers of the resin layer 16 are further formed; and the semi-cured resin layers 16 are heated to be cured again to a degree where there is practically no problem. As a result, the adhesion between the resin layers 16 and between the resin layer 16 and a circuit can be improved. In this case, the temperature of semi-curing is preferably 80° C. to 200° C. and more preferably 100° C. to 180° C. In the subsequent process, a via hole 22 is formed in the resin by irradiating laser light. Before that, it is necessary that the peel-off film 12 be peeled off. After forming the insulating resin layer, the peel-off film 12 can be peeled off before or after thermal curing without a particular problem.

Next, the adhesion layer 14 and the resin layer 16 are irradiated with laser light to form the via hole 22 (FIG. 6(c)). Examples of the laser light include excimer laser light, UV laser light, and carbon dioxide laser light. When the via hole 22 is formed with laser light, the fine via hole 22 can be easily formed, irrespective of whether the material of the resin layer 16 is photosensitive or non-photosensitive. Therefore, when it is necessary that a fine opening be formed in the resin layer 16, laser light is particularly preferable.

After irradiating laser light, residual resin and the like are removed using an oxidant such as permanganate or dichromate in desmear process. In desmear process, a smooth surface of the resin layer 16 can be roughened at the same time and the adhesion of a conductive wiring circuit, which is formed through metal plating subsequent thereto, can be improved. According to the laminated base material for a printed wiring board 10 of this embodiment, the adhesion between the adhesion layer 14 and an outer layer circuit 20 can be maintained after desmear process. Since fine convex and concave portions are uniformly provided on the surface of the adhesion layer 14 in desmear process, the adhesion with the outer layer circuit 20 can be improved. In addition, since the smoothness of the surface of the resin layer is high, a fine wiring circuit can be accurately formed.

Next, the outer layer circuit 20 is formed (FIG. 6(d)). As a method of forming the outer layer circuit 20, the outer layer circuit 20 can be formed with, for example, a semi-additive method which is a well-known method. However, the invention is not limited thereto. Next, a conductive post 23 is formed (FIG. 6(e)). As a method of forming the conductive post 23, the conductive post 23 can be formed through electroplating and the like which is a well-known method. For example, using the outer layer circuit 20 as a electroplating lead, copper electroplating is performed and the inside of the via hole 22 is filled with copper. As a result, a copper post can be formed.

Furthermore, by repeating the steps illustrated in FIG. 6(b) to FIG. 6(e), multiple layers can be formed. When the insulating resin layer is semi-cured, there are cases where postcure is performed.

Next, a solder resist 24 is formed (FIG. 6(f)). In FIG. 6(f), by repeating again the steps illustrated in FIG. 6(b) to FIG. 6(e), a multilayer structure having two layers of the resin layer 16 can be obtained.

A method of forming the solder resist 24 is not particularly limited, and for example, the solder resist is formed with a method of laminating a dry film type solder resist, followed by exposure and development; and a method of printing a liquid resist, followed by exposure and development. In addition, a connection electrode portion can be appropriately coated with a metal coating such as gold plating, nickel plating or solder plating. With such a method, a multilayer printed wiring board can be manufactured.

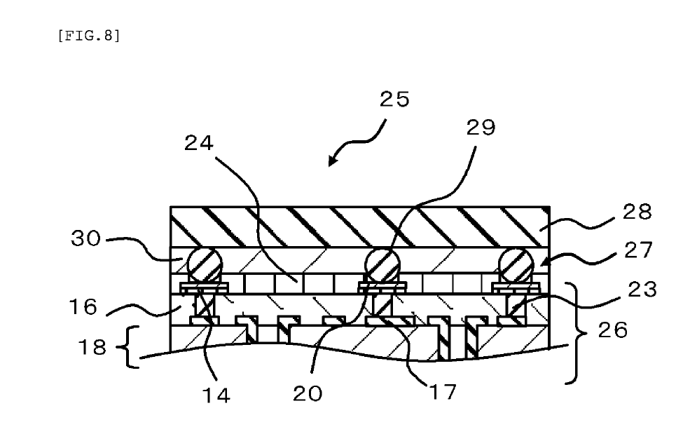

FIG. 7 illustrates a method of manufacturing a multilayer printed wiring board using the laminated base material for a printed wiring board 11. As illustrated in FIG. 7(a), the laminated base material for a printed wiring board is laminated to cover the inner layer circuit 17 such that the resin layer 16 faces the inner layer circuit board 18 side (FIG. 6(b)). In a similar way to that of the first embodiment, a method of laminating the laminated base material for a printed wiring board is not particularly limited. For example, a laminating method using a vacuum press, a normal-pressure laminator, or a laminator which applies heat and pressure in a vacuum is preferable and a laminating method using a laminator which applies heat and pressure in a vacuum is more preferable.

Next, a via hole is provided in the laminated base material for a printed wiring board.

First, with a predetermined etching method, the metal foil 13 is etched to form an opening (FIG. 7(b). Then, the resin layer 16 which is exposed through the bottom of the opening is irradiated with laser light to form a via hole (FIG. 7(c)).

After irradiating laser light, in order to remove residual resin and the like in the via hole, desmear process is performed using an oxidant such as permanganate or dichromate. Through the desmear process, the adhesion of a conductive wiring circuit, which is formed through metal plating subsequent thereto, can be improved. According to the laminated base material for a printed wiring board 11 of this embodiment, the adhesion between the adhesion layer 14 and the metal layer 16 can be maintained even after the desmear process.

Then, the connection between insulating resin layers is made through metal plating and an outer layer circuit pattern is formed through etching (FIG. 7(d)). Then, in a similar way to the case of using the laminated base material for a printed wiring board 10, a multilayer printed wiring board can be obtained. In FIG. 7(b), all the metal foils are removed through etching and a printed wiring board can be obtained through the steps of FIG. 6(b) to (f).

<Method of Manufacturing Semiconductor Device>

Next, a semiconductor device obtained by mounting a semiconductor element to the printed wiring board according to this embodiment will be described.

FIG. 8 is a cross-sectional view illustrating an example of a semiconductor device 25.

As illustrated in FIG. 8, plural connection electrode portions 27 are provided on a single surface of a printed wiring board 26. A semiconductor element 28 having solder bumps 29 which are provided to correspond to the connection electrode portions 27 of the multilayer printed wiring board is connected to the printed wiring board 26 through the solder bumps 29.

A gap between the printed wiring board 26 and the semiconductor element 28 is filled with a liquid sealing resin 30 and thus the semiconductor device 25 is formed. The printed wiring board 26 includes the inner layer circuit 17, the insulating layer 16, the adhesion layer 14, and the outer layer circuit 20 on the inner layer circuit board 18. The inner layer circuit 17 and the outer layer circuit 20 are connected through the conductive post 23. In addition, the insulating layer 16 is covered with the solder resist 24.

It is preferable that the solder bump 29 be configured by an alloy of tin, lead, silver, copper, bismuth, and the like. Regarding a method of connecting the semiconductor element 28 and the printed wiring board 26, the connection electrode portions on the substrate and the metal bumps of the semiconductor element are aligned using a flip chip bonder or the like; the solder bumps 29 are heated to a melting point or higher using an IR reflow machine, a heating plate, and other heating devices; and thus the multilayer printed wiring board 26 on the substrate and the solder bumps 29 are melted and joined to each other. In order to improve connection reliability, a layer of a metal having a relatively low melting point such as solder paste may be formed on the connection electrode portions of the multilayer printed wiring board 26 in advance. Prior to this junction process, the solder bumps and/or surface layers of the connection electrode portions on the printed wiring board can be coated with flux to improve connectivity.

In addition, the epoxy resin composition for a printed wiring board can be preferably used for a printed wiring board and the like requiring high reliability which is used for a system-in-package (SiP) or the like requiring reduction in size, high-density wiring, and high reliability.

Hereinafter, the invention will be described in detail with reference to Examples and Comparative Examples, but the invention is not limited thereto. In addition, the unit of a mixing amount in Tables is a part by weight.

### Example 1

### Regarding First Resin Composition

Base materials used in Examples and Comparative Examples are as follows.

(1) Inorganic filler A/spherical silica; manufactured by Admatechs., “SO-25R”, average particle size: 0.5 μm

(2) Inorganic filler B/Boehmite; manufactured by TAIMEI CHEMICALS CO., LTD., C-20, average particle size: 2.0 μm, BET specific surface area: 4.0 m²/g

(3) Epoxy resin A/methoxynaphthalene dimethylene epoxy resin; manufactured by DIC corporation, “HP-5000”, epoxy equivalent: 250

(4) Epoxy resin B/biphenyl dimethylene epoxy resin; manufactured by NIPPON KAYAKU Co., Ltd., “NC-3000”, epoxy equivalent: 275

(5) Cyanate resin A/novolac cyanate resin; manufactured by LONZA Japan, “Primaset PT-30”, cyanate equivalent: 124

(6) Cyanate resin B/bisphenol A cyanate resin; manufactured by LONZA Japan, “Primaset BA-200”, cyanate equivalent: 139

(7) Phenoxy resin/copolymer of bisphenol An epoxy resin and bisphenol F epoxy resin; manufactured by JAPAN EPDXY RESIN Co., Ltd., “jER4275”, weight average molecular weight 60000

(8) Phenol curing agent/biphenyl alkylene type novolac resin; manufactured by MEIWA PLASTIC INDUSTRIES LTD., “MEH-7851-3H”, hydroxyl equivalent: 220

(9) Curing accelerator/imidazole compound; manufactured by SHIKOKU CHEMICALS CORPORATION, “CUREZOL 1B2PZ (1-benzyl-2-phenylimidazole)”

(10) Cyclic siloxane compound (C) A (TMCTS)/1,3,5,7-tetramethylcyclotetrasiloxane; manufactured by AZMAX Co., Ltd.

(11) Cyclic siloxane compound (C) B (PMCTS)/1,3,5,7,9-pentamethylcyclopentasiloxane; manufactured by AZMAX Co., Ltd.

### Example 1-1

(1) Preparation of Resin Varnish

25.0 parts by weight of the epoxy resin A, 24.0 parts by weight of the phenol curing agent, and 1.0 parts by weight of the cyclic siloxane compound A were dissolved and dispersed in methyl ethyl ketone. Furthermore, 50.0 parts by weight of the inorganic filler A was added, followed by stirring for 10 minutes with a high-speed stirring machine. As a result, 60 parts by weight of resin varnish was prepared in terms of solid content.

(2) Preparation of Prepreg

Glass woven fabric (thickness: 92 μm, manufactured by Nitto Boseki Co., Ltd., WEA-116E) was impregnated with the resin varnish, followed by drying for 2 minutes in a heating furnace at 150° C. As a result, about 50% by weight of prepreg was obtained in terms of the solid content of the resin varnish in the prepreg.

(3) Preparation of Laminate

Two sheets of the prepregs are made to overlap, a 3 μm-thick copper foil with a carrier (manufactured by Mitsui Kinzoku Co. Ltd., MTEx) was overlapped on both surfaces thereof, followed by applying heat and pressure for molding for 2 hours at a pressure of 4 MPa and a temperature of 200° C. As a result, a 0.2 mm-thick laminate having the copper foil on both surfaces thereof was obtained.

(4) Preparation of Resin Sheet

The resin varnish was coated on a PET film (thickness: 38 μm, manufactured by Mitsubishi Plastics Inc., SFB 38) using a comma coater such that the thickness of an epoxy resin layer after drying is 40 μm, followed by drying for 5 minutes with a drying machine at 150° C. As a result, a resin sheet was obtained.

(5) Preparation of Printed Wiring Board (Double-Sided Circuit Board)

The laminate was drilled using a 0.1 mm drill bit to obtain a through hole and the through hole was filled through plating. Furthermore, a dry film for a semi-additive method (manufactured by Asahi Kasei Corporation, UFG-255) was laminated on the surface of the copper foil using a roll laminator, followed by exposure and development in a predetermined pattern. Then, a patterned exposed portion was electroplated with copper. As a result, a 20 μm-thick copper electroplating film was formed. Furthermore, the dry film was peeled off, followed by flash-etching. As a result, a 3 μm-thick copper foil sheet layer was removed. Then, circuit roughening was performed (manufactured by MEC CO., LTD., CZ8101). As a result, a printed wiring board (double-sided circuit board) having a pectinate-pattern copper circuit in which L/S=15 μm/15 μm, was prepared.

(6) Preparation of Multilayer Printed Wiring Board

The obtained resin sheet was made to overlap the obtained double-sided circuit board such that the epoxy resin surface thereof faces inside, followed by applying heat and pressure in a vacuum at a temperature of 100° C. and a pressure of 1 MPa using a vacuum pressure laminator for molding. The PET film of the substrate was peeled off from the resin sheet, followed by heating and curing in a hot air drying machine for 60 minutes at 170°. Furthermore, an opening was provided to an insulating layer using a carbon laser machine and an outer layer circuit in which L/S=25 μm/25 μm was formed on a surface of the insulating layer through electroplating to make a connection between the outer layer circuit and the inner layer circuit. In addition, the outer layer circuit was provided with a connection electrode portion for mounting a semiconductor element. Then, a solder resist (manufactured by TAIYO INK MFG. CO., LTD., PSR4000/AUS308) was formed on the outermost layer, the connection electrode portion was exposed such that the semiconductor element was mounted thereon through exposure and development, ENEPIG process was performed, and the resultant was cut to the size of 50 mm×50 mm. As a result, a multilayer printed wiring board for packaging was obtained.

(7) Preparation of Semiconductor Device

As a semiconductor element (TEG chip, size: 15 mm×15 mm, thickness: 0.8 mm), a semiconductor element in which a solder bump was formed of eutectic crystal of Sn/Pb composition and a circuit protective film was formed of a positive photosensitive resin (manufactured by SUMITOMO BAKELITE CO., LTD., CRC-8300) was used. In the fabrication of the semiconductor device, first, the solder bump was uniformly coated with flux by transfer process and the solder bump was mounted on the multilayer printed wiring board for packaging by applying heat and pressure using a flip chip bonder. Next, the solder bump was melted and joined in an IR reflow furnace, and was filled with a liquid sealing resin (manufactured by SUMITOMO BAKELITE CO., LTD., CRP-415S). Then, the liquid sealing resin was cured. As a result, a semiconductor device was obtained. In this case, the liquid sealing resin was cured for 120 minutes at a temperature of 150° C.

### Examples 1-2 to 1-5 and Comparative Examples 1-1 to 1-3

According to the mixing amounts of Table 1, in the same manner as that of Example 1, a prepreg, a laminate, a printed wiring board, a multilayer printed wiring board, and a semiconductor device were obtained.

Regarding the prepreg, the laminate, the multilayer printed wiring board, and the semiconductor which were obtained above, the following evaluation items were evaluated. In addition, the mixing compositions, the respective physical properties, and the evaluation results of Examples and Comparative Examples are shown in Tables 1 and 2. In Tables, the respective mixing amounts are represented by “parts by weight”.

TABLE 1

| | | Example | Example | Example | Example | Example | Comparative | Comparative | Comparative |
|---|---|---|---|---|---|---|---|---|---|
| | | 1-1 | 1-2 | 1-3 | 1-4 | 1-5 | Example 1-1 | Example 1-2 | Example 1-3 |
| | Inorganic Filler A | 50.0 | 50.0 | | 70.0 | 30.0 | 50.0 | | 50.0 |
| | (SO-25R) | | | | | | | | |
| | Inorganic Filler B | | | 50.0 | | | | | |
| | (C-20) | | | | | | | | |
| | Epoxy Resin A | 25.0 | 20.0 | | | | 25.0 | 50.0 | |
| | (HP-5000) | | | | | | | | |
| | Epoxy Resin B | | | 29.0 | 9.5 | 20.0 | | | |
| | (NC-3000) | | | | | | | | |
| | Cyanate Resin A | | 15.0 | | 12.0 | | | | 25.0 |
| | (PT-30) | | | | | | | | |
| | Cyanate Resin B | | | 20.0 | | 35.0 | | | |
| | (BA-200) | | | | | | | | |
| | Phenoxy Resin | | | | 5.0 | | | | |
| | (jER4275) | | | | | | | | |
| | Phenol Curing | 24.0 | 14.0 | | | 14.5 | 25.0 | 49.0 | 24.0 |
| | Agent | | | | | | | | |
| | (MEH-7851-3H) | | | | | | | | |
| | Imidazole | | | 0.5 | 0.5 | | | | |
| | Compound (1B2PZ) | | | | | | | | |
| | Cyclic Siloxane | 1.0 | | 0.5 | 3.0 | | | 1.0 | 1.0 |
| | Compound A (TMCTS) | | | | | | | | |
| | Cyclic Siloxane | | 1.0 | | | 0.5 | | | |
| | Compound B (PMCPS) | | | | | | | | |
| Evaluation | (1) Coefficient of | ◯ | © | ◯ | © | ◯ | ◯ | X | ◯ |
| Items | Thermal Expansion | | | | | | | | |
| | (2) Resistance to | ◯ | ◯ | ◯ | ◯ | ◯ | ◯ | ◯ | X |
| | Moisture | | | | | | | | |
| | Absorption and | | | | | | | | |
| | Solder Heat | | | | | | | | |
| | (3) ENEPIG | ◯ | ◯ | ◯ | ◯ | ◯ | X | ◯ | ◯ |
| | Characteristics | | | | | | | | |
| | (4) Thermal Shock | ◯ | ◯ | ◯ | ◯ | ◯ | ◯ | X | X |
| | Test | | | | | | | | |

(1) Coefficient of Thermal Expansion

The entire surface of a copper foil of a 0.2 mm-thick laminate was etched, a 4 mm×20 mm test piece was cut out from the obtained laminate, and the coefficient of liner expansion in a surface direction thereof (mean coefficient of linear expansion) was measured using a TMA under conditions of 10° C./min and 50 to 150° C. The respective symbols represent as follows.

©: The coefficient of liner expansion was less than 10 ppm

◯: The coefficient of liner expansion was equal to or greater than 10 ppm and less than 15 ppm

X: The coefficient of liner expansion was equal to or greater than 15 ppm

(2) Resistance to Moisture Absorption and Solder Heat

A 50 mm² test piece was cut out from the obtained laminate, three fourths of the test piece was etched, followed by moisture absorption at 121° C. for 2 hours using a pressure cooker. Then, the resultant was dipped in a solder at 260° C. for 30 seconds and whether there was swelling or not was observed. The respective symbols represent as follows.

◯: There were no problems

X: Swelling occurred

(3) Adaptability to ENEPIG Process

Using a double-sided circuit board which was cut to 50 mm² as a test piece, the adaptability to ENEPIG process was evaluated in the following order.

The test piece was dipped in a cleaning solution (manufactured by C.Uyemura & CO., LTD., ACL-007) having a temperature of 50° C. for 5 minutes, sufficiently washed with water, dipped in a soft etchant (mixed solution of sodium persulfate and a sulfuric acid) having a temperature of 25° C. for 1 minute, and sufficiently washed with water. Next, as acid cleaning process, the test piece was dipped in a sulfuric acid having a temperature of 25° C. for 1 minute and sufficiently washed with water. The test piece was further dipped in sulfuric acid having a temperature of 25° C. for 1 minute, dipped in a palladium catalyst-added solution (manufactured by C.Uyemura & CO., LTD., KAT-450) having a temperature of 25° C. for 2 minutes, and washed with water. This test piece was dipped in a electroless Ni plating bath (manufactured by C.Uyemura & CO., LTD., NPR-4) having a temperature of 80° C. for 35 minutes, sufficiently washed with water, dipped in a electroless Pd plating bath (manufactured by C.Uyemura & CO., LTD., TPD-30) having a temperature of 50° C. for 5 minutes, and sufficiently washed with water. Finally, the test piece was dipped in a electroless Au plating bath (manufactured by C.Uyemura & CO., LTD., TWX-40) having a temperature of 80° C. for 30 minutes, and sufficiently washed with water.

Interconnects of this test piece were observed with an electron microscope (2000 times magnification) and whether there is abnormal deposition of plating or not in the interconnects was examined. When there is abnormal deposition of plating, this causes short-circuit of interconnects, which is not preferable. The respective symbols represent as follows.

◯: The surface area of metal-deposited portions in the 50 mm² test piece was equal to or less than 5%

X: Equal to or greater than 5%

(4) Thermal Shock Test

The obtained semiconductor device was treated in Fluorinert 1000 cycles, in which the treatment at −55° C. for 10 minutes, at 125° C. for 10 minutes, and at −55° C. for 10 minutes was set as one cycle. Then, whether there are cracks or not in the test piece was examined by visual inspection. The respective symbols represent as follows.

◯: No cracks occurred

X: Cracks occurred

Examples 1-1 to 1-5 used the resin compositions for a printed wiring board according to the invention. The evaluation results were satisfactory overall and the adaptability to ENEPIG process was also satisfactory. On the other hand, in Comparative Example 1-1, since the cyclic siloxane compound was not used, there was a problem in ENEPIG process. In Comparative Example 1-2, since the inorganic filler was not used, low thermal expansion deteriorated and the thermal shock resistance of the semiconductor device was not satisfactory. In Comparative Example 1-3, since the epoxy resin was not used, resistance to moisture absorption and heat and thermal shock resistance deteriorated. It was found that the resin composition for a wiring board according to the invention is effective for satisfying all of low thermal expansion, heat resistance, adaptability to ENEPIG process, and thermal shock resistance.

### Reference Example

Reference tests were conducted using the following base materials other than the base materials used for Examples and Comparative Examples.

(12) Inorganic filler C/spherical nano-silica; manufactured by Tokuyama Corporation, NSS-5N, average particle size: 70 nm

(13) Inorganic filler D/spherical nano-silica; manufactured by FUSO CHEMICAL CO., LTD., PL-1, average particle size: 15 nm

(14) Epoxy resin C/bisphenol An epoxy resin; manufactured by DIC corporation, “840-S”, epoxy equivalent: 185

### Reference Examples 1-1 to 1-5

A prepreg, a laminate, a resin sheet, a multilayer printed wiring board, and a semiconductor device were obtained in the same manner as that of Example 1-1, except that components were mixed as shown in Table 2.

TABLE 2

| | | Reference | Reference | Reference | Reference | Reference |
|---|---|---|---|---|---|---|
| | | Example 1-1 | Example 1-2 | Example 1-3 | Example 1-4 | Example 1-5 |
| | Inorganic Filler A | 45.0 | 48.0 | | 50.0 | |
| | (SO-25R) | | | | | |
| | Inorganic Filler B (C-20) | | | | | 50.0 |
| | Inorganic Filler C | 5.0 | | | | |
| | (NSS-5N) | | | | | |
| | Inorganic Filler D (PL-1) | | 3.0 | 10.0 | | |
| | Epoxy Resin A (HP-5000) | 25.0 | 20.0 | | 20.0 | |
| | Epoxy Resin B (NC-3000) | | | 20.0 | | 29.0 |
| | Epoxy Resin C (840-S) | | | 50.0 | | |
| | Cyanate Resin A (PT-30) | | 15.0 | | 15.0 | |
| | Cyanate Resin B (BA-200) | | | | | 20.0 |
| | Phenoxy Resin (jER4275) | | | 20.0 | | |
| | Phenol Curing Agent | 24.0 | 14.0 | | 15.0 | |
| | (MEH-7851-3H) | | | | | |
| | Imidazole Compound | | | 0.5 | | 1.0 |
| | (1B2PZ) | | | | | |
| | Cyclic Siloxane Compound A | 1.0 | | | | |
| | (TMCTS) | | | | | |
| | Cyclic Siloxane Compound B | | 1.0 | | | |
| | (PMCPS) | | | | | |
| Evaluation | (1) Coefficient of Thermal | ◯ | © | X | © | ◯ |
| Items | Expansion | | | | | |
| | (2) Resistance to Moisture | ◯ | ◯ | ◯ | ◯ | ◯ |
| | Absorption and Solder Heat | | | | | |
| | (3) ENEPIG | ◯ | ◯ | ◯ | X | X |
| | Characteristics | | | | | |
| | (4) Thermal Shock Test | ◯ | ◯ | ◯ | ◯ | ◯ |

(5) Contact Angle Measurement

A copper foil of the laminate was removed through etching and the contact angle was measured after the following steps. The laminate (a) was dipped in a cleaning solution (manufactured by C.Uyemura & CO., LTD., ACL-007) having a temperature of 50° C. for 5 minutes and sufficiently washed with water; and (b) was dipped in a soft etchant (mixed solution of sodium persulfate and a sulfuric acid) having a temperature of 25° C. for 1 minute and sufficiently washed with water. Next, (c) as acid cleaning process, the laminate was dipped in a sulfuric acid having a temperature of 25° C. for 1 minute and sufficiently washed with water. The laminate (d) was further dipped in sulfuric acid having a temperature of 25° C. for 1 minute, and dipped in a palladium catalyst-added solution (manufactured by C.Uyemura & CO., LTD., KAT-450) having a temperature of 25° C. for 2 minutes, and washed with water. This test piece (e) was dipped in a electroless Ni plating bath (manufactured by C.Uyemura & CO., LTD., NPR-4) having a temperature of 80° C. for 35 minutes, sufficiently washed with water, (f) dipped in a electroless Pd plating bath (manufactured by C.Uyemura & CO., LTD., TPD-30) having a temperature of 50° C. for 5 minutes, and sufficiently washed with water. Finally, the laminate (g) was dipped in a electroless Au plating bath (manufactured by C.Uyemura & CO., LTD., TWX-40) having a temperature of 80° C. for 30 minutes, and sufficiently washed with water.

Then, using a contact angle meter (DM-301) manufactured by Kyowa Interface Science Co., Ltd, the contact angle between a resin surface (where there is no wiring) and pure water was measured. The results of the contact angle measurement are shown in Table 3.

TABLE 3

| | | Reference | Reference | Reference | Reference | Reference |
|---|---|---|---|---|---|---|
| | | Example 1-1 | Example 1-2 | Example 1-3 | Example 1-4 | Example 1-5 |
| Evaluation | (a) After | 105 | 115 | 115 | 115 | 110 |
| Items | Cleaning | | | | | |
| | (b) After Soft | 110 | 115 | 115 | 110 | 105 |
| | Etching | | | | | |
| | (c) After Acid | 110 | 115 | 110 | 115 | 110 |
| | Cleaning | | | | | |
| | (d) After | 115 | 115 | 110 | 110 | 110 |
| | Palladium | | | | | |
| | Catalyst-Added | | | | | |
| | Solution | | | | | |
| | Treatment | | | | | |
| | (e) After | 60 | 65 | 75 | 115 | 90 |
| | Electroless Ni | | | | | |
| | plating | | | | | |
| | (f) After | 110 | 105 | 105 | 110 | 105 |
| | Electroless Pd | | | | | |
| | Plating | | | | | |
| | (g) After | 105 | 105 | 110 | 110 | 100 |
| | Electroless Au | | | | | |
| | Plating | | | | | |

It was confirmed that all the laminates of Reference Examples 1-1 to 1-3 have a contact angle of 85° or less. In addition, in a printed wiring board using the laminates of Reference Examples, ENEPIG characteristics were satisfactory.

Regarding the laminates of Examples and Comparative Examples, the relationship between the contact angle and ENEPIG characteristics is shown in Table 4. The numerical values in the table represent the contact angles (°) in the respective steps (a) to (g).

TABLE 4

| | | Example | Example | Example | Example | Example | Comparative | Comparative | Comparative |
|---|---|---|---|---|---|---|---|---|---|
| | | 1-1 | 1-2 | 1-3 | 1-4 | 1-5 | Example 1-1 | Example 1-2 | Example 1-3 |
| Contact | (a) After | 105 | 115 | 110 | 115 | 120 | 110 | 115 | 115 |
| Angle | Cleaning | | | | | | | | |
| Measurement | (b) After Soft | 115 | 115 | 105 | 115 | 115 | 105 | 110 | 115 |
| | Etching | | | | | | | | |
| | (c) After Acid | 110 | 110 | 110 | 110 | 110 | 110 | 115 | 105 |
| | Cleaning | | | | | | | | |
| | (d) After | 115 | 115 | 115 | 110 | 115 | 105 | 115 | 110 |
| | Palladium | | | | | | | | |
| | Catalyst-Added | | | | | | | | |
| | Solution | | | | | | | | |
| | Treatment | | | | | | | | |
| | (e) After | 70 | 80 | 55 | 70 | 75 | 100 | 70 | 80 |
| | Electroless Ni | | | | | | | | |
| | plating | | | | | | | | |
| | (f) After | 110 | 105 | 110 | 105 | 110 | 105 | 110 | 110 |
| | Electroless Pd | | | | | | | | |
| | Plating | | | | | | | | |
| | (g) After | 105 | 100 | 110 | 110 | 110 | 110 | 110 | 105 |
| | Electroless Au | | | | | | | | |
| | Plating | | | | | | | | |
| | (3) ENEPIG | ◯ | ◯ | ◯ | ◯ | ◯ | X | ◯ | ◯ |
| | Characteristics | | | | | | | | |

As a result, in particular, in Comparative Example 1 in which the contact angle is 100° after (e) dipping in an electroless Ni plating bath having a temperature of 80° C., abnormal deposition of metal occurred after ENEPIG. On the other hand, in the other examples in which the contact angle is equal to or less than 85°, ENEPIG characteristics were satisfactory. In Reference Examples 4 and 5, the contact angle is equal to or greater than 85°. In a printed wiring board using the laminates of Reference 5 and 5, abnormal deposition of metal occurred after ENEPIG. Furthermore, using laminates of Reference Examples 1-1 and 1-2 which contain both of the cyclic siloxane compound (C) and the fine particles, a printed wiring board (double-sided circuit board) in which L/S=10 μm/10 μm was prepared and ENEPIG characteristics were evaluated. As a result, abnormal deposition of metal did not occur and the results were satisfactory.

### Regarding Second Resin Composition

### Example 2-1

1. Preparation of Varnish

1.1 Preparation of Resin Varnish (1A) for Forming Adhesion Layer

30 parts by weight of polyamide resin (manufactured by NIPPON KAYAKU Co., Ltd., BPAM01) having a hydroxyl group, 15 parts by weight of slurry of spherical silica (manufactured by Admatechs., SX009, average particle size: 50 nm) as silica having an average particle size of 100 nm or less, 35 parts by weight of HP-5000 (manufactured by DIC corporation) as an epoxy resin, 19.4 parts by weight of phenol novolac cyanate resin (manufactured by LONZA, Primaset PT-30) as a cyanate ester resin, 0.1 parts by weight of epoxy silane coupling agent (manufactured by Nippon Unicar Company Limited, A187) as a coupling agent, and 0.5 parts by weight of imidazole (manufactured by SHIKOKU CHEMICALS CORPORATION, CUREZOL 1B2PZ) as a curing catalyst were stirred in a mixed solution of dimethylacetamide and methyl ethyl ketone for 60 minutes using a high-speed stirring machine. As a result, a resin varnish (1A) for an insulating layer, which is in contact with a substrate, having a solid content of 30% was prepared.

1.2 Preparation of Resin Varnish (1B) for Forming Resin Layer

65 parts by weight of spherical fused silica (manufactured by Admatechs., SO-25R, average particle size 0.5 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 10 parts by weight of phenol novolac cyanate resin (manufactured by LONZA JAPAN, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (1B) having a solid content of 70% was prepared.

2. Preparation of Resin Sheet (Laminated Base Material for Printed Wiring Board)

The obtained resin varnish (1A) was coated on a single surface of a 36 μm-thick polyethylene terephthalate (PET) film using a comma coater such that the thickness of an adhesion layer after drying be 5 μm, followed by drying for 3 minutes with a drying machine at 160° C. As a result, an adhesion layer was obtained. Next, the resin varnish (1B) was further coated on the upper surface of the adhesion layer using a comma coater such that the total thickness of a resin layer after drying be 30 μm, followed by drying for 3 minutes with a drying machine at 160° C. As a result, a resin layer in which the adhesion layer and the resin layer were laminated on the PET film was obtained.

3. Preparation of Cured Resin Sheet

The vanish for a resin layer which was used in the respective Examples and Comparative Examples was coated on the PET film such that the thickness be 90 μm, followed by applying heat and pressure for molding at a temperature of 200° C. and a pressure of 1.5 MPa in a vacuum. As a result, a cured resin sheet was obtained.

4. Preparation of Printed Wiring Board

In order to measure surface roughness (Ra) and plating peel strength described later, a multilayer printed wiring board was manufactured.

The multilayer printed wiring board was manufactured with a method in which the obtained resin sheet is made to overlap the front and back of an inner layer circuit board, where a predetermined inner layer circuit pattern was formed on both surfaces thereof, such that the insulating layer surface thereof face inside, followed by applying heat and pressure in a vacuum at a temperature of 100° C. and a pressure of 1 MPa using a vacuum pressure laminator and then heating and curing in a hot air drying machine for 60 minutes at 170° C. In addition, as the inner layer circuit board, the following copper-clad laminate was used.
Insulating layer: made of halogen-free FR-4, thickness: 0.4 mm
Conductive Layer: thickness of copper foil: 18 μm, L/S=120/180 μm, clearance hole: 1 mmφ, 3 mmφ, slit: 2 mm

5. Preparation of Semiconductor Device

A substrate was peeled off from the obtained multilayer printed wiring board and an φ60 μm opening (blind via hole) was formed using a carbon laser machine, followed by dipping in a swelling solution at 60° C. (manufactured by Atotech Japan, SWELLING DIP SECURIGANTH P) for 10 minutes, dipping in an aqueous potassium permanganate solution at 80° C. (manufactured by Atotech Japan, CONCENTRATE COMPACT CP) for 20 minutes, and neutralization for roughening. After processes of degreasing, catalyst addition, and activation, a 1 μm-thick electroless copper plating film and a 30 μm-thick electroplating copper film were formed, followed by annealing with a hot air drying machine for 60 minutes at 200° C. Next, a solder resist (manufactured by TAIYO INK MFG. CO., LTD., PSR-4000 AUS703) is printed and a predetermined mask was exposed such that a semiconductor element mounting pad and the like be exposed, followed by development and curing. As a result, a solder resist layer was formed on a circuit such that the thickness thereof be 12 μm.

Finally, a layer, in which a 3-μm thick electroless nickel plating film was formed on a circuit layer exposed through the solder resist and furthermore a 0.1 μm-thick electroless gold plating film was formed thereto, was formed to obtain a substrate. The obtained substrate was cut to 50 mm×50 mm size and thus a multilayer printed wiring board for a semiconductor device was obtained. The semiconductor device was obtained with a method in which a semiconductor element (TEG chip, size: 15 mm×15 mm, thickness: 0.8 mm) having a solder bump was mounted on the multilayer printed wiring board for the semiconductor device by applying heat and pressure using a flip chip bonder; the solder bump was melted and joined in an IR reflow furnace and was filled with a liquid sealing resin (manufactured by SUMITOMO BAKELITE CO., LTD., CRP-4152S); and the liquid sealing resin was cured. In this case, the liquid sealing resin was cured for 120 minutes at a temperature of 150° C. In addition, the solder bump of the semiconductor element was formed of eutectic crystal of Sn/Pb composition.

### Example 2-2

A resin sheet, a cured resin sheet, a multilayer printed wiring board, and a semiconductor device were obtained in the same manner as that of Example 1, except that the following resin varnish (2A) was used instead of the resin varnish (1A).

Preparation of Resin Varnish (2A) for Forming Adhesion Layer

35 parts by weight of polyamide resin (manufactured by NIPPON KAYAKU Co., Ltd., BPAM01) having a hydroxyl group, 40 parts by weight of HP-5000 (manufactured by DIC corporation) as an epoxy resin, 24. 5 parts by weight of phenol novolac cyanate resin (manufactured by LONZA, Primaset PT-30) as a cyanate ester resin, 0.5 parts by weight of imidazole (manufactured by SHIKOKU CHEMICALS CORPORATION, CUREZOL 1B2PZ) as a curing catalyst were stirred in a mixed solution of dimethylacetamide and methyl ethyl ketone for 60 minutes using a high-speed stirring machine. As a result, a varnish (2A) for an insulating layer, which is in contact with a substrate, having a solid content of 30% was prepared.

### Example 2-3

A resin sheet, a cured resin sheet, a multilayer printed wiring board, and a semiconductor device were obtained in the same manner as that of Example 1, except that the following resin varnish (3A) was used instead of the resin varnish (1A).

Preparation of Resin Varnish (3A) for Forming Adhesion Layer

30 parts by weight of polyamide resin (manufactured by NIPPON KAYAKU Co., Ltd., BPAM01) having a hydroxyl group, 15 parts by weight of slurry of spherical silica (manufactured by Admatechs., SC1030, average particle size: 300 nm), 35 parts by weight of HP-5000 (manufactured by DIC corporation) as an epoxy resin, 19.4 parts by weight of phenol novolac cyanate resin (manufactured by LONZA, Primaset PT-30) as a cyanate ester resin, 0.1 parts by weight of epoxy silane coupling agent (manufactured by Nippon Unicar Company Limited, A187) as a coupling agent, and 0.5 parts by weight of imidazole (manufactured by SHIKOKU CHEMICALS CORPORATION, CUREZOL 1B2PZ) as a curing catalyst were stirred in a mixed solution of dimethylacetamide and methyl ethyl ketone for 60 minutes using a high-speed stirring machine. As a result, a varnish (3A) for an insulating layer, which is in contact with a substrate, having a solid content of 30% was prepared.

### Example 2-4

A resin sheet, a cured resin sheet, a multilayer printed wiring board, and a semiconductor device were obtained in the same manner as that of Example 1, except that the following resin varnish (4B) was used instead of the resin varnish (1B).

Preparation of Resin Varnish (4B) for Forming Resin Layer

65 parts by weight of spherical fused silica (manufactured by Admatechs., SO-25R, average particle size 0.5 μm) as an inorganic filler, methyl ethyl ketone as a solvent, 0.5 parts by weight of PMCPS (reagent) as a cyclic siloxane compound, 20 parts by weight of dicyclopentadiene epoxy resin (manufactured by DIC corporation, HP-7200) as an epoxy resin, 10 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a varnish (4B) having a solid content of 70% was prepared.

### Example 2-5

A resin sheet, a cured resin sheet, a multilayer printed wiring board, and a semiconductor device were obtained in the same manner as that of Example 1, except that the following resin varnish (5B) was used instead of the resin varnish (1B).

Preparation of Resin Varnish (5B) for Forming Resin Layer

65 parts by weight of spherical fused silica (manufactured by Admatechs., SO-25R, average particle size 0.5 μm) as an inorganic filler, methyl ethyl ketone as a solvent, 0.5 parts by weight of PMCPS (reagent) as a cyclic siloxane compound, 20 parts by weight of methoxynaphthalene aralkyl epoxy resin (manufactured by DIC corporation, HP-5000) as an epoxy resin, 10 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a varnish (5B) having a solid content of 70% was prepared.

### Example 2-6)

A resin sheet, a cured resin sheet, a multilayer printed wiring board, and a semiconductor device were obtained in the same manner as that of Example 1, except that the following resin varnish (6B) was used instead of the resin varnish (1B).

Preparation of Resin Varnish (6B) for Forming Resin Layer

65 parts by weight of spherical fused silica (manufactured by Admatechs., SO-25R, average particle size 0.5 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 10 parts by weight of dicyclopentadiene cyanate resin (manufactured by LONZA, DT-4000) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a varnish (6B) having a solid content of 70% was prepared.

### Example 2-7

A resin sheet, a cured resin sheet, a multilayer printed wiring board, and a semiconductor device were obtained in the same manner as that of Example 1, except that the following resin varnish (7B) was used instead of the resin varnish (1B).

Preparation of Resin Varnish (7B) for Forming Resin Layer

65 parts by weight of spherical fused silica (manufactured by Admatechs., SO-25R, average particle size 0.5 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 3.8 parts by weight of phenoxy resin (manufactured by Mitsubishi Chemical Corporation, jER-4275), 10 parts by weight of phenol resin (manufactured by NIPPON KAYAKU Co., Ltd., GPH-103), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a varnish (7B) having a solid content of 70% was prepared.

### Example 2-8

A resin sheet, a cured resin sheet, a multilayer printed wiring board, and a semiconductor device were obtained in the same manner as that of Example 1, except that the following resin varnish (8A) was used instead of the resin varnish (1A).

Preparation of Resin Varnish (8A) for Forming Adhesion Layer

40 parts by weight of polyamide resin (manufactured by NIPPON KAYAKU Co., Ltd., BPAM01) having a hydroxyl group, 58 parts by weight of HP-5000 (manufactured by DIC corporation) as an epoxy resin, and 2 parts by weight of imidazole (manufactured by SHIKOKU CHEMICALS CORPORATION, CUREZOL 1B2PZ) as a curing catalyst were stirred in a mixed solution of dimethylacetamide and methyl ethyl ketone for 60 minutes using a high-speed stirring machine. As a result, a varnish (8A) for an insulating layer, which is in contact with a substrate, having a solid content of 30% was prepared.

### Example 2-9

A resin sheet, a cured resin sheet, a multilayer printed wiring board, and a semiconductor device were obtained in the same manner as that of Example 6, except that the following resin varnish (9A) was used instead of the resin varnish (1A).

Preparation of Resin Varnish (9A) for Forming Adhesion Layer

45 parts by weight of HP-5000 (manufactured by DIC corporation) as an epoxy resin, 29.6 parts by weight of phenol novolac cyanate resin (manufactured by LONZA, Primaset PT-30) as a cyanate ester resin, and 0.4 parts by weight of imidazole (manufactured by SHIKOKU CHEMICALS CORPORATION, CUREZOL 1B2PZ) as a curing catalyst were stirred in a mixed solution of dimethylacetamide and methyl ethyl ketone for 60 minutes using a high-speed stirring machine. As a result, a varnish (9A) for an insulating layer, which is in contact with a substrate, having a solid content of 30% was prepared.

### Example 2-10

A resin sheet, a cured resin sheet, a multilayer printed wiring board, and a semiconductor device were obtained in the same manner as that of Example 1, except that the following resin varnish (10B) was used instead of the resin varnish (1B).

Preparation of Resin Varnish (10B) for Forming Resin Layer

65 parts by weight of spherical fused silica (manufactured by Admatechs., SO-25R, average particle size 0.5 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 10 parts by weight of phenol novolac cyanate resin (manufactured by LONZA, Primaset PT-30) as a cyanate ester resin, 3.5 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.5 parts by weight of adduct of tetraphenyl phosphonium and bis(naphthalene-2,3-dioxy)phenyl silicate (manufactured by SUMITOMO BAKELITE CO., LTD., C05-MB) as a curing accelerator were added, followed by stirring for 60 minutes using a high-speed stirring machine. As a result, a varnish (10B) having a solid content of 70% was prepared.

### Example 2-11

A resin sheet, a cured resin sheet, a multilayer printed wiring board, and a semiconductor device were obtained in the same manner as that of Example 1, except that the following resin varnish (11B) was used instead of the resin varnish (1B).

Preparation of Resin Varnish (11B) for Forming Resin Layer

65 parts by weight of spherical fused silica (manufactured by Admatechs., SO-31R, average particle size 1.0 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 10 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (11B) having a solid content of 70% was prepared.

### Example 2-12

A resin sheet, a cured resin sheet, a multilayer printed wiring board, and a semiconductor device were obtained in the same manner as that of Example 1, except that the following resin varnish (12B) was used instead of the resin varnish (1B).

Preparation of Resin Varnish (12B) for Forming Resin Layer

50 parts by weight of spherical fused silica (manufactured by Admatechs., SO-25R, average particle size 0.5 μm) and 15 parts by weight of spherical fused silica (manufactured by Admatechs., SO-22R, average particle size 0.3 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 10 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (12B) having a solid content of 70% was prepared.

### Example 2-14

A resin sheet, a cured resin sheet, a multilayer printed wiring board, and a semiconductor device were obtained in the same manner as that of Example 1, except that the following resin varnish (14B) was used instead of the resin varnish (1B).

Preparation of Resin Varnish (14B) for Forming Resin Layer

55 parts by weight of spherical fused silica (manufactured by Admatechs., SO-31R, average particle size 1.0 μm) as an inorganic filler, methyl ethyl ketone as a solvent, 0.5 parts by weight of TMCTS (reagent) as a cyclic siloxane compound, 43 parts by weight of dicyclopentadiene epoxy resin (manufactured by DIC corporation, HP-7200) as an epoxy resin, 0.5 parts by weight of epoxy silane coupling agent (manufactured by Nippon Unicar Company Limited, A187) as a coupling agent, and 1 parts by weight of adduct of tetraphenyl phosphonium and bis(naphthalene-2,3-dioxy)phenyl silicate (manufactured by SUMITOMO BAKELITE CO., LTD., C05-MB) as a curing accelerator were added, followed by stirring for 60 minutes using a high-speed stirring machine. As a result, a varnish (14B) having a solid content of 70% was prepared.

### Example 2-15

A resin sheet, a cured resin sheet, a multilayer printed wiring board, and a semiconductor device were obtained in the same manner as that of Example 1, except that the following resin varnish (15B) was used instead of the resin varnish (1B).

Preparation of Resin Varnish (15B) for Forming Resin Layer

60 parts by weight of spherical fused silica (manufactured by Admatechs., SO-25R, average particle size 0.5 μm) as an inorganic filler, methyl ethyl ketone as a solvent, 0.5 parts by weight of TMCTS (reagent) as a cyclic siloxane compound, 23 parts by weight of dicyclopentadiene epoxy resin (manufactured by DIC corporation, HP-7200) as an epoxy resin, 12 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (15B) having a solid content of 70% was prepared.

### Example 2-16

A resin sheet, a cured resin sheet, a multilayer printed wiring board, and a semiconductor device were obtained in the same manner as that of Example 1, except that the following resin varnish (16B) was used instead of the resin varnish (1B).

Preparation of Resin Varnish (16B) for Forming Resin Layer

70 parts by weight of spherical fused silica (manufactured by Admatechs., SO-25R, average particle size 0.5 μm) as an inorganic filler, methyl ethyl ketone as a solvent, 0.5 parts by weight of TMCTS (reagent) as a cyclic siloxane compound, 18 parts by weight of dicyclopentadiene epoxy resin (manufactured by DIC corporation, HP-7200) as an epoxy resin, 7 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (16B) having a solid content of 70% was prepared.

### Example 2-17

A resin sheet, a cured resin sheet, a multilayer printed wiring board, and a semiconductor device were obtained in the same manner as that of Example 1, except that the following resin varnish (17B) was used instead of the resin varnish (1B).

Preparation of Resin Varnish (17B) for Forming Resin Layer

10 parts by weight of spherical fused silica (manufactured by Admatechs., SO-25R, average particle size 0.5 μm) and 55 parts by weight of spherical fused silica (manufactured by Admatechs., SO-C6, average particle size 2.0 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 10 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (17B) having a solid content of 70% was prepared.

### Example 2-18

A resin sheet, a cured resin sheet, a multilayer printed wiring board, and a semiconductor device were obtained in the same manner as that of Example 1, except that the following resin varnish (18B) was used instead of the resin varnish (1B).

Preparation of Resin Varnish (18B) for Forming Resin Layer

35 parts by weight of spherical fused silica (manufactured by Admatechs., SO-31R, average particle size 1.0 μm) and 25 parts by weight of spherical fused silica (manufactured by Admatechs., SO-C6, average particle size 2.2 μm) as an inorganic filler, methyl ethyl ketone as a solvent, 0.5 parts by weight of TMCTS (reagent) as a cyclic siloxane compound, 28 parts by weight of dicyclopentadiene epoxy resin (manufactured by DIC corporation, HP-7200) as an epoxy resin, 12 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (18B) having a solid content of 70% was prepared.

### Example 2-19

A resin sheet, a cured resin sheet, a multilayer printed wiring board, and a semiconductor device were obtained in the same manner as that of Example 1, except that the following resin varnish (19B) was used instead of the resin varnish (1B).

Preparation of Resin Varnish (19B) for Forming Resin Layer

72 parts by weight of spherical fused silica (manufactured by Admatechs., SO-25R, average particle size 0.5 μm) as an inorganic filler, methyl ethyl ketone as a solvent, 0.7 parts by weight of TMCTS (reagent) as a cyclic siloxane compound, 20 parts by weight of dicyclopentadiene epoxy resin (manufactured by DIC corporation, HP-7200) as an epoxy resin, 3 parts by weight of phenol novolac cyanate resin (manufactured by LONZA, Primaset PT-30) as a cyanate ester resin, 3.6 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (19B) having a solid content of 70% was prepared.

### Example 2-20

A resin sheet, a cured resin sheet, a multilayer printed wiring board, and a semiconductor device were obtained in the same manner as that of Example 1, except that the following resin varnish (20B) was used instead of the resin varnish (1B).

Preparation of Resin Varnish (20B) for Forming Resin Layer

59 parts by weight of spherical fused silica (manufactured by Admatechs., SO-25R, average particle size 0.5 μm) and 6 parts by weight of spherical fused silica (manufactured by Admatechs., SO-22R, average particle size 0.3 μm) as an inorganic filler, methyl ethyl ketone as a solvent, 0.5 parts by weight of TMCTS (reagent) as a cyclic siloxane compound, 20 parts by weight of dicyclopentadiene epoxy resin (manufactured by DIC corporation, HP-7200) as an epoxy resin, 10 parts by weight of phenol novolac cyanate resin (manufactured by LONZA, Primaset PT-30) as a cyanate ester resin, 3.8 parts by weight of phenoxy resin (manufactured by Mitsubishi Chemical Corporation, jER-4275), 0.5 parts by weight of epoxy silane coupling agent (manufactured by Nippon Unicar Company Limited, A187) as a coupling agent, and 0.2 parts by weight of imidazole (manufactured by SHIKOKU CHEMICALS CORPORATION, CUREZOL 1B2PZ) as a curing catalyst were added, followed by stirring for 60 minutes using a high-speed stirring machine. As a result, a resin varnish (12B) having a solid content of 70% was prepared.

### Comparative Example 2-1

A resin sheet, a cured resin sheet, a multilayer printed wiring board, and a semiconductor device were obtained in the same manner as that of Example 1, except that the following resin varnish (3C) was used instead of the resin varnish (1B).

Preparation of Resin Varnish (3C) for Forming Resin Layer

70 parts by weight of spherical fused silica (manufactured by Admatechs., SO-25R, average particle size 0.5 μm) as an inorganic filler, methyl ethyl ketone as a solvent, 3 parts by weight of dicyclopentadiene epoxy resin (manufactured by DIC corporation, HP-7200) as an epoxy resin, 26 parts by weight of phenol novolac cyanate resin (manufactured by LONZA, Primaset PT-30) as a cyanate ester resin, 0.5 parts by weight of epoxy silane coupling agent (manufactured by Nippon Unicar Company Limited, A187) as a coupling agent, and 0.5 parts by weight of adduct of tetraphenyl phosphonium and bis(naphthalene-2,3-dioxy)phenyl silicate (manufactured by SUMITOMO BAKELITE CO., LTD., C05-MB) as a curing accelerator were added, followed by stirring for 60 minutes using a high-speed stirring machine. As a result, a resin varnish (3C) having a solid content of 70% was prepared.

The mixed components of the resin varnishes used in the respective Examples and Comparative Examples; and the resin sheets, the prepregs, the multilayer printed wiring boards; and the evaluation results for the semiconductor devices obtained in the respective Examples and Comparative Examples, are shown in Tables 5 to 7.

The respective evaluation items were evaluated in the following methods.

(1) Water Absorption of Each Resin of Resin Layer

The obtained double-sided copper-clad laminate was cut to 50 mm² to obtain samples; the weight of a sample after being left to stand for 2 hours in a drying machine at 120° C. and the weight of a sample after being left to stand for 2 hours in a bath at 121° C. and a humidity of 100% were respectively measured, and the water absorption of each resin can be obtained according to the following expression.

water absorption (%) of each resin=((B−A)/A)×100×(100/(100−X)) Expression

A: weight (mg) of sample after being left to stand for 2 hours in drying machine at 120° C.

B: weight (mg) of sample after being left to stand for 2 hours in bath at 121° C. and humidity of 100%

X: % by weight (%) of inorganic filler of resin layer (100% by weight)

(2) Coefficient of Thermal Expansion

A 4 mm×20 mm evaluation sample was obtained from the obtained cured resin, the temperature was raised and dropped from 0° C. to 260° C. at 10° C./min for the measurement using a thermo-mechanical analyzer (TMA; manufactured by TA Instruments. Japan). The coefficient of expansion from 50° C. to 100° C. was calculated.

(3) Processability (Laminating Property)

The obtained insulating resin sheet with a film was laminated on a circuit board having a circuit layer, in which wiring width/wiring interval/thickness=20 μm/20 μm/10 μm, using a vacuum laminator under conditions of a temperature of 120° C. and a pressure of 1.0 MPa. Then, the film was peeled off, followed by heating with a drying machine at 170° C. for 1 hour to cure a resin composition. As a result, an insulating resin layer was formed. The cross-section of the circuit board having the obtained insulating resin layer was observed and the embedability of the resin between wirings was evaluated. The symbol represent as follows.

©: Satisfactory; resin was embedded without a gap

◯: Practically no problem; a small and round void of 2 μm or less was found

Δ: Practically unusable; a void of 2 μm or greater was found

X: Unusable; defective embedding

(4) Surface Roughness After Desmear Process (Desmear Property)

After roughening the obtained multilayer printed wiring board, the surface roughness (Ra) was measured using a laser microscope (manufactured by KEYENCE CORPORATION, VK-8510, conditions: pitch of 0.02 μm, Run mode of color ultra-depth). Ra was obtained by measuring ten points and calculating the average value of the ten points.

(5) Plating Peel

Using the multilayer printed wiring board, the peel strength of a plating copper film was measured according to JIS C-6481.

(6) Insulating Reliability between Vias

Multilayer printed wiring boards having via wall thicknesses of 50 μm and 100 μm were manufactured, a voltage of 20V was applied thereto under conditions of PCT-130° C. and 85%, and insulating properties were examined after 200 hours.

©: In both cases of via wall thicknesses of 50 μm and 100 μm, 1E08Ω or higher was maintained after 200 hours

◯: In the case of the via wall thickness of 100 μm, 1E08Ω or higher was maintained after 200 hours

Δ: In either cases of via wall thicknesses of 50 μm or 100 μm, short-circuit did not occur but 1E08Ω or higher was not maintained

X: In either cases of via wall thicknesses of 50 μm or 100 μm, short-circuit occurred

(7) Thermal Shock Test

The obtained semiconductor device was treated in Fluorinert 1000 cycles, in which the treatment at −55° C. for 30 minutes and at 125° C. for 30 minutes was set as one cycle. Then, whether there are cracks or not in a substrate, a semiconductor element, and the like was examined. The respective symbols represent as follows.

◯: No cracks occurred

X: Cracks occurred

(8) Heat Resistance

The obtained semiconductor device was caused to pass through a reflow oven at 260° C. and whether there is swelling or not was examined by observing the cross-section thereof. The semiconductor device was caused to pass through the reflow oven 30 times. As the reflow condition, the temperature was gradually raised from room temperature (25° C.) to 160° C. (50 to 60 seconds). Next, the temperature was raised from 160° C. to 200° C. for 50 to 60 seconds. Then, the temperature was raised from 200° C. to 260° C. for 65 to 75 seconds and furthermore heating (reflow) was performed at a temperature of 260 to 262° C. for 5 to 10 seconds. Then, cooling was performed to 30° C. for 15 minutes.

◯: No problems

X: When the cross-section was observed, swelling was found between copper and resin

TABLE 5

| | | Exam- | Exam- | Exam- | Exam- | Exam- | Exam- | Exam- | Exam- | Exam- | Exam- |
|---|---|---|---|---|---|---|---|---|---|---|---|
| | | ple | ple | ple | ple | ple | ple | ple | ple | ple | ple |
| | | 2-1 | 2-2 | 2-3 | 2-4 | 2-5 | 2-6 | 2-7 | 2-8 | 2-9 | 2-10 |
| [Adhesion Layer (A Layer)] | | | | | | | | | | | |
| Aromatic | BPAM01 (Polyamide Resin Containing | 30 | 35 | 30 | 30 | 30 | 30 | 30 | 40 | | 30 |
| Polyamide | Hydroxyl Group and Rubber Component) | | | | | | | | | | |
| Resin | | | | | | | | | | | |
| Inorganic | SX009 (Silica Having Average Particle | 15 | | | 15 | 15 | 15 | 15 | | | 15 |
| Filler | Size of 50 nm) | | | | | | | | | | |
| Epoxy | HP5000 (Methoxynaphthalene Aralkyl | 35 | 40 | 35 | 35 | 35 | 35 | 35 | 58 | 45 | 35 |
| Resin | Epoxy Resin) | | | | | | | | | | |
| Cyanate | PT-30 (Novolac Cyanate Resin) | 19.4 | 24.5 | 19.4 | 19.4 | 19.4 | 19.4 | 19.4 | | 29.6 | 19.4 |
| Ester | | | | | | | | | | | |
| Resin | | | | | | | | | | | |
| | A187 (Epoxy Silane Coupling Agent) | 0.1 | | 0.1 | 0.1 | 0.1 | 0.1 | 0.1 | | | 0.1 |
| | 1B2PZ (1-Benzyl-2-Phenylimidazole) | 0.5 | 0.5 | 0.5 | 0.5 | 0.5 | 0.5 | 0.5 | 2 | 0.4 | 0.5 |
| | SC-1030 (Silica Having Average | | | 15 | | | | | | 25 | |
| | Particle Size of 0.3 μm) | | | | | | | | | | |
| Total | | 100 | 100 | 100 | 100 | 100 | 100 | 100 | 100 | 100 | 100 |
| [Resin Layer (B layer)] | | | | | | | | | | | |
| Inorganic | SO-25R (Fused Silica) | 65 | 65 | 65 | 65 | 65 | 65 | 65 | 65 | 65 | 65 |
| Filler | | | | | | | | | | | |
| Coupling | TMCTS (1,3,5,7-Tetramethylcyclotetra- | 0.5 | 0.5 | 0.5 | | 0.5 | 0.5 | 0.5 | 0.5 | 0.5 | 0.5 |
| Agent | siloxane) | | | | | | | | | | |
| | PMCPS (1,3,5,7,9-Pentamethylcyclo- | | | | 0.5 | | | | | | |
| | pentasiloxane) | | | | | | | | | | |
| Epoxy | HP-7200 (Dicyclopentadiene Epoxy | 20 | 20 | 20 | 20 | | 20 | 20 | 20 | 20 | 20 |
| Resin | Resin) | | | | | | | | | | |
| | HP-5000 (Methoxynaphthalene Aralkyl | | | | | 20 | | | | | |
| | Epoxy Resin) | | | | | | | | | | |
| Cyanate | PT-30 (novolac cyanate resin) | 10 | 10 | 10 | 10 | 10 | | | 10 | 10 | 10 |
| Ester | DT-4000 (Dicyclopentadiene Cyanate | | | | | | 10 | | | | |
| Resin | Resin) | | | | | | | | | | |
| | jER-4275 (BisA + BisF Structure | 3.8 | 3.8 | 3.8 | 3.8 | 3.8 | 3.8 | 3.8 | 3.8 | 3.8 | 3.5 |
| | Phenoxy Resin) | | | | | | | | | | |
| | GPH-103 (Biphenyl Aralkyl Phenol | | | | | | | 10 | | | |
| | Resin) | | | | | | | | | | |
| | A187 (Epoxy Silane Coupling Agent) | 0.5 | 0.5 | 0.5 | 0.5 | 0.5 | 0.5 | 0.5 | 0.5 | 0.5 | 0.5 |
| | 1B2PZ (1-Benzyl-2-Phenylimidazole) | 0.2 | 0.2 | 0.2 | 0.2 | 0.2 | 0.2 | 0.2 | 0.2 | 0.2 | |
| | C05-MB | | | | | | | | | | 0.5 |
| Total | | 100 | 100 | 100 | 100 | 100 | 100 | 100 | 100 | 100 | 100 |
| Total Surface Area (m²/g) Of Inorganic Filler | | 3.9 | 3.9 | 3.9 | 3.9 | 3.9 | 3.9 | 3.9 | 3.9 | 3.9 | 3.9 |
| Included In Resin Layer Per Unit Weight | | | | | | | | | | | |
| [Physical Properties] | | | | | | | | | | | |
| Cured | Water Absorption (%) of Cured | 2.1 | 2.1 | 2.1 | 2.1 | 2.4 | 2.0 | 1.9 | 2.1 | 2.1 | 1.9 |
| Resin | Material of Cured Resin Sheet A | | | | | | | | | | |
| Sheet | Coefficient of Thermal Expansion | 21 | 23 | 21 | 21 | 22 | 25 | 24 | 25 | 18 | 21 |
| | (ppm) of Cured Resin Sheet B | | | | | | | | | | |
| Multilayer | Processability | © | © | © | © | © | © | © | © | © | © |
| Printed | Desmear Property, Surface | 0.21 | 0.12 | 0.36 | 0.2 | 0.25 | 0.22 | 0.21 | 0.11 | 0.03 | 0.2 |
| Wiring | Roughness Ra (μm) | | | | | | | | | | |
| Board | Plating Peel Strength (kgf/cm) | 0.75 | 0.79 | 0.68 | 0.76 | 0.65 | 0.75 | 0.78 | 0.79 | 0.43 | 0.75 |
| | Insulating Reliability between Vias | © | © | © | © | © | © | © | © | © | © |
| Semi- | Thermal Shock Test | ◯ | ◯ | ◯ | ◯ | ◯ | ◯ | ◯ | ◯ | ◯ | ◯ |
| conductor | Heat Resistance | ◯ | ◯ | ◯ | ◯ | ◯ | ◯ | ◯ | ◯ | ◯ | ◯ |
| Device | | | | | | | | | | | |

TABLE 6

| | | Exam- | Exam- | Exam- | Exam- | Exam- | Exam- | Exam- | Exam- | Exam- |
|---|---|---|---|---|---|---|---|---|---|---|
| | | ple | ple | ple | ple | ple | ple | ple | ple | ple |
| | | 2-11 | 2-12 | 2-14 | 2-15 | 2-16 | 2-17 | 2-18 | 2-19 | 2-20 |
| [Adhesion Layer (A Layer)] | | | | | | | | | | |
| Aromatic | BPAM01 (Polyamide Resin Containing Hydroxyl | 30 | 30 | 30 | 30 | 30 | 30 | 30 | 30 | 30 |
| Polyamide | Group and Rubber Component) | | | | | | | | | |
| Resin | | | | | | | | | | |
| Inorganic | SX009 (Silica Having Average Particle Size of | 15 | 15 | 15 | 15 | 15 | 15 | 15 | 15 | 15 |
| Filler | 50 nm) | | | | | | | | | |
| Epoxy | HP5000 (Methoxynaphthalene Aralkyl Epoxy | 35 | 35 | 35 | 35 | 35 | 35 | 35 | 35 | 35 |
| Resin | Resin) | | | | | | | | | |
| Cyanate | PT-30 (Novolac Cyanate Resin) | 19.4 | 19.4 | 19.4 | 19.4 | 19.4 | 19.4 | 19.4 | 19.4 | 19.4 |
| Ester | | | | | | | | | | |
| Resin | | | | | | | | | | |
| | A187 (Epoxy Silane Coupling Agent) | 0.1 | 0.1 | 0.1 | 0.1 | 0.1 | 0.1 | 0.1 | 0.1 | 0.1 |
| | 1B2PZ (1-Benzyl-2-Phenylimidazole) | 0.5 | 0.5 | 0.5 | 0.5 | 0.5 | 0.5 | 0.5 | 0.5 | 0.5 |
| Total | | 100 | 100 | 100 | 100 | 100 | 100 | 100 | 100 | 100 |
| [Resin Layer (B layer)] | | | | | | | | | | |
| Inorganic | SO-25R (Fused Silica) | | 50 | | 60 | 70 | 10 | | 72 | 59 |
| Filler | SO-31R (Fused Silica) | 65 | | 55 | | | | 35 | | |
| | SO-22R (Fused Silica) | | 15 | | | | | | | 6 |
| | SO-C6R (Fused Silica) | | | | | | 55 | 25 | | |
| Coupling | TMCTS | 0.5 | 0.5 | 0.5 | 0.5 | 0.5 | 0.5 | 0.5 | 0.7 | 0.5 |
| Agent | (1,3,5,7-Tetramethylcyclotetrasiloxane) | | | | | | | | | |
| | PMCPS | | | | | | | | | |
| | (1,3,5,7,9-Pentamethylcyclopentasiloxane) | | | | | | | | | |
| Epoxy | HP-7200 (Dicyclopentadiene Epoxy Resin) | 20 | 20 | 43 | 23 | 18 | 20 | 28 | 20 | 20 |
| Resin | | | | | | | | | | |
| Cyanate | PT-30 (novolac cyanate resin) | 10 | 10 | | 12 | 7 | 10 | 12 | 3 | 10 |
| Ester | | | | | | | | | | |
| Resin | | | | | | | | | | |
| | jER-4275 (BisA + BisF Structure Phenoxy | 3.8 | 3.8 | | 3.8 | 3.8 | 3.8 | 3.8 | 3.6 | 3.8 |
| | Resin) | | | | | | | | | |
| | A187 (Epoxy Silane Coupling Agent) | 0.5 | 0.5 | 0.5 | 0.5 | 0.5 | 0.5 | 0.5 | 0.5 | 0.5 |
| | 1B2PZ (1-Benzyl-2-Phenylimidazole) | 0.2 | 0.2 | | 0.2 | 0.2 | 0.2 | 0.2 | 0.2 | 0.2 |
| | C05-MB | | | 1 | | | | | | |
| Total | | 100 | 100 | 100 | 100 | 100 | 100 | 105 | 100 | 100 |
| Total Surface Area (m²/g) Of Inorganic Filler Included | | 2.9 | 6.0 | 2.5 | 3.6 | 4.2 | 1.6 | 2.1 | 4.3 | 4.7 |
| In Resin Layer Per Unit Weight | | | | | | | | | | |
| [Physical Properties] | | | | | | | | | | |
| Cured | Water Absorption (%) of Cured Material of | 1.8 | 2.4 | 1.3 | 1.9 | 2.3 | 1.6 | 1.8 | 2.4 | 2.3 |
| Resin | Cured Resin Sheet A | | | | | | | | | |
| Sheet | Coefficient of Thermal Expansion (ppm) of | 21 | 22 | 33 | 26 | 20 | 21 | 28 | 18 | 22 |
| | Cured Resin Sheet B | | | | | | | | | |
| Multilayer | Processability | ◯ | Δ | © | © | ◯ | © | © | ◯ | Δ |
| Printed | Desmear Property, Surface Roughness Ra (μm) | 0.22 | 0.41 | 0.15 | 0.18 | 0.25 | 0.19 | 0.2 | 0.31 | 0.31 |
| Wiring | Plating Peel Strength (kgf/cm) | 0.81 | 0.54 | 0.75 | 0.79 | 0.71 | 0.77 | 0.75 | 0.69 | 0.66 |
| Board | Insulating Reliability between Vias | ◯ | © | ◯ | © | © | Δ | Δ | © | © |
| Semi- | Thermal Shock Test | ◯ | ◯ | ◯ | ◯ | ◯ | ◯ | ◯ | ◯ | ◯ |
| conductor | Heat Resistance | ◯ | ◯ | ◯ | ◯ | ◯ | ◯ | ◯ | ◯ | ◯ |
| Device | | | | | | | | | | |

TABLE 7

Compar-
ative
Example
2-1

[Adhesion Layer (A Layer)

| | | |
|---|---|---|
| Aromatic | BPAM01 (Polyamide Resin Containing Hydroxyl | 30 |
| Polyamide | Group and Rubber Component) | |
| Resin | | |
| Inorganic | SX009 (Silica Having Average Particle Size | 15 |
| Filler | of 50 nm) | |
| Epoxy | HP5000 (Methoxynaphthalene Aralkyl Epoxy | 35 |
| Resin | Resin) | |
| Cyanate | PT-30 (Novolac Cyanate Resin) | 19.4 |
| Ester | | |
| Resin | | |
| | A187 (Epoxy Silane Coupling Agent) | 0.1 |
| | 1B2PZ (1-Benzyl-2-Phenylimidazole) | 0.5 |

| | |
|---|---|
| Total | 100 |

[Resin Layer (B Layer)]

| | | |
|---|---|---|
| Inorganic | SO-25R (Fused Silica) | 70 |
| Filler | | |
| Coupling | TMCTS (1,3,5,7- | |
| Agent | Tetramethylcyclotetrasiloxane) | |
| | PMCPS (1,3,5,7,9- | |
| | Pentamethylcyclopentasiloxane) | |
| Epoxy | HP-7200 (Dicyclopentadiene Epoxy Resin) | 3 |
| Resin | | |
| Cyanate | PT-30 (novolac cyanate resin) | 26 |
| Ester | | |
| Resin | | |
| | jER-4275 (BisA + BisF Structure Phenoxy | |
| | Resin) | |
| | A187 (Epoxy Silane Coupling Agent) | 0.5 |
| | 1B2PZ (1-Benzyl-2-Phenylimidazole) | |
| | C05-MB | 0.5 |

| | |
|---|---|
| Total | 100 |
| Total Surface Area (m²/g) Of Inorganic Filler Included | 4.2 |
| In Resin Layer Per Unit Weight | |

[Physical Properties]

| | | |
|---|---|---|
| Cured | Water Absorption (%) of Cured Material | 3.0 |
| Resin | of Cured Resin Sheet A | |
| Sheet | Coefficient of Thermal Expansion (ppm) | 19 |
| | of Cured Resin Sheet B | |
| Multilayer | Processability | ◯ |
| Printed | Desmear Property, Surface Roughness Ra (μm) | 0.45 |
| Wiring | Plating Peel Strength (kgf/cm) | 0.26 |
| Board | | |
| Semi- | Insulating Reliability between Vias | © |
| conductor | Thermal Shock Test | ◯ |
| Device | Heat Resistance | X |

In Examples 2-1 to 2-12 and 2-14 to 2-20, all the evaluation results for moldability and the like were satisfactory. However, In Comparative Example 1 in which the cyclic siloxane compound (C) was not mixed into the resin layer, plating peel strength was low and heat resistance deteriorated.

This application claims priority based on Japanese patent application No. 2010-107694 filed on May 7, 2010 and Japanese patent application No. 2010-110645 filed on May 12, 2010, the entire contents of which are incorporated hereinto by reference.

1. An epoxy resin composition for a circuit board comprising:
an epoxy resin (A);
an inorganic filler (B); and
a cyclic siloxane compound (C) having at least two Si—H bonds or two Si—OH bonds.

2. The epoxy resin composition for a circuit board according to claim 1,
wherein the cyclic siloxane compound (C) having at least two Si—H bonds or two Si—OH bonds is represented by Formula (1) below. 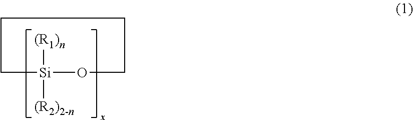
wherein x represents an integer of equal to or more than 2 and equal to or less than 10;
R₁'s may be the same as or different from each other and represent a group having an atom selected from an oxygen atom, a boron atom, and a nitrogen atom; and
R₂ represents a hydrogen atom or a saturated or unsaturated hydrocarbon group having 1 to 20 carbon atoms, in which at least two of R₁'s and R₂'s represent a hydrogen atom or a hydroxyl group.

3. The epoxy resin composition for a circuit board according to claim 1, further comprising:
a cyanate resin composition.

4. A prepreg obtained by impregnating a substrate with an epoxy resin composition for a circuit board,
wherein the epoxy resin composition for a circuit board is the epoxy resin composition for a circuit board according to claim 1.

5. A metal-clad laminate comprising a metal foil at least on a single surface of the prepreg according to claim 4 or at least on a single surface of a laminate obtained by making two or more said prepregs overlap.

6. A resin sheet comprising:
a support substrate; and
an insulating layer which is formed over the support substrate and is formed of an epoxy resin composition for a circuit board,
wherein the support substrate is a film or a metal foil, and
the epoxy resin composition for a circuit board is the epoxy resin composition for a circuit board according to claim 1.

7. A printed wiring board obtained by using the metal-clad laminate according to claim 5 as an inner layer circuit board.

8. A printed wiring board obtained by laminating the prepreg according to claim 4 over a circuit of an inner layer circuit board.

9. A printed wiring board obtained by laminating the prepreg according to claim 4 or the resin sheet according to claim 6 over a circuit of an inner layer circuit board.

10. A semiconductor device obtained by mounting a semiconductor element over a printed wiring board,
wherein the printed wiring board is the printed wiring board according to claim 7.

11. A laminated base material for a printed wiring board comprising:
a support substrate;
an adhesive layer which is formed over the support substrate; and
a resin layer which is formed over the adhesive layer,
wherein the resin layer contains an epoxy resin (A), an inorganic filler (B), and a cyclic or cage-shape siloxane compound (C) having at least two bonds selected from a group consisting of an Si—H bond and an Si—OH bond.

12. The laminated base material for a printed wiring board according to claim 11,
wherein the cyclic or cage-shape siloxane compound (C) having at least two bonds selected from a group consisting of an Si—H bond and an Si—OH bond is represented by Formula (1) below. 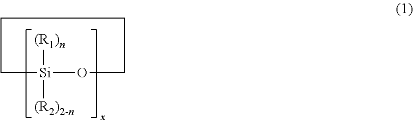
wherein x represents an integer of equal to or more than 2 and equal to or less than 10;
n represents an integer of equal to or more than 0 and equal to or less than 2;
R₁'s may be the same as or different from each other and represent a substituent having an atom selected from an oxygen atom, a boron atom, and a nitrogen atom; and
R₂'s may be the same as or different from each other and represent a hydrogen atom or a saturated or unsaturated hydrocarbon group having 1 to 20 carbon atoms, in which at least two of R₁'s and R₂'s represent a hydrogen atom or a hydroxyl group.

13. The laminated base material for a printed wiring board according to claim 11,
wherein the resin layer contains 40 to 75% by weight of the inorganic filler (B) with respect to 100% by weight of the total weight of the resin layer.

14. The laminated base material for a printed wiring board according to claim 11,
wherein the resin layer contains a cyanate resin composition (D).

15. The laminated base material for a printed wiring board according to claim 14,
wherein the adhesive layer contains an aromatic polyamide resin (X) having at least one hydroxyl group.

16. The laminated base material for a printed wiring board according to claim 15,
wherein the aromatic polyamide resin (X) having at least one hydroxyl group contains a segment where 4 or more carbon chains having a diene structure are connected.

17. The laminated base material for a printed wiring board according to claim 15,
wherein the aromatic polyamide resin (X) having at least one hydroxyl group contains a segment having a butadiene rubber component.

18. The laminated base material for a printed wiring board according to claim 11,
wherein the adhesive layer contains an inorganic filler (Y) having an average particle size of 100 nm or less.

19. The laminated base material for a printed wiring board according to claim 11,
wherein a total specific surface area of the inorganic filler (B) included in the resin layer is equal to or greater than 1.8 m² and equal to or less than 4.5 m².

20. A laminate for a printed wiring board obtained by bonding a laminated base material for a printed wiring board onto both surfaces of a substrate,
wherein the laminated base material for a printed wiring board is the laminated base material for a printed wiring board according to claim 11.

21. A printed wiring board obtained by using the laminated base material for a printed wiring board according to claim 11 as an inner layer circuit board.

22. The printed wiring board according to claim 21,
wherein the inner layer circuit board is obtained by curing a laminate for a printed wiring board and forming a conductive circuit over the laminate for a printed wiring board, wherein said laminate is obtained by bonding said laminated base material for a printed wiring board onto both surfaces of a substrate.

23. A semiconductor device obtained by mounting a semiconductor element to the printed wiring board according to claim 21.
